(19) United States
(12) Patent Application Publication
(10) Pub. No.: US 2018/0286316 A1
(43) Pub. Date: Oct. 4, 2018

(54) DISPLAY DEVICE AND CIRCUIT MEMBER

(71) Applicant: Sharp Kabushiki Kaisha, Sakai City, Osaka (JP)

(72) Inventors: Ryuzo YUKI, Sakai City (JP); Katsuhiro YAMAGUCHI, Sakai City (JP); Hiromi ENOMOTO, Sakai City (JP); Kazuyoshi MAEDA, Sakai City (JP); Haruhito KAGAWA, Sakai City (JP); Koji MICHIBAYASHI, Sakai City (JP); Yuji TANIGUCHI, Sakai City (JP); Takashi KUBO, Sakai City (JP); Masataka OYAMA, Sakai City (JP)

(21) Appl. No.: 15/758,777

(22) PCT Filed: Sep. 5, 2016
(86) PCT No.: PCT/JP2016/075940

§ 371 Date: Mar. 9, 2018

(30) Foreign Application Priority Data
Sep. 11, 2015 (JP) 2015-179918

(51) Int. Cl. G09G 3/3291; G02F 1/1345; G02F 1/1333; G02F 1/1335; H05K 1/18; H01L 27/12; G09G 3/36; G09G 3/3225; H01L 51/50; H01L 27/32

(52) U.S. Cl. CPC G09G 3/3291; G02F 1/13452; G02F 1/133308; G02F 1/133514; H01L 27/3262; H01L 27/124; G09G 3/3648; G09G 3/3225; H01L 51/5012; H05K 1/189

(57) ABSTRACT

The display device of the present invention includes: a display panel having an outer shape that is curved as a whole and is partially provided with multiple linear outer edge portions; and a circuit member including a main part and multiple branches coupled with the main part. Each of the linear outer edge portions is provided with a terminal on the front surface side of the display panel. The main part is provided with a driver. Each of the branches is provided with a conductive line that electrically couples the driver and the terminal. Each of ends of the branches is attached to the corresponding linear outer edge portion and is bent along the corresponding linear outer edge portion from the front surface side toward the back surface of the display panel. The main part is disposed on the back surface side of the display panel.

### TECHNICAL FIELD

The present invention relates to display devices and circuit members. The present invention specifically relates to a display device having a shape other than a quadrangular shape, and a circuit member to be used in the display device.

### BACKGROUND ART

Display devices are used in a wide variety of uses, and there arises a strong demand for display devices with a shape other than conventional quadrangular shapes (hereinafter, also referred to as a deformed shape). In order to meet this demand, display devices with a variety of deformed shapes are proposed (for example, see Patent Literatures 1 to 5).

### CITATION LIST

### Patent Literature

Patent Literature 1: JP 2006-276359 A

Patent Literature 2: JP 5177875 B

Patent Literature 3: JP 2006-276580 A

Patent Literature 4: JP 2009-69768 A

Patent Literature 5: JP 2009-128420 A

### SUMMARY OF INVENTION

### Technical Problem

The present inventors examined conventional deformed display devices to unfortunately find that such deformed display devices are difficult to have both a narrow frame and high definition. The reason of this is described below.

In a display device, a display panel is coupled with drivers such as a signal line drive circuit. Known methods of coupling a display panel and drivers are a method of disposing drivers on a display panel (hereinafter, also referred to as Method A) and a method of disposing drivers on a circuit member (hereinafter, also referred to as Method B).

A representative example of Method A is a technique using chip on glass (COG). In the COG technique, drivers are disposed as chip-like integrated circuits (ICs) on a display panel (a glass substrate of the display panel) and electrically coupled with a terminal portion of the display panel.

A representative example of Method B is a technique using chip on film (COF). In the COF technique, drivers are disposed as chip-like integrated circuits on a circuit member (film-like circuit member) and are electrically coupled with a terminal portion of the display panel via conductive lines on the circuit member. Since drivers are not disposed on the display panel in Method B, the frame can be more narrowed down than in Method A owing to the space generated by the absence of the drivers.

In Method B, the circuit member is usually attached to the terminal portion on the outer edge of the display panel and bent toward the back surface of the display panel. If the circuit member is not bent along the terminal portion, a stress is applied to the portion where the circuit member and the terminal portion are attached, breaking the conductive lines of the circuit member. Further, the circuit member is twisted so that it is not favorably bent. The circuit member can be easily bent along a linear portion, and thus the terminal portion of the display panel to be attached to the circuit member is usually placed at a linear portion of the outer edge of the display panel.

In consideration of the above points, the present inventors examined as follows a deformed liquid crystal display device in which a liquid crystal display panel and drivers are coupled by Method B.

### (Examination 1)

FIG. 43 are schematic plan views of a liquid crystal display panel of a liquid crystal display device in Examination 1; FIG. 43(a) shows the initial state and FIG. 43(b) shows a state with higher definition than in FIG. 43(a). As shown in FIG. 43(a), a liquid crystal display panel 102a has a polygonal outer shape (in FIG. 43(a), an octagonal outer shape). The liquid crystal display panel 102a has a display region a and a frame region b1 around the display region a. The display region a has a circular shape. The inner edge of the frame region b1 has a circular shape and the outer edge thereof has a polygonal shape. On the linear portion of the outer edge of the frame region b1 is disposed a terminal portion 130a. The terminal portion 130a is attached to a circuit member (not shown) provided with drivers. In FIG. 43(a), Wa1 represents the width of the region where the liquid crystal display panel 102a (terminal portion 130a) and the circuit member are attached to each other. Ra1 represents the distance from the center of the display region a to the outermost portion of the liquid crystal display panel 102a.

In the liquid crystal display panel 102a, conductive lines such as scanning lines and signal lines are routed to the terminal portion 130a inside the frame region b1. Still, the frame region b1 having a circular inner edge and a polygonal outer edge has a narrow space for arrangement of these conductive lines, complicating the routing of the conductive lines and making it difficult to form a narrow frame.

Further, when the liquid crystal display panel 102a is made to have higher definition, in other words, the number of pixels is increased without changing the size of the display region a, the following problems occur.

(i) Since the number of terminals increases, the width of a terminal portion 130b of a liquid crystal display panel 102b is greater than the width of the terminal portion 130a of the liquid crystal display panel 102a, as shown in FIGS. 43(a) and 43(b).

(ii) Since the number of outputs of the drivers increases, the number of conductive lines of the circuit member increases and the width of the circuit member increases. This is because Method B (e.g., a COF technique) has difficulty in placing the conductive lines at a narrow pitch on the circuit member.

As a result of the above problems (i) and (ii), the width Wb1 of the region where the liquid crystal display panel 102b (terminal portion 130b) and the circuit member are attached to each other is greater than the width Wa1, as shown in FIGS. 43(a) and 43(b). Along with this, a frame region b2 of the liquid crystal display panel 102b is greater than the frame region b1 and the distance Rb1 from the center of the display region a to the outermost portion of the liquid crystal display panel 102b is greater than Ra1. Therefore, the liquid crystal display panel 102b having higher definition than the liquid crystal display panel 102a is difficult to have a narrow frame.

### (Examination 2)

FIG. 44 are schematic plan views of a liquid crystal display panel of a liquid crystal display device in Examination 2; FIG. 44(a) shows the initial state and FIG. 44(b) shows a state with higher definition than in FIG. 44(a). As shown in FIG. 44(a), a liquid crystal display panel 102c has a circular outer shape partially notched in a linear manner. The liquid crystal display panel 102c has a display region a and a frame region b3 around the display region a. The display region a has a circular shape. The inner edge of the frame region b3 has a circular shape and the outer edge thereof has a circular shape partially notched in a linear manner. On the linear portion of the outer edge of the frame region b3 is disposed a terminal portion 130c. The terminal portion 130c is attached to a circuit member (not shown) provided with drivers. In FIG. 44(a), Wa1 represents the width of the region where the liquid crystal display panel 102c (terminal portion 130c) and the circuit member are attached to each other. Rat represents the distance from the center of the display region a to the outermost portion of the liquid crystal display panel 102c.

Since both the inner and outer edges of the frame region b3 of the liquid crystal display panel 102c include a circular portion, the frame region b3 has a wider space for arrangement of conductive lines such as scanning lines and signal lines than the frame region b1 of the liquid crystal display panel 102a shown in FIG. 43(a). Thus, the liquid crystal display panel 102c can more easily achieve a narrow frame than the liquid crystal display panel 102a.

Still, when the liquid crystal display panel 102c is made to have higher definition, in other words, the number of pixels is increased without changing the size of the display region a, the following problems occur.

(iii) Since the number of terminals increases, the width of a terminal portion 130d of a liquid crystal display panel 102d is greater than the width of the terminal portion 130c of the liquid crystal display panel 102c, as shown in FIGS. 44(a) and 44(b).

(iv) Since the number of outputs of the drivers increases, the number of conductive lines of the circuit member increases and the width of the circuit member increases.

As a result of the above problems (iii) and (iv), the width Wb2 of the region where the liquid crystal display panel 102d (terminal portion 130d) and the circuit member are attached to each other is greater than the width Wa1, as shown in FIGS. 44(a) and 44(b). Along with this, a frame region b4 of the liquid crystal display panel 102d is greater than the frame region b3 and the distance Rb2 from the center of the display region a to the outermost portion of the liquid crystal display panel 102d is greater than Ra2. Therefore, the liquid crystal display panel 102d having higher definition than the liquid crystal display panel 102c is difficult to have a narrow frame.

### (Examination 3)

FIG. 45 are schematic plan views of a liquid crystal display panel of a liquid crystal display device in Examination 3; FIG. 45(a) shows the initial state and FIG. 45(b) shows a state with higher definition than in FIG. 45(a). As shown in FIG. 45(a), a liquid crystal display panel 102e has a circular outer shape partially protruding. The liquid crystal display panel 102e has a display region a and a frame region b5 around the display region a. The display region a has a circular shape. The inner edge of the frame region b5 has a circular shape and the outer edge thereof has a circular shape partially protruding. On the protruding portion of the frame region b5 is disposed a terminal portion 130e. The terminal portion 130e is attached to a circuit member (not shown) provided with drivers. In FIG. 45(a), Wa3 represents the width of the region where the liquid crystal display panel 102e (terminal portion 130e) and the circuit member are attached to each other (the width of the protruding portion of the frame region b5). Ra3 represents the distance from the center of the display region a to the outermost portion of the liquid crystal display panel 102e.

Since both the inner and outer edges of the frame region b5 of the liquid crystal display panel 102e include a circular region, the frame region b5 makes it easier to arrange conductive lines such as scanning lines and signal lines than the frame region b1 of the liquid crystal display panel 102a shown in FIG. 43(a). Thus, the liquid crystal display panel 102e can more easily achieve a narrow frame than the liquid crystal display panel 102a.

Still, supposing the liquid crystal display panel 102e is enclosed in a circular housing 131a, the frame region including the housing 131a unfortunately becomes wide. This is because the outermost portion of the housing 131a corresponds to the outermost portion of the liquid crystal display panel 102e, i.e., an edge of the protruding portion of the frame region b5, as shown in FIG. 45(a). In order to avoid this problem, the liquid crystal display panel 102e may be enclosed in a housing having the same shape as the outer shape of the liquid crystal display panel 102e. However, such a housing has a complicated shape, which costs high.

In addition, when the liquid crystal display panel 102e is made to have higher definition, in other words, the number of pixels is increased without changing the size of the display region a, the following problems occur.

(v) Since the number of terminals increases, the width of a terminal portion 130f of a liquid crystal display panel 102f is greater than the width of the terminal portion 130e of the liquid crystal display panel 102e, as shown in FIGS. 45(a) and 45(b).

(vi) Since the number of outputs of the drivers increases, the number of conductive lines of the circuit member increases and the width of the circuit member increases.

As a result of the above problems (v) and (vi), the width Wb3 of the region where the liquid crystal display panel 102f (terminal portion 130f) and the circuit member are attached to each other is greater than the width Wa3, as shown in FIGS. 45(a) and 45(b). Along with this, the protruding portion of a frame region b6 is greater than the protruding portion of the frame region b5 and the distance Rb3 from the center of the display region a to the outermost portion of the liquid crystal display panel 102f is greater than Ra3. Further, the frame region including a housing 131b is also large. Therefore, the liquid crystal display panel 102f having higher definition than the liquid crystal display panel 102e is difficult to have a narrow frame.

The shape of the liquid crystal display panel 102f is greatly different from the shape of the liquid crystal display panel 102e. In other words, when the liquid crystal display panel 102e is made to have higher definition, it is difficult to maintain its design qualities.

As mentioned above, conventional deformed display devices have problems in achieving both a narrow frame and higher definition. Nevertheless, no solution to the above problems has been found. For example, Patent Literature 1 discloses a liquid crystal display device having a shape similar to that in Examination 1 and fails to propose any solution to the above problems. Patent Literature 2 discloses a liquid crystal cell having a shape similar to that in Examination 3 and fails to propose any solution to the above problems. The inventions of Patent Literatures 3 to 5 also fail to propose any solution to the above problems.

The present invention is devised in view of the above state of the art, and aims to provide a deformed display device having both a narrow frame and high definition, and a circuit member to be used in the display device.

### Solution to Problem

The present inventors performed various studies on a deformed display device having both a narrow frame and high definition, and focused on a structure in which, even with high definition, the width of a region where the display panel (terminal portion) and the circuit member are attached to each other is not elongated. Finally, the present inventors found the following structures of a display panel and a circuit member:

(1) disposing multiple linear outer edge portions on the outer edge of a display panel, and disposing terminals on the corresponding linear outer edge portion; and

(2) providing a circuit member with a main part and multiple branches coupled with the main part, disposing a driver on the main part, and disposing, on each of the branches, conductive lines that electrically couple the driver and terminals of the display panel.

The present inventors found that the structure (1) can deal with an increase in the number of terminals of the display panel resulting from high definition by disposing the increased number of terminals dividedly on multiple linear outer edge portions or by increasing the number of linear outer edge portions. They also found that the structure (2) can deal with an increase in the number of conductive lines of the circuit member resulting from high definition by disposing the increased number of conductive lines dividedly on multiple branches or by increasing the number of the branches. As a result, the present inventors found that high definition can be achieved without increasing the width of each region where multiple linear outer edge portions and multiple branches are attached to each other, i.e., without increasing the size of the frame region of the display panel. Finally, the present inventors arrived at the solution to the above problems, completing the present invention.

Specifically, one aspect of the present invention may be a display device including a display panel having an outer shape that is curved as a whole and is partially provided with multiple linear outer edge portions; and a circuit member including a main part and multiple branches coupled with the main part, each of the linear outer edge portions being provided with a terminal on the front surface side of the display panel, the main part being provided with a driver, each of the branches being provided with a conductive line that electrically couples the driver and the terminal, each of ends of the branches being attached to the corresponding linear outer edge portion and being bent along the corresponding linear outer edge portion from the front surface side toward the back surface of the display panel, the main part being disposed on the back surface side of the display panel.

Another aspect of the present invention may be a circuit member including a main part; and multiple branches coupled with the main part, the main part being provided with a driver, each of the branches being provided with a conductive line electrically coupled with the driver, at least an end of each of the branches being bendable.

### Advantageous Effects of Invention

The present invention can provide a deformed display device having both a narrow frame and high definition, and a circuit member to be used in the display device.

### BRIEF DESCRIPTION OF DRAWINGS

FIG. 1 are schematic plan views of a liquid crystal display device of Embodiment 1; FIG. 1(a) is a view seen from the front surface side and FIG. 1(b) is a view seen from the back surface side.

FIG. 2 is a schematic cross-sectional view of a cross section taken along the A-A′ line in FIG. 1(b).

FIG. 3 is a schematic cross-sectional view of a cross section taken along the B-B′ line in FIG. 1(b).

FIG. 4 are schematic plan views illustrating a process of coupling a circuit member of Embodiment 1 with a liquid crystal display panel and bending the circuit member toward the back surface of the liquid crystal display panel (steps (a) to (c)).

FIG. 5 is a schematic cross-sectional view of a cross section taken along the C-C′ line in FIG. 4(b).

FIG. 6 is a schematic cross-sectional view of a cross section taken along the D-D′ line in FIG. 4(c).

FIG. 7 are schematic plan views of a liquid crystal display device of Variation of Embodiment 1; FIG. 7(a) is a view seen from the front surface side and FIG. 7(b) is a view seen from the back surface side.

FIG. 8 are schematic plan views illustrating a process of coupling a circuit member of Variation of Embodiment 1 with a liquid crystal display panel and bending the circuit member toward the back surface of the liquid crystal display panel (steps (a) to (c)).

FIG. 9 are schematic plan views of a liquid crystal display device of Embodiment 2; FIG. 9(a) is a view seen from the front surface side and FIG. 9(b) is a view seen from the back surface side (before the circuit member is bent).

FIG. 10 are schematic plan views illustrating a process of coupling a circuit member of Embodiment 2 with a liquid crystal display panel and bending the circuit member toward the back surface of the liquid crystal display panel (steps (a) to (d)).

FIG. 11 are schematic plan views of a liquid crystal display device of Variation of Embodiment 2; FIG. 11(a) is a view seen from the front surface side and FIG. 11(b) is a view seen from the back surface side (before the circuit member is bent).

FIG. 12 are schematic plan views illustrating a process of coupling a circuit member of Variation of Embodiment 2 with a liquid crystal display panel and bending the circuit member toward the back surface of the liquid crystal display panel (steps (a) to (d)).

FIG. 13 are schematic plan views of a liquid crystal display device of Embodiment 3; FIG. 13(a) is a view seen from the front surface side and FIG. 13(b) is a view seen from the back surface side.

FIG. 14 are schematic plan views illustrating a process of coupling a circuit member of Embodiment 3 with a liquid crystal display panel and bending the circuit member toward the back surface of the liquid crystal display panel (steps (a) to (c)).

FIG. 15 are schematic plan views of a liquid crystal display device of Variation 1 of Embodiment 3; FIG. 15(a) is a view seen from the front surface side and FIG. 15(b) is a view seen from the back surface side.

FIG. 16 are schematic plan views illustrating a process of coupling a circuit member of Variation 1 of Embodiment 3 with a liquid crystal display panel and bending the circuit member toward the back surface of the liquid crystal display panel (steps (a) to (c)).

FIG. 17 are schematic plan views of a liquid crystal display device of Variation 2 of Embodiment 3; FIG. 17(a) is a view seen from the front surface side and FIG. 17(b) is a view seen from the back surface side.

FIG. 18 are schematic plan views illustrating a process of coupling a circuit member of Variation 2 of Embodiment 3 with a liquid crystal display panel and bending the circuit member toward the back surface of the liquid crystal display panel (steps (a) to (c)).

FIG. 19 are schematic plan views of a liquid crystal display device of Embodiment 4; FIG. 19(a) is a view seen from the front surface side and FIG. 19(b) is a view seen from the back surface side.

FIG. 20 are schematic plan views illustrating a process of coupling a circuit member of Embodiment 4 with a liquid crystal display panel and bending the circuit member toward the back surface of the liquid crystal display panel (steps (a) to (c)).

FIG. 21 are schematic plan views of a liquid crystal display device of Variation 1 of Embodiment 4; FIG. 21(a) is a view seen from the front surface side and FIG. 21(b) is a view seen from the back surface side.

FIG. 22 are schematic plan views illustrating a process of coupling a circuit member of Variation 1 of Embodiment 4 with a liquid crystal display panel and bending the circuit member toward the back surface of the liquid crystal display panel (steps (a) to (c)).

FIG. 23 are schematic plan views of a liquid crystal display device of Variation 2 of Embodiment 4; FIG. 23(a) is a view seen from the front surface side and FIG. 23(b) is a view seen from the back surface side.

FIG. 24 are schematic plan views illustrating a process of coupling a circuit member of Variation 2 of Embodiment 4 with a liquid crystal display panel and bending the circuit member toward the back surface of the liquid crystal display panel (steps (a) to (c)).

FIG. 25 are schematic plan views of a liquid crystal display device of Embodiment 5; FIG. 25(a) is a view seen from the front surface side and FIG. 25(b) is a view seen from the back surface side (before the circuit member is bent).

FIG. 26-1 are schematic plan views illustrating a process of coupling a circuit member of Embodiment 5 with a liquid crystal display panel and bending the circuit member toward the back surface of the liquid crystal display panel (steps (a) and (b)).

FIG. 26-2 are schematic plan views illustrating a process of coupling a circuit member of Embodiment 5 with a liquid crystal display panel and bending the circuit member toward the back surface of the liquid crystal display panel (steps (c) and (d)).

FIG. 27 are schematic plan views of a liquid crystal display device of Variation of Embodiment 5; FIG. 27(a) is a view seen from the front surface side and FIG. 27(b) is a view seen from the back surface side.

FIG. 28 are schematic plan views illustrating a process of coupling a circuit member of Variation of Embodiment 5 with a liquid crystal display panel and bending the circuit member toward the back surface of the liquid crystal display panel (steps (a) to (c)).

FIG. 29 are schematic plan views of a liquid crystal display device of Embodiment 6; FIG. 29(a) is a view seen from the front surface side and FIG. 29(b) is a view seen from the back surface side.

FIG. 30 are schematic plan views illustrating a process of coupling a circuit member of Embodiment 6 with a liquid crystal display panel and bending the circuit member toward the back surface of the liquid crystal display panel (steps (a) to (d)).

FIG. 31 are schematic plan views illustrating another process of coupling the circuit member of Embodiment 6 with a liquid crystal display panel and bending the circuit member toward the back surface of the liquid crystal display panel (steps (a) to (d)).

FIG. 32 are schematic plan views of a liquid crystal display device of Variation 1 of Embodiment 6; FIG. 32(a) is a view seen from the front surface side and FIG. 32(b) is a view seen from the back surface side.

FIG. 33 are schematic plan views illustrating a process of coupling a circuit member of Variation 1 of Embodiment 6 with a liquid crystal display panel and bending the circuit member toward the back surface of the liquid crystal display panel (steps (a) to (d)).

FIG. 34 are schematic plan views of a liquid crystal display device of Variation 2 of Embodiment 6; FIG. 34(a) is a view seen from the front surface side and FIG. 34(b) is a view seen from the back surface side.

FIG. 35 are schematic plan views illustrating a process of coupling a circuit member of Variation 2 of Embodiment 6 with a liquid crystal display panel and bending the circuit member toward the back surface of the liquid crystal display panel (steps (a) to (d)).

FIG. 36 is a schematic plan view of a liquid crystal display device of Embodiment 7.

FIG. 37 is a schematic plan view of a liquid crystal display device of Variation of Embodiment 7.

FIG. 38 are schematic plan views of an organic electroluminescent display device of Embodiment 8; FIG. 38(a) is a view seen from the front surface side and FIG. 38(b) is a view seen from the back surface side.

FIG. 39 is a schematic cross-sectional view of a cross section taken along the H-H′ line in FIG. 38(b).

FIG. 40 is a schematic cross-sectional view of a cross section taken along the J-J′ line in FIG. 38(b).

FIG. 41 are schematic plan views illustrating a process of coupling a circuit member of Embodiment 8 with an organic EL display panel and bending the circuit member toward the back surface of the organic EL display panel (steps (a) to (c)).

FIG. 42 is a schematic plan view of an example of the shape of a liquid crystal display panel different from that in Embodiment 1.

FIG. 43 are schematic plan views of a liquid crystal display panel of a liquid crystal display device in Examination 1; FIG. 43(a) shows the initial state and FIG. 43(b) shows a state with higher definition than in FIG. 43(a).

FIG. 44 are schematic plan views of a liquid crystal display panel of a liquid crystal display device in Examination 2; FIG. 44(a) shows the initial state and FIG. 44(b) shows a state with higher definition than in FIG. 44(a).

FIG. 45 are schematic plan views of a liquid crystal display panel of a liquid crystal display device in Examination 3; FIG. 45(a) shows the initial state and FIG. 45(b) shows a state with higher definition than in FIG. 45(a).

### DESCRIPTION OF EMBODIMENTS

Hereinafter, the present invention is described in more detail based on embodiments with reference to the drawings. The embodiments, however, are not intended to limit the scope of the present invention. In the following drawings, the same components or those having the same function have the same reference numerals except for their additional alphabetic characters and/or apostrophes, and repetition of the description thereof is omitted as appropriate. The configurations of the embodiments may appropriately be combined or modified within the spirit of the present invention.

### Embodiment 1

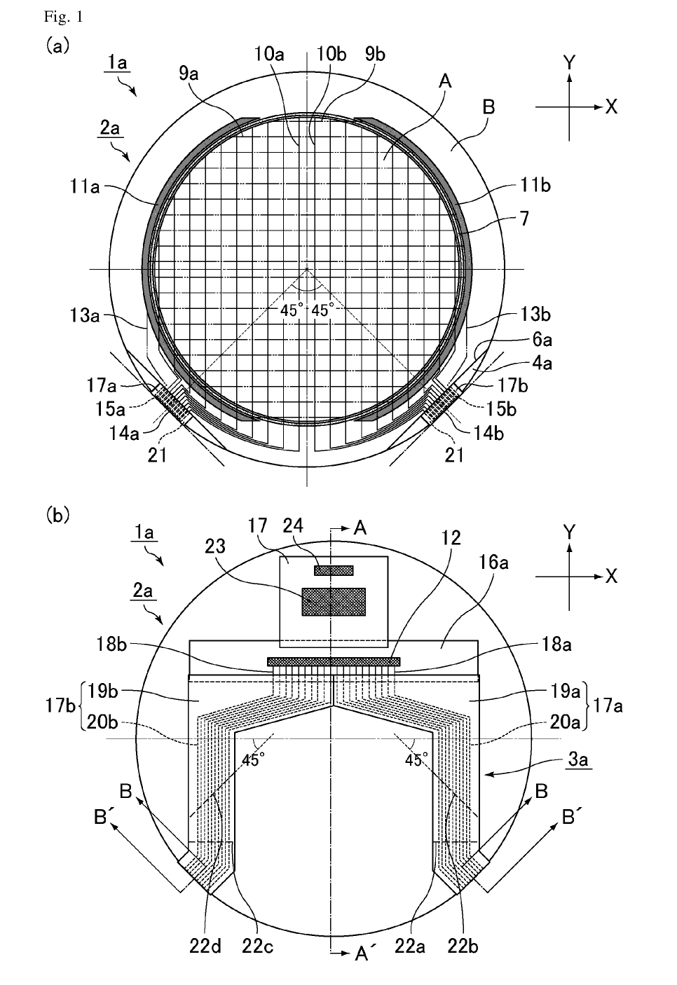

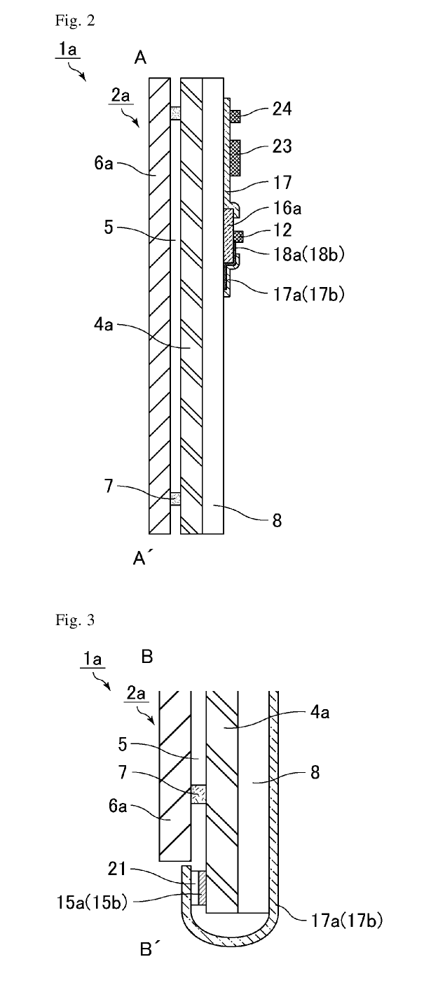

A liquid crystal display device and circuit member of Embodiment 1 are described with reference to FIG. 1, FIG. 2, and FIG. 3. FIG. 1 are schematic plan views of a liquid crystal display device of Embodiment 1; FIG. 1(a) is a view seen from the front surface side and FIG. 1(b) is a view seen from the back surface side. FIG. 2 is a schematic cross-sectional view of a cross section taken along the A-A′ line in FIG. 1(b). FIG. 3 is a schematic cross-sectional view of a cross section taken along the B-B′ line in FIG. 1(b).

A liquid crystal display device 1a includes a liquid crystal display panel 2a and a circuit member 3a disposed on the back surface side of the liquid crystal display panel 2a.

The liquid crystal display panel 2a has a display region A and a frame region B around the display region A. The display region A has a circular shape. The inner edge of the frame region B has a circular shape, and the outer edge thereof has a circular shape with two linearly notched portions (corresponding to linear outer edge portions 14a and 14b).

As shown in FIG. 2, the liquid crystal display panel 2a includes a thin film transistor array substrate 4a, a liquid crystal layer 5, and a color filter substrate 6a in the given order from the back surface side to the front surface side. The thin film transistor array substrate 4a and the color filter substrate 6a are attached to each other at the peripheral portions thereof with a sealing material 7 in between so as to sandwich the liquid crystal layer 5. The front surface side as used herein means the left side (the color filter substrate 6a side) of the liquid crystal display device 1a in FIG. 2. The back surface side as used herein means the right side (the thin film transistor array substrate 4a side) of the liquid crystal display device 1a in FIG. 2.

The thin film transistor array substrate 4a may have a structure in which multiple sets of components for driving the respective pixels, such as a thin film transistor element, a pixel electrode (transparent electrode), and a variety of conductive lines (a scanning line and a signal line), are disposed on a glass substrate. Instead of the glass substrate, the structure may include a transparent substrate such as a plastic substrate.

The semiconductor layer of each thin film transistor element may have any composition, and may contain amorphous silicon, low temperature polysilicon, or an oxide semiconductor, for example. The oxide semiconductor may be formed from a compound containing indium, gallium, zinc, and oxygen or a compound containing indium, zinc, and oxygen, for example. The oxide semiconductor formed from a compound containing indium, gallium, zinc, and oxygen causes less off-state leakage current and, once voltage is applied thereto, enables pause driving in which the state of voltage application is maintained until the next data signal (voltage) is written (applied). Accordingly, from the viewpoint of low power consumption, the oxide semiconductor is preferably a compound containing indium, gallium, zinc, and oxygen.

As shown in FIG. 1(a), the outer edge of the thin film transistor array substrate 4a (frame region B) is provided with a scanning line drive circuit (gate driver) 11a configured to apply voltage to multiple scanning lines 9a and a scanning line drive circuit 11b configured to apply voltage to multiple scanning lines 9b. The scanning line drive circuits 11a and 11b may be directly formed on the thin film transistor array substrate 4a, or may be disposed as chip-like integrated circuits on the thin film transistor array substrate 4a.

As shown in FIG. 1(a), multiple signal lines 10a disposed on the left half of the thin film transistor array substrate 4a and a conductive line 13a led from the scanning line drive circuit 11a are electrically coupled with multiple terminals 15a disposed on the front surface side of the linear outer edge portion 14a of the liquid crystal display panel 2a (the outer edge of the thin film transistor array substrate 4a) in an independent manner. Multiple signal lines 10b disposed on the right half of the thin film transistor array substrate 4a and a conductive line 13b led from the scanning line drive circuit 11b are electrically coupled with multiple terminals 15b disposed on the front surface side of a linear outer edge portion 14b of the liquid crystal display panel 2a (the outer edge of the thin film transistor array substrate 4a) in an independent manner. The linear outer edge portions 14a and 14b are portions attached to the circuit member 3a.

The outer shape of the liquid crystal display panel 2a is at least a curved whole shape partially provided with multiple linear outer edge portions. The phrase “the outer shape of the liquid crystal display panel is a curved whole shape” as used herein means that at least part of the periphery of the liquid crystal display panel is substantially curved in a macroscopic view, and includes an outer edge of the liquid crystal display panel constituted by a curved line except for multiple linear outer edge portions, for example. In the present embodiment, the outer edge of the liquid crystal display panel 2a has a circular shape except for the linear outer edge portions 14a and 14b. In other words, the linear outer edge portions 14a and 14b can be regarded as the two linearly notched portions in the circular shape.

The number of the linear outer edge portions of the liquid crystal display panel 2a may be any plural number, and may be two as in the present embodiment, or may be three or more.

The linear outer edge portions 14a and 14b may be present at any position as long as they are present on the outer edge of the liquid crystal display panel 2a. Specifically, in the state shown in FIG. 1(a), the direction perpendicular to the linear outer edge portion 14a (14b) and the Y direction (the vertical direction in the FIG. 1(a)) may form any angle. In the present embodiment, the direction perpendicular to the linear outer edge portion 14a (14b) and the Y direction (the vertical direction in FIG. 1(a)) form an angle of 45° in the state shown in FIG. 1(a). The Y direction in FIG. 1(a) is the direction along which the signal lines 10a and 10b extends in the display region A.

The color filter substrate 6a may have a structure in which multiple components such as color filter layers corresponding to the respective pixels are disposed on a glass substrate, for example. Instead of the glass substrate, the structure may include a transparent substrate such as a plastic substrate. The color filter layers may provide any combination of colors, such as combination of red, green, and blue or combination of red, green, blue, and yellow. The color filter substrate 6a may further include multiple pixel electrodes (transparent electrodes) configured to drive the pixels.

The liquid crystal display panel 2a may further include a polarizing plate on each of the back surface side (the back surface side of the thin film transistor array substrate 4a) and the front surface side (the front surface side of the color filter substrate 6a).

The liquid crystal display device 1a may further include a backlight 8 as shown in FIG. 2 on the back surface side of the liquid crystal display panel 2a (the back surface side of the thin film transistor array substrate 4a). The backlight 8 may be of any type, such as an edge-lit type or a direct-lit type. The backlight 8 may have any display light source, such as a light emitting diode (LED) or a cold cathode fluorescent lamp (CCFL).

As shown in FIG. 1(b), the circuit member 3a includes a COF 16a (main part) and flexible printed circuits (FPCs) 17a and 17b (branches) coupled with the COF 16a.

The COF 16a is provided with a signal line drive circuit (source driver) 12 configured to apply voltage to the signal lines 10a and 10b and multiple conductive lines 18a and 18b led from the signal line drive circuit 12 (hereinafter, also referred to simply as conductive lines 18a and 18b). This can eliminate the necessity of preparing the space for disposing the signal line drive circuit 12 in the frame region B, and thus the frame can be easily narrowed down.

The driver(s) (drive circuit(s)) disposed on the COF 16a may be of any type. The driver(s) may be the signal line drive circuit 12 as in the present embodiment or may be the scanning line drive circuits 11a and 11b, or may be all of these drive circuits. When all of the scanning line drive circuits 11a and 11b and the signal line drive circuit 12 are disposed on the COF 16a, the frame is more easily narrowed down. When the signal line drive circuit 12 is disposed on the thin film transistor array substrate 4a, the signal line drive circuit 12 may be directly formed on the thin film transistor array substrate 4a or may be disposed as a chip-like integrated circuit on the thin film transistor array substrate 4a.

In the present embodiment, the signal line drive circuit 12 is disposed on the COF 16a. Still, it may be disposed not on the COF 16a but on an FPC. In order to achieve high definition easily, the signal line drive circuit 12 is preferably disposed on the COF 16a.

The FPC 17a includes a flexible substrate 19a and multiple conductive lines 20a. A first end of the FPC 17a is provided with ends of the conductive lines 20a or a conductive portion electrically coupled with the conductive lines 20a. A second end of the FPC 17a is provided with multiple FPC terminals (not shown) electrically coupled with the respective conductive lines 20a in an independent manner. The FPC 17b includes a flexible substrate 19b and multiple conductive lines 20b. A first end of the FPC 17b is provided with ends of the conductive lines 20b or a conductive portion electrically coupled with the conductive lines 20b. A second end of the FPC 17b is provided with multiple FPC terminals (not shown) electrically coupled with the respective conductive lines 20b in an independent manner. In FIG. 1(b), only some of the conductive lines 20a and 20b are illustrated.

As shown in FIG. 1(b), the conductive lines 20a and 20b are preferably led outward relative to the signal line drive circuit 12. This enables further reduction in size of the circuit member 3a. As a result, the circuit member 3a is likely to be disposed on the back surface side of the liquid crystal display panel 2a without protruding from the liquid crystal display panel 2a.

The flexible substrates 19a and 19b may be insulating films, for example. Examples of insulating materials include resin materials such as polyimide and polyester and metal materials covered with an insulating coat.

The conductive lines 20a and 20b may be formed from a conductor such as copper foil, for example. The conductive lines 20a (20b) may be disposed on either one or both surfaces of the flexible substrate 19a (19b), or may be disposed to pass inside the flexible substrate 19a (19b). In the present embodiment, the conductive lines 20a (20b) are disposed on one surface of the flexible substrate 19a (19b) and disposed on the liquid crystal display panel 2a side of the flexible substrate 19a (19b) in the state shown in FIG. 1(b).

As shown in FIG. 1(a) and FIG. 3, the linear outer edge portion 14a and the first end of the FPC 17a are attached to each other via an anisotropic conductive film (ACF) 21. This allows electrical coupling of the terminals 15a of the liquid crystal display panel 2a and the conductive lines 20a of the FPC 17a via the anisotropic conductive film 21. Also, the linear outer edge portion 14b and the first end of the FPC 17b are attached to each other via the anisotropic conductive film 21. This allows electrical coupling of the terminals 15b of the liquid crystal display panel 2a and the conductive lines 20b of the FPC 17b via the anisotropic conductive film 21. The linear outer edge portion 14a (14b) and the first end of the FPC 17a (17b) may be directly coupled without any member such as the anisotropic conductive film 21.

As shown in FIG. 1(b), the COF 16a and the second end of the FPC 17a are coupled with each other. This allows electrical coupling of the conductive lines 18a of the COF 16a and the conductive lines 20a of the FPC 17a. Also, the COF 16a and the second end of the FPC 17b are coupled with each other. This allows electrical coupling of the conductive lines 18b of the COF 16a and the conductive lines 20b of the FPC 17b.

As a result, the signal line drive circuit 12 and the terminals 15a are electrically coupled via the conductive lines 18a and 20a. Also, the signal line drive circuit 12 and the terminals 15b are electrically coupled via the conductive lines 18b and 20b. Thereby, voltage (data signal) output from the signal line drive circuit 12 is applied (supplied) to the liquid crystal display panel 2a and an image is displayed.

As shown in FIGS. 1(a) and 1(b), the first end of the FPC 17a is bent from the front surface side toward the back surface of the liquid crystal display panel 2a along the linear outer edge portion 14a. Also, the first end of the FPC 17b is bent from the front surface side toward the back surface of the liquid crystal display panel 2a along the linear outer edge portion 14b.

At least an end of each branch (each of the FPCs 17a and 17b in the present embodiment) of the circuit member 3a is bendable. The term “bendable” as used herein means that an object is at least reversibly bendable, including the cases where an object is bendable from the front surface side toward the back surface of the liquid crystal display panel 2a as in the present embodiment. Examples of such bendable materials include film-like materials such as FPC and COF. Highly rigid materials such as a glass substrate are broken when bent, and thus are not regarded as bendable materials. The portion to be bent may be provided with a fold.

As shown in FIG. 1(b), the COF 16a is disposed on the back surface side of the liquid crystal display panel 2a. The COF 16a may be further coupled with an FPC 17 provided with members such as a component 23 and a B to B connector 24, as shown in FIG. 1(b).

The signal line drive circuit 12 is disposed on the COF 16a so as to be opposite to the liquid crystal display panel 2a in the state shown in FIG. 1(b). Thereby, the COF 16a and the FPC 17 can be easily coupled with each other and the thickness of the liquid crystal display device 1a can be reduced.

The FPC 17a has folds 22a and 22b which are not bent in the state shown in FIG. 1(b). Preferably, one of the folds 22a and 22b is a mountain fold and the other is a valley fold. In the present embodiment, the fold 22a is a valley fold and the fold 22b is a mountain fold in the state shown in FIG. 1(b). Also, the FPC 17b has folds 22c and 22d which are not bent in the state shown in FIG. 1(b). Preferably, one of the folds 22c and 22d is a mountain fold and the other is a valley fold. In the present embodiment, the fold 22c is a valley fold and the fold 22d is a mountain fold in the state shown in FIG. 1(b).

The term “fold” as used herein includes portions which are bent, portions which are not bent now but are the remaining marks of the previous bending, and portions which are not yet bent but are marks for future bending.

The FPC 17a (17b) may have any number of folds, and preferably has multiple folds in addition to the fold along the linear outer edge portion 14a (14b). The folds preferably include a mountain fold and a valley fold. This enables coupling of the circuit member 3a and the liquid crystal display panel 2a and favorable bending of the circuit member 3a toward the back surface of the liquid crystal display panel 2a.

The folds 22a and 22b may be at any positions on the FPC 17a. The folds 22c and 22d may be at any positions on the FPC 17b.

The folds 22a, 22b, 22c, and 22d may be in any direction. Specifically, in the state shown in FIG. 1(b), the direction of each of the folds 22a, 22b, 22c, and 22d and the X direction (the horizontal direction in FIG. 1(b)) may form any angle. In the present embodiment, the direction of each of the folds 22a and 22c and the X direction (the horizontal direction in FIG. 1(b)) form an angle of 0° (parallel), while the direction of each of the folds 22b and 22d and the X direction form an angle of 45°, in the state shown in FIG. 1(b). The X direction in FIG. 1(b) corresponds to the X direction in FIG. 1(a), and is the direction along which the scanning lines 9a and 9b extend in the display region A.

The folds 22a, 22b, 22c, and 22d may be marked with a perforation or a different mark. Examples of the different mark include locally thinner portions of the FPC 17a or 17b and portions where insulating resin (trade name: TUFFY®, Hitachi Chemical Co., Ltd.) is applied.

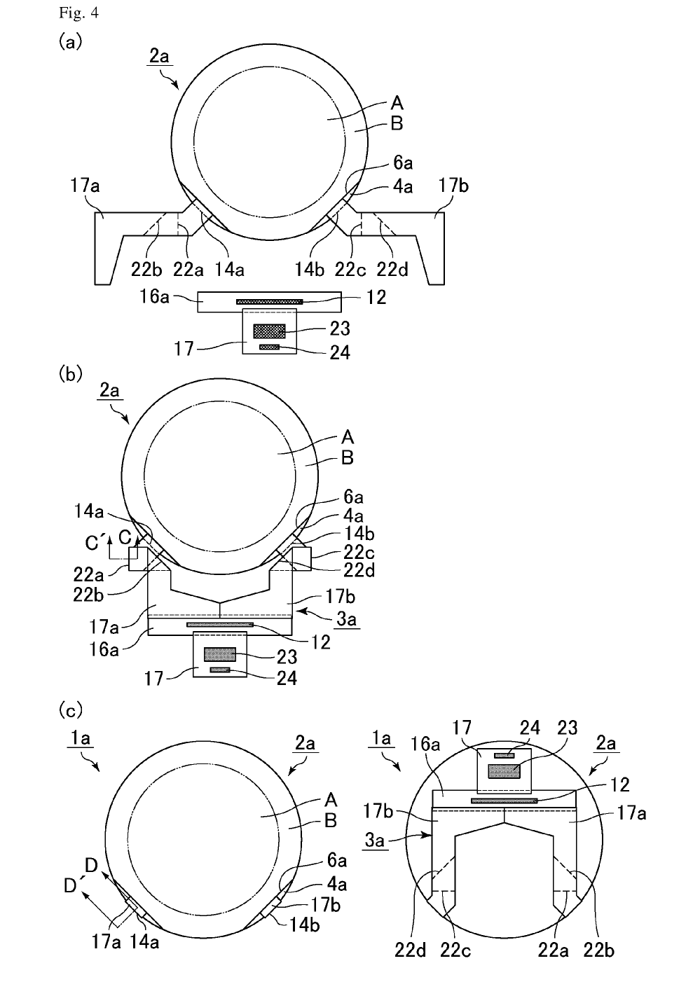

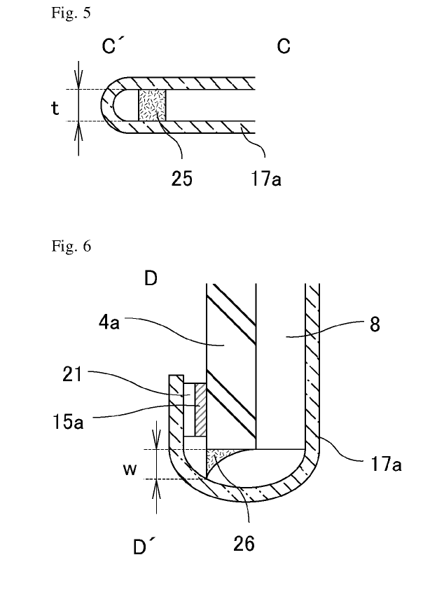

Next, a process of coupling the circuit member 3a with the liquid crystal display panel 2a and bending the circuit member 3a toward the back surface of the liquid crystal display panel 2a is described with reference to FIG. 4. FIG. 4 are schematic plan views illustrating a process of coupling a circuit member of Embodiment 1 with a liquid crystal display panel and bending the circuit member toward the back surface of the liquid crystal display panel (steps (a) to (c)). In FIG. 4, conductive lines and other members of the liquid crystal display panel and circuit member are omitted as appropriate.

### (a) Coupling of Liquid Crystal Display Panel and FPC

As shown in FIG. 4(a), the linear outer edge portion 14a and the first end of the FPC 17a are attached to each other. Also, the linear outer edge portion 14b and the first end of the FPC 17b are attached to each other. The COF 16a is prepared.

The FPC 17a has the folds 22a and 22b in addition to the fold along the linear outer edge portion 14a to be formed in the following step (c). The FPC 17b has the folds 22c and 22d in addition to the fold along the linear outer edge portion 14b to be formed in the following step (c).

The COF 16a may be coupled with the FPC 17 that is provided with members such as the component 23 and the B to B connector 24, as shown in FIG. 4(a). The COF 16a and the FPC 17 may be coupled at any timing.

### (b) Coupling of COF and FPC

As shown in FIG. 4(b), the COF 16a and the second end of the FPC 17a are coupled with each other. At this time, the FPC 17a is bent along the folds 22a and 22b. Also, the COF 16a and the second end of the FPC 17b are coupled with each other. At this time, the FPC 17b is bent along the folds 22c and 22d. As a result, the circuit member 3a is coupled with the liquid crystal display panel 2a and is placed on the same plane as the liquid crystal display panel 2a. In this state, the liquid crystal display panel 2a can be easily subjected to a lighting inspection using the circuit member 3a. This enables early detection of open circuits of any of the conductive lines (e.g., the signal lines 10a and 10b) of the liquid crystal display panel 2a and the conductive lines 20a and 20b of the circuit member 3a.

The circuit member 3a has a line-symmetric shape in the state shown in FIG. 4(b). This provides a more simplified shape of the circuit member 3a. The circuit member 3a may have any shape, and may have either a line-symmetric shape or a line-asymmetric shape.

### (c) Bending of FPC

The first end of the FPC 17a is bent from the front surface side toward the back surface of the liquid crystal display panel 2a along the linear outer edge portion 14a. Also, the first end of the FPC 17b is bent from the front surface side toward the back surface of the liquid crystal display panel 2a along the linear outer edge portion 14b. Thereby, the liquid crystal display device 1a is completed with a deformed shape as shown in FIG. 4(c). In the liquid crystal display device 1a, the circuit member 3a does not protrude from the liquid crystal display panel 2a. The image on the left side of FIG. 4(c) is an image seen from the front surface side. The image on the right side of FIG. 4(c) is an image seen from the back surface side.

The FPC 17a is not bent along the folds 22a and 22b in the state shown in FIG. 4(c). The FPC 17b is not bent along the folds 22c and 22d in the state shown in FIG. 4(c).

The circuit member 3a may be attached to the back surface side of the liquid crystal display panel 2a with an adhesive component. Thereby, the circuit member 3a can be easily fixed on the back surface side of the liquid crystal display panel 2a. Examples of the adhesive component include adhesive such as paste and tapes with a pressure-sensitive adhesive layer.

On back surface side of the liquid crystal display panel 2a may be mounted a backlight (the backlight 8 as shown in FIG. 2). The backlight may be mounted in either the step (b) or the step (c). When the backlight is mounted in the step (c), it has only to be inserted between the liquid crystal display panel 2a and the circuit member 3a. At this time, the FPCs 17a and 17b are not bent on the back surface side of the liquid crystal display panel 2a, so that the circuit member 3a does not hinder the mounting of the backlight.

Next, a method of favorably bending the FPC 17a along the fold 22a is described with reference to FIG. 5. FIG. 5 is a schematic cross-sectional view of a cross section taken along the C-C′ line in FIG. 4(b). As shown in FIG. 5, the FPC 17a is preferably bent with a spacer 25 in between. This can reduce a load generated in bending the FPC 17a.

The spacer 25 may be attached to the FPC 17a with an adhesive component.

The spacer 25 may be PET tape or PORON tape, for example.

The spacer 25 preferably has a thickness t of 0.6 mm or greater and 3 mm or smaller. The spacer 25 with a thickness t of 0.6 mm or greater can sufficiently reduce a load generated in bending the FPC 17a. The spacer 25 with a thickness t of 3 mm or smaller can sufficiently reduce the thickness of the bent portion of the FPC 17a.

The above describes the method of favorably bending the FPC 17a along the fold 22a, and the same applies to the case where the FPC 17a is bent along the fold 22b and to the case where the FPC 17b is bent along the folds 22c and 22d. The same also applies to the case where the COF is bent along a fold as described in other embodiments (e.g., Variation of Embodiment 1 to be mentioned later).

Next, a method of favorably bending the first end of the FPC 17a along the linear outer edge portion 14a is described with reference to FIG. 6. FIG. 6 is a schematic cross-sectional view of a cross section taken along the D-D′ line in FIG. 4(c). As shown in FIG. 6, the first end of the FPC 17a is preferably bent with an insulating resin 26 being applied to an end surface of the thin film transistor array substrate 4a. This can reduce a load generated in bending the FPC 17a.

The insulating resin 26 may be insulating resin (trade name: TUFFY) available from Hitachi Chemical Co., Ltd., for example.

The insulating resin 26 is preferably applied with a width w of 0.3 mm or greater and 3 mm or smaller. The insulating resin applied with a width w of 0.3 mm or greater can sufficiently reduce a load generated in bending the FPC 17a. The insulating resin applied with a width w of 3 mm or smaller can sufficiently reduce the degree of protrusion of the bent portion of the FPC 17a from the outer edge of the liquid crystal display panel 2a.

The above describes the method of favorably bending the first end of the FPC 17a along the linear outer edge portion 14a. The same applies to the case where the first end of the FPC 17b is bent along the linear outer edge portion 14b. The same also applies to the case where the COF is bent along the linear outer edge portion as described in other embodiments (e.g., Variation of Embodiment 1 to be mentioned later).

Embodiment 1 can provide the following effects.

(1) Since the liquid crystal display panel 2a has the linear outer edge portions 14a and 14b on the outer edge, even when the number of terminals of the liquid crystal display panel 2a is increased due to higher definition, the increased terminals can be dividedly disposed on the linear outer edge portions 14a and 14b.

(2) Since the circuit member 3a includes the FPCs 17a and 17b, even when the number of conductive lines of the circuit member 3a is increased due to higher definition, the increased conductive lines can be dividedly disposed on the FPCs 17a and 17b.

The above effects (1) and (2) enable higher definition without increasing the width of the region where the linear outer edge portion 14a and the FPC 17a are attached to each other or increasing the width of the region where the linear outer edge portion 14b and the FPC 17b are attached to each other. Therefore, the liquid crystal display device 1a with a deformed shape can be achieved having both a narrow frame and high definition.

### (Variation of Embodiment 1)

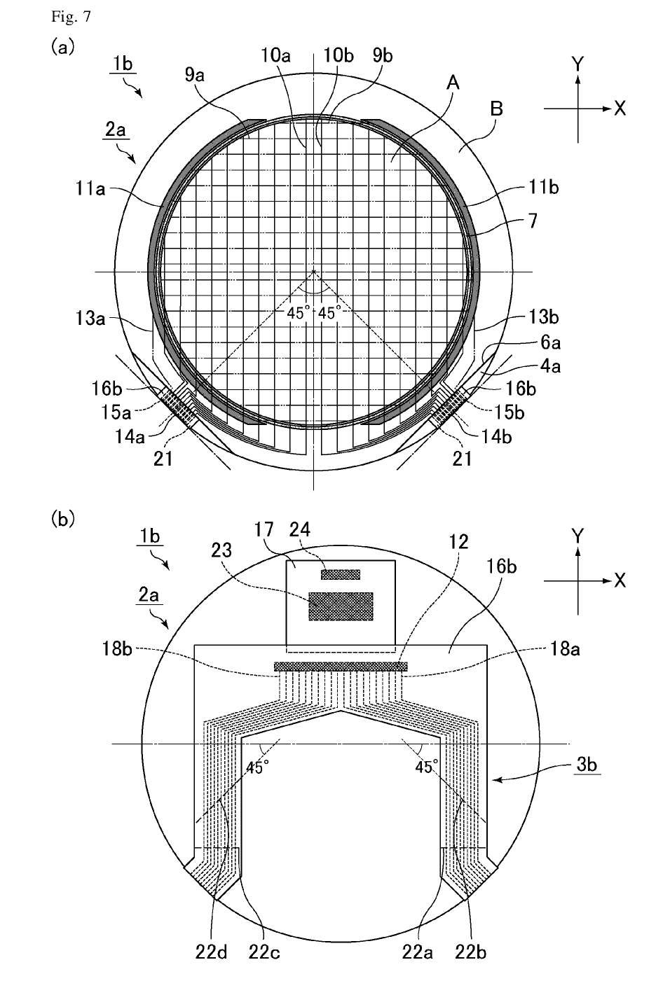

FIG. 7 are schematic plan views of a liquid crystal display device of Variation of Embodiment 1; FIG. 7(a) is a view seen from the front surface side and FIG. 7(b) is a view seen from the back surface side. Variation of Embodiment 1 is the same as Embodiment 1, except that the circuit member is changed to a COF. Thus, descriptions of the same features are omitted as appropriate.

A liquid crystal display device 1b includes the liquid crystal display panel 2a and a circuit member 3b disposed on the back surface side of the liquid crystal display panel 2a.

The circuit member 3b is a COF 16b as shown in FIG. 7(b). The COF 16b has a shape such that two branches are coupled with a main part, which corresponds to integration of the COF 16a (main part) and the FPCs 17a and 17b (branches) as shown in FIG. 1(b).

The main part of the COF 16b is provided with the signal line drive circuit 12.

A first branch of the COF 16b is provided with the conductive lines 18a. A second branch of the COF 16b is provided with the conductive lines 18b. In FIG. 7(b), only some of the conductive lines 18a and 18b are illustrated.

As shown in FIG. 7(b), the conductive lines 18a and 18b are preferably led outward relative to the signal line drive circuit 12. This enables further reduction in size of the circuit member 3b. As a result, the circuit member 3b is likely to be disposed on the back surface side of the liquid crystal display panel 2a without protruding from the liquid crystal display panel 2a.

As shown in FIG. 7(a), the linear outer edge portion 14a and the end of the first branch of the COF 16b are attached to each other via the anisotropic conductive film 21. This allows electrical coupling of the terminals 15a of the liquid crystal display panel 2a and the conductive lines 18a of the COF 16b via the anisotropic conductive film 21. Also, the linear outer edge portion 14b and the end of the second branch of the COF 16b are attached to each other via the anisotropic conductive film 21. This allows electrical coupling of the terminals 15b of the liquid crystal display panel 2a and the conductive lines 18b of the COF 16b via the anisotropic conductive film 21. The linear outer edge portion 14a (14b) and the end of the first (second) branch of the COF 16b may be directly coupled without any member such as the anisotropic conductive film 21.

As a result, the signal line drive circuit 12 and the terminals 15a are electrically coupled via the conductive lines 18a. Also, the signal line drive circuit 12 and the terminals 15b are electrically coupled via the conductive lines 18b. Thereby, voltage (data signal) output from the signal line drive circuit 12 is applied (supplied) to the liquid crystal display panel 2a and an image is displayed.

As shown in FIGS. 7(a) and 7(b), the end of the first branch of the COF 16b is bent from the front surface side toward the back surface of the liquid crystal display panel 2a along the linear outer edge portion 14a. Also, the end of the second branch of the COF 16b is bent from the front surface side toward the back surface of the liquid crystal display panel 2a along the linear outer edge portion 14b.

As shown in FIG. 7(b), the main part of the COF 16b is disposed on the back surface side of the liquid crystal display panel 2a.

The signal line drive circuit 12 is disposed on the COF 16b so as to face the liquid crystal display panel 2a in the state shown in FIG. 7(b).

The conductive lines 18a and 18b are disposed on the COF 16b so as to face the liquid crystal display panel 2a in the state shown in FIG. 7(b).

The first branch of the COF 16b has the folds 22a and 22b which are not bent in the state shown in FIG. 7(b). Also, the second branch of the COF 16b has the folds 22c and 22d which are not bent in the state shown in FIG. 7(b).

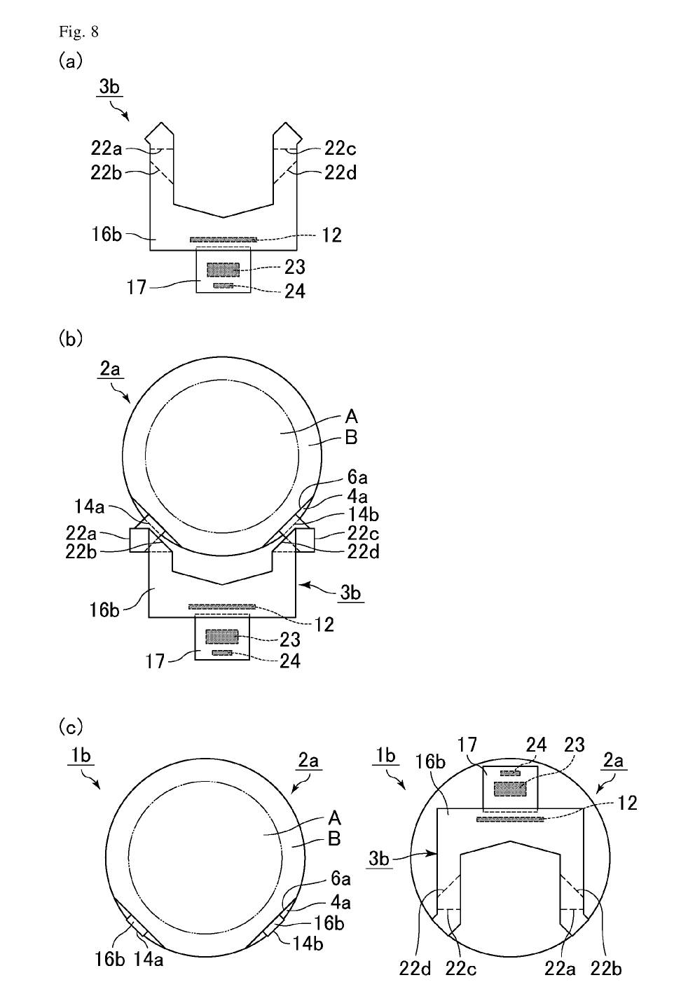

Next, a process of coupling the circuit member 3b with the liquid crystal display panel 2a and bending the circuit member 3b toward the back surface of the liquid crystal display panel 2a is described with reference to FIG. 8. FIG. 8 are schematic plan views illustrating a process of coupling a circuit member of Variation of Embodiment 1 with a liquid crystal display panel and bending the circuit member toward the back surface of the liquid crystal display panel (steps (a) to (c)). In FIG. 8, conductive lines and other members of the liquid crystal display panel and circuit member are omitted as appropriate.

### (a) Preparation of COF

As shown in FIG. 8(a), the COF 16b is prepared as the circuit member 3b.

### (b) Coupling of Liquid Crystal Display Panel and COF

As shown in FIG. 8(b), the linear outer edge portion 14a and the end of the first branch of the COF 16b are attached to each other. At this time, the first branch of the COF 16b is bent along the folds 22a and 22b. Also, the linear outer edge portion 14b and the end of the second branch of the COF 16b are attached to each other. At this time, the second branch of the COF 16b is bent along the folds 22c and 22d. As a result, the circuit member 3b is coupled with the liquid crystal display panel 2a and is placed on the same plane as the liquid crystal display panel 2a.

### (c) Bending of COF

The end of the first branch of the COF 16b is bent from the front surface side toward the back surface of the liquid crystal display panel 2a along the linear outer edge portion 14a. Also, the end of the second branch of the COF 16b is bent from the front surface side toward the back surface of the liquid crystal display panel 2a along the linear outer edge portion 14b. Thereby, the liquid crystal display device 1b is completed with a deformed shape as shown in FIG. 8(c). In the liquid crystal display device 1b, the circuit member 3b does not protrude from the liquid crystal display panel 2a. The image on the left side of FIG. 8(c) is an image seen from the front surface side. The image on the right side of FIG. 8(c) is an image seen from the back surface side.

The first branch of the COF 16b is not bent along the folds 22a and 22b in the state shown in FIG. 8(c). The second branch of the COF 16b is not bent along the folds 22c and 22d in the state shown in FIG. 8(c).

Since the COF 16b is used as the circuit member 3b, Variation of Embodiment 1 can eliminate the step of coupling the COF 16a with the FPCs 17a and 17b, such as the step (b) in Embodiment 1. As a result, Variation of Embodiment 1 can achieve reduction in the process cost and improvement in the yield in comparison with Embodiment 1.

### Embodiment 2

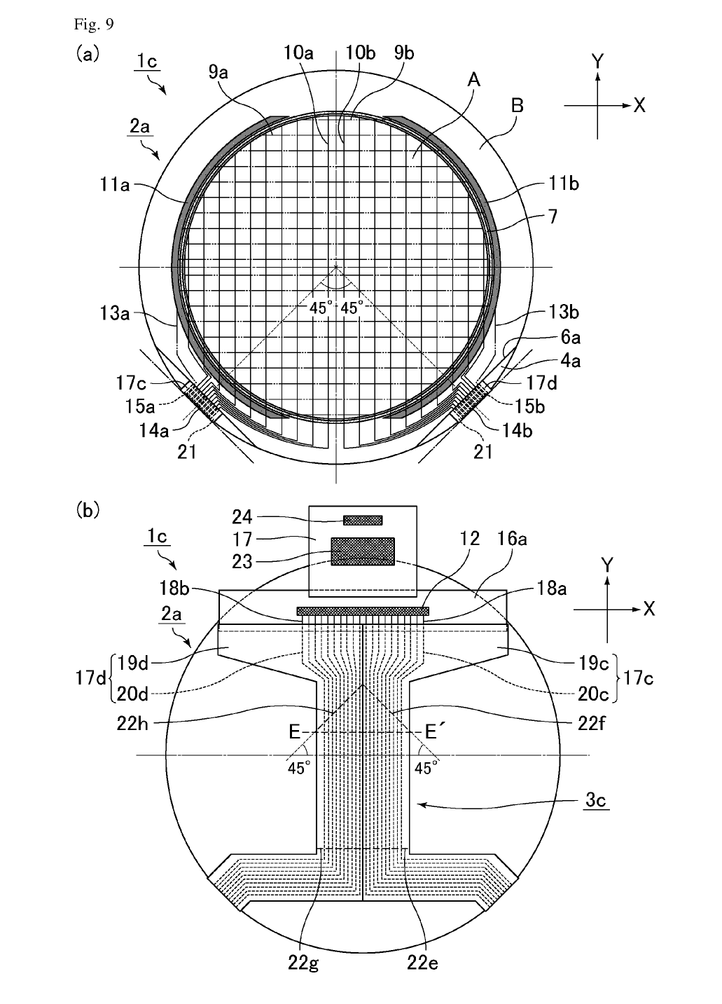

FIG. 9 are schematic plan views of a liquid crystal display device of Embodiment 2; FIG. 9(a) is a view seen from the front surface side and FIG. 9(b) is a view seen from the back surface side (before the circuit member is bent). FIGS. 9(a) and 9(b) do not completely correspond to each other in that part of the circuit member protrudes from the liquid crystal display panel in FIG. 9(b). Still, for convenience of description, FIG. 9(b) illustrates the state before the circuit member is folded up. Embodiment 2 is the same as Embodiment 1, except that the shape of the circuit member is changed. Thus, descriptions of the same features are omitted as appropriate.

A liquid crystal display device 1c includes the liquid crystal display panel 2a and a circuit member 3c disposed on the back surface side of the liquid crystal display panel 2a.

As shown in FIG. 9(b), the circuit member 3c includes the COF 16a (main part) and FPCs 17c and 17d (branches) coupled with the COF 16a.

The FPC 17c includes a flexible substrate 19c and multiple conductive lines 20c. A first end of the FPC 17c is provided with ends of the conductive lines 20c or a conductive portion electrically coupled with the conductive lines 20c. A second end of the FPC 17c is provided with multiple FPC terminals (not shown) electrically coupled with the respective conductive lines 20c in an independent manner. The FPC 17d includes a flexible substrate 19d and multiple conductive lines 20d. A first end of the FPC 17d is provided with ends of the conductive lines 20d or a conductive portion electrically coupled with the conductive lines 20d. A second end of the FPC 17d is provided with multiple FPC terminals (not shown) electrically coupled with the respective conductive lines 20d in an independent manner. In FIG. 9(b), only some of the conductive lines 20c and 20d are illustrated.

As shown in FIG. 9(b), the conductive lines 20c and 20d are led inward relative to the signal line drive circuit 12. In this case, the size of the circuit member 3c increases in comparison with the circuit member 3a of Embodiment 1. As a result, the circuit member 3c may unfortunately protrude from the liquid crystal display panel 2a in a state of being bent toward the back surface of the liquid crystal display panel 2a as shown in FIG. 9(b). If the circuit member 3c protrudes from the liquid crystal display panel 2a, the circuit member 3c may be bent at any position (for example, at the E-E′ line in FIG. 9(b)). Thereby, the circuit member 3c can be folded up on the back surface side of the liquid crystal display panel 2a. As a result, the liquid crystal display device 1c can be obtained with a deformed shape and with the circuit member 3c not protruding from the liquid crystal display panel 2a, as shown in FIG. 9(a).

As shown in FIG. 9(a), the linear outer edge portion 14a and the first end of the FPC 17c are attached to each other via the anisotropic conductive film 21. This allows electrical coupling of the terminals 15a of the liquid crystal display panel 2a and the conductive lines 20c of the FPC 17c via the anisotropic conductive film 21. Also, the linear outer edge portion 14b and the first end of the FPC 17d are attached to each other via the anisotropic conductive film 21. This allows electrical coupling of the terminals 15b of the liquid crystal display panel 2a and the conductive lines 20d of the FPC 17d via the anisotropic conductive film 21.

As shown in FIG. 9(b), the COF 16a and the second end of the FPC 17c are coupled with each other. This allows electrical coupling of the conductive lines 18a of the COF 16a and the conductive lines 20c of the FPC 17c. Also, the COF 16a and the second end of the FPC 17d are coupled with each other. This allows electrical coupling of the conductive lines 18b of the COF 16a and the conductive lines 20d of the FPC 17d.

As a result, the signal line drive circuit 12 and the terminals 15a are electrically coupled via the conductive lines 18a and 20c. Also, the signal line drive circuit 12 and the terminals 15b are electrically coupled via the conductive lines 18b and 20d.

As shown in FIGS. 9(a) and 9(b), the first end of the FPC 17c is bent from the front surface side toward the back surface of the liquid crystal display panel 2a along the linear outer edge portion 14a. Also, the first end of the FPC 17d is bent from the front surface side toward the back surface of the liquid crystal display panel 2a along the linear outer edge portion 14b.

As shown in FIG. 9(b), the COF 16a is disposed on the back surface side of the liquid crystal display panel 2a.

The signal line drive circuit 12 is disposed on the COF 16a so as to be opposite to the liquid crystal display panel 2a in the state shown in FIG. 9(b).

The conductive lines 20c (20d) are disposed on the flexible substrate 19c (19d) so as to face the liquid crystal display panel 2a in the state shown in FIG. 9(b).

The FPC 17c has folds 22e and 22f which are not bent in the state shown in FIG. 9(b). Preferably, one of the folds 22e and 22f is a mountain fold and the other is a valley fold. In the present embodiment, the fold 22e is a valley fold and the fold 22f is a mountain fold in the state shown in FIG. 9(b). Also, the FPC 17d has folds 22g and 22h which are not bent in the state shown in FIG. 9(b). Preferably, one of the folds 22g and 22h is a mountain fold and the other is a valley fold. In the present embodiment, the fold 22g is a valley fold and the fold 22h is a mountain fold in the state shown in FIG. 9(b).

In the present embodiment, the direction of each of the folds 22e and 22g and the X direction (the horizontal direction in FIG. 9(b)) form an angle of 0° (parallel), while the direction of each of the folds 22f and 22h and the X direction form an angle of 45°, in the state shown in FIG. 9(b).

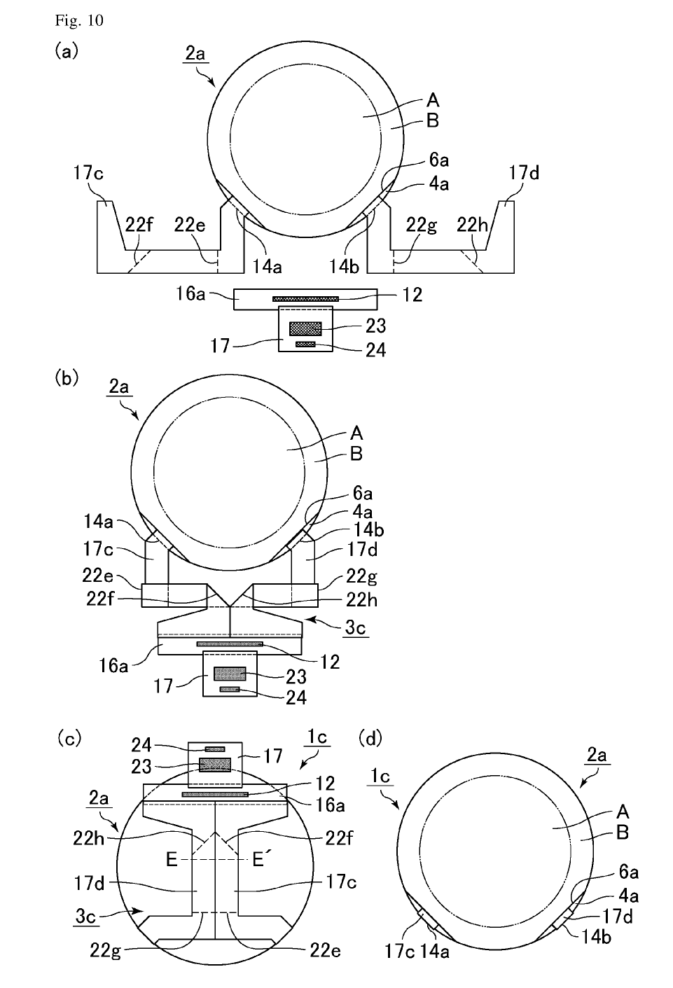

Next, a process of coupling the circuit member 3c with the liquid crystal display panel 2a and bending the circuit member 3c toward the back surface of the liquid crystal display panel 2a is described with reference to FIG. 10. FIG. 10 are schematic plan views illustrating a process of coupling a circuit member of Embodiment 2 with a liquid crystal display panel and bending the circuit member toward the back surface of the liquid crystal display panel (steps (a) to (d)). In FIG. 10, conductive lines and other members of the liquid crystal display panel and circuit member are omitted as appropriate.

### (a) Coupling of Liquid Crystal Display Panel and FPC

As shown in FIG. 10(a), the linear outer edge portion 14a and the first end of the FPC 17c are attached to each other. Also, the linear outer edge portion 14b and the first end of the FPC 17d are attached to each other. The COF 16a is prepared.

The FPC 17c has the folds 22e and 22f in addition to the fold along the linear outer edge portion 14a to be formed in the following step (c). The FPC 17d has the folds 22g and 22h in addition to the fold along the linear outer edge portion 14b to be formed in the following step (c).

### (b) Coupling of COF and FPC

As shown in FIG. 10(b), the COF 16a and the second end of the FPC 17c are coupled with each other. At this time, the FPC 17c is bent along the folds 22e and 22f. Also, the COF 16a and the second end of the FPC 17d are coupled with each other. At this time, the FPC 17d is bent along the folds 22g and 22h. As a result, the circuit member 3c is coupled with the liquid crystal display panel 2a and is placed on the same plane as the liquid crystal display panel 2a.

### (c) Bending of FPC

The first end of the FPC 17c is bent from the front surface side toward the back surface of the liquid crystal display panel 2a along the linear outer edge portion 14a. Also, the first end of the FPC 17d is bent from the front surface side toward the back surface of the liquid crystal display panel 2a along the linear outer edge portion 14b. Thereby, the circuit member 3c is bent toward the back surface of the liquid crystal display panel 2a, as shown in FIG. 10(c). FIG. 10(c) is a view seen from the back surface side.

The FPC 17c is not bent along the folds 22e and 22f in the state shown in FIG. 10(c). The FPC 17d is not bent along the folds 22g and 22h in the state shown in FIG. 10(c).

### (d) Folding Up of Circuit Member

As shown in FIG. 10(c), the circuit member 3c protrudes from the liquid crystal display panel 2a. In this case, the circuit member 3c may be bent at any position of the FPCs 17c and 17d (for example, at the E-E′ line in FIG. 10(c)). Thereby, the circuit member 3c can be folded up on the back surface side of the liquid crystal display panel 2a. As a result, the liquid crystal display device 1c can be obtained with a deformed shape and with the circuit member 3c not protruding from the liquid crystal display panel 2a, as shown in FIG. 10(d). FIG. 10(d) is a view seen from the front surface side.

### (Variation of Embodiment 2)

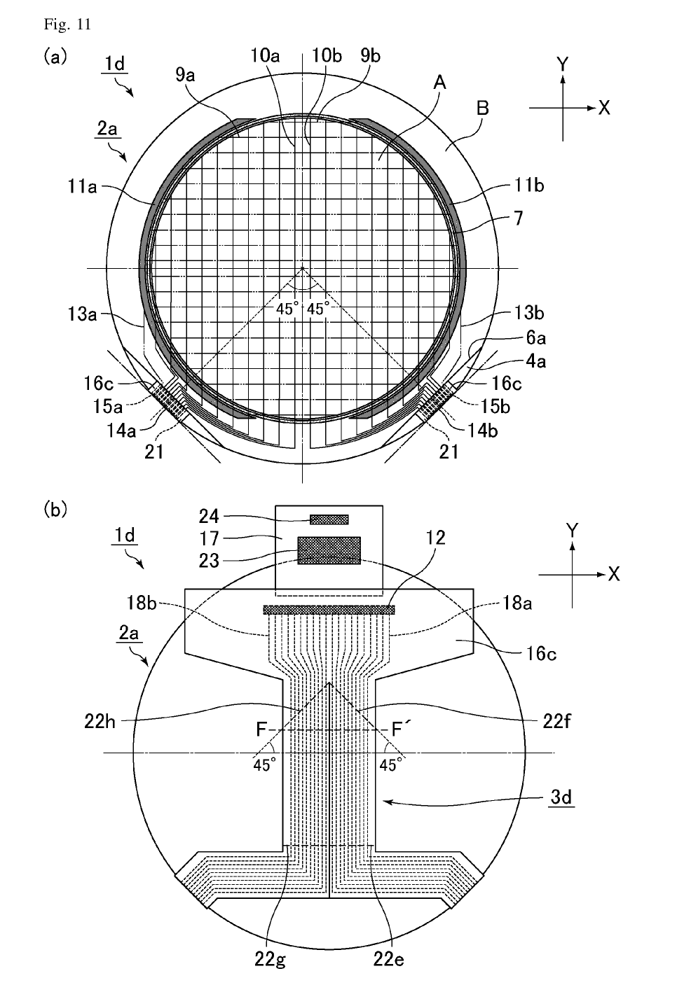

FIG. 11 are schematic plan views of a liquid crystal display device of Variation of Embodiment 2; FIG. 11(a) is a view seen from the front surface side and FIG. 11(b) is a view seen from the back surface side (before the circuit member is bent). FIGS. 11(a) and 11(b) do not completely correspond to each other in that part of the circuit member protrudes from the liquid crystal display panel in FIG. 11(b). Still, for convenience of description, FIG. 11(b) illustrates the state before the circuit member is folded up. Variation of Embodiment 2 is the same as Embodiment 2, except that the circuit member is changed to a COF. Thus, descriptions of the same features are omitted as appropriate.

A liquid crystal display device 1d includes the liquid crystal display panel 2a and a circuit member 3d disposed on the back surface side of the liquid crystal display panel 2a.

The circuit member 3d is a COF 16c as shown in FIG. 11(b). The COF 16c has a shape such that two branches are coupled with a main part, which corresponds to integration of the COF 16a (main part) and the FPCs 17c and 17d (branches) as shown in FIG. 9(b).

The main part of the COF 16c is provided with the signal line drive circuit 12.

A first branch of the COF 16c is provided with the conductive lines 18a. A second branch of the COF 16c is provided with the conductive lines 18b. In FIG. 11(b), only some of the conductive lines 18a and 18b are illustrated.

As shown in FIG. 11(b), the conductive lines 18a and 18b are led inward relative to the signal line drive circuit 12. In this case, the size of the circuit member 3d increases in comparison with the circuit member 3b of Variation of Embodiment 1. As a result, the circuit member 3d may unfortunately protrude from the liquid crystal display panel 2a in a state of being bent toward the back surface of the liquid crystal display panel 2a as shown in FIG. 11(b). If the circuit member 3d protrudes from the liquid crystal display panel 2a, the circuit member 3d may be bent at any position (for example, at the F-F′ line in FIG. 11(b)). Thereby, the circuit member 3d can be folded up on the back surface side of the liquid crystal display panel 2a. As a result, the liquid crystal display device 1d can be obtained with a deformed shape and with the circuit member 3d not protruding from the liquid crystal display panel 2a, as shown in FIG. 11(a).

As shown in FIG. 11(a), the linear outer edge portion 14a and the end of the first branch of the COF 16c are attached to each other via the anisotropic conductive film 21. This allows electrical coupling of the terminals 15a of the liquid crystal display panel 2a and the conductive lines 18a of the COF 16c via the anisotropic conductive film 21. Also, the linear outer edge portion 14b and the end of the second branch of the COF 16c are attached to each other via the anisotropic conductive film 21. This allows electrical coupling of the terminals 15b of the liquid crystal display panel 2a and the conductive lines 18b of the COF 16c via the anisotropic conductive film 21.

As a result, the signal line drive circuit 12 and the terminals 15a are electrically coupled via the conductive lines 18a. Also, the signal line drive circuit 12 and the terminals 15b are electrically coupled via the conductive lines 18b.

As shown in FIGS. 11(a) and 11(b), the end of the first branch of the COF 16c is bent from the front surface side toward the back surface of the liquid crystal display panel 2a along the linear outer edge portion 14a. Also, the end of the second branch of the COF 16c is bent from the front surface side toward the back surface of the liquid crystal display panel 2a along the linear outer edge portion 14b.

As shown in FIG. 11(b), the main part of the COF 16c is disposed on the back surface side of the liquid crystal display panel 2a.

The signal line drive circuit 12 is disposed on the COF 16c so as to face the liquid crystal display panel 2a in the state shown in FIG. 11(b).

The conductive lines 18a and 18b are disposed on the COF 16c so as to face the liquid crystal display panel 2a in the state shown in FIG. 11(b).

The first branch of the COF 16c has the folds 22e and 22f which are not bent in the state shown in FIG. 11(b). Also, the second branch of the COF 16c has the folds 22g and 22h which are not bent in the state shown in FIG. 11(b).

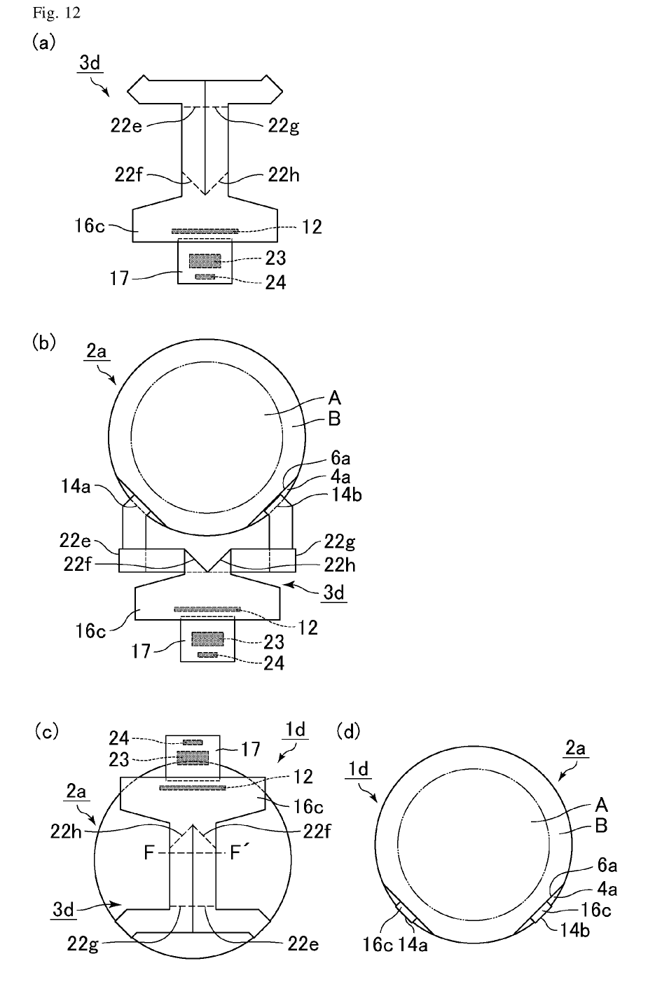

Next, a process of coupling the circuit member 3d with the liquid crystal display panel 2a and bending the circuit member 3d toward the back surface of the liquid crystal display panel 2a is described with reference to FIG. 12. FIG. 12 are schematic plan views illustrating a process of coupling a circuit member of Variation of Embodiment 2 with a liquid crystal display panel and bending the circuit member toward the back surface of the liquid crystal display panel (steps (a) to (d)). In FIG. 12, conductive lines and other members of the liquid crystal display panel and circuit member are omitted as appropriate.

### (a) Preparation of COF

As shown in FIG. 12(a), the COF 16c is prepared as the circuit member 3d.

### (b) Coupling of Liquid Crystal Display Panel and COF

As shown in FIG. 12(b), the linear outer edge portion 14a and the end of the first branch of the COF 16c are attached to each other. At this time, the first branch of the COF 16c is bent along the folds 22e and 22f. Also, the linear outer edge portion 14b and the end of the second branch of the COF 16c are attached to each other. At this time, the second branch of the COF 16c is bent along the folds 22g and 22h. As a result, the circuit member 3d is coupled with the liquid crystal display panel 2a and is placed on the same plane as the liquid crystal display panel 2a.

### (c) Bending of COF

The end of the first branch of the COF 16c is bent from the front surface side toward the back surface of the liquid crystal display panel 2a along the linear outer edge portion 14a. Also, the end of the second branch of the COF 16c is bent from the front surface side toward the back surface of the liquid crystal display panel 2a along the linear outer edge portion 14b. Thereby, the circuit member 3d is bent toward the back surface of the liquid crystal display panel 2a, as shown in FIG. 12(c). FIG. 12(c) is a view seen from the back surface side.

The first branch of the COF 16c is not bent along the folds 22e and 22f in the state shown in FIG. 12(c). The second branch of the COF 16c is not bent along the folds 22g and 22h in the state shown in FIG. 12(c).

### (d) Folding Up of Circuit Member

As shown in FIG. 12(c), the circuit member 3d protrudes from the liquid crystal display panel 2a. In this case, the circuit member 3d may be bent at any position of the COF 16c (for example, at the F-F line in FIG. 12(c)). Thereby, the circuit member 3d can be folded up on the back surface side of the liquid crystal display panel 2a. As a result, the liquid crystal display device 1d can be obtained with a deformed shape and with the circuit member 3d not protruding from the liquid crystal display panel 2a, as shown in FIG. 12(d). FIG. 12(d) is a view seen from the front surface side.

Since the COF 16c is used as the circuit member 3d, Variation of Embodiment 2 can eliminate the step of coupling the COF 16a with the FPCs 17c and 17d, such as the step (b) in Embodiment 2. As a result, Variation of Embodiment 2 can achieve reduction in the process cost and improvement in the yield in comparison with Embodiment 2.

### Embodiment 3

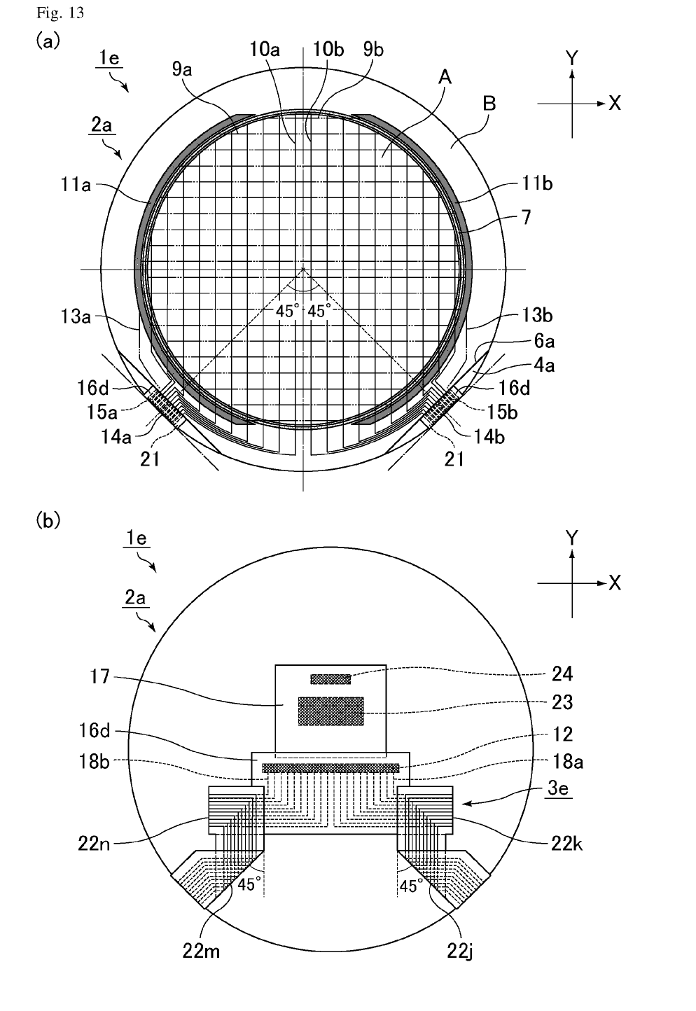

FIG. 13 are schematic plan views of a liquid crystal display device of Embodiment 3; FIG. 13(a) is a view seen from the front surface side and FIG. 13(b) is a view seen from the back surface side. Embodiment 3 is the same as Variation of Embodiment 1, except that the shape of the circuit member is changed. Thus, descriptions of the same features are omitted as appropriate.

A liquid crystal display device 1e includes the liquid crystal display panel 2a and a circuit member 3e disposed on the back surface side of the liquid crystal display panel 2a.

The circuit member 3e is a COF 16d as shown in FIG. 13(b). The COF 16d has a shape such that two branches are coupled with a main part.

The main part of the COF 16d is provided with the signal line drive circuit 12.

A first branch of the COF 16d is provided with the conductive lines 18a. A second branch of the COF 16d is provided with the conductive lines 18b. In FIG. 13(b), only some of the conductive lines 18a and 18b are illustrated.

As shown in FIG. 13(a), the linear outer edge portion 14a and the end of the first branch of the COF 16d are attached to each other via the anisotropic conductive film 21. This allows electrical coupling of the terminals 15a of the liquid crystal display panel 2a and the conductive lines 18a of the COF 16d via the anisotropic conductive film 21. Also, the linear outer edge portion 14b and the end of the second branch of the COF 16d are attached to each other via the anisotropic conductive film 21. This allows electrical coupling of the terminals 15b of the liquid crystal display panel 2a and the conductive lines 18b of the COF 16d via the anisotropic conductive film 21.

As a result, the signal line drive circuit 12 and the terminals 15a are electrically coupled via the conductive lines 18a. Also, the signal line drive circuit 12 and the terminals 15b are electrically coupled via the conductive lines 18b.

As shown in FIGS. 13(a) and 13(b), the end of the first branch of the COF 16d is bent from the front surface side toward the back surface of the liquid crystal display panel 2a along the linear outer edge portion 14a. Also, the end of the second branch of the COF 16d is bent from the front surface side toward the back surface of the liquid crystal display panel 2a along the linear outer edge portion 14b.

The first branch of the COF 16d is bent along folds 22j and 22k in the state shown in FIG. 13(b). Preferably, one of the folds 22j and 22k is a mountain fold and the other is a valley fold. In the present embodiment, the fold 22j is a mountain fold and the fold 22k is a valley fold in the state shown in FIG. 13(b). Also, the second branch of the COF 16d is bent along folds 22m and 22n in the state shown in FIG. 13(b). Preferably, one of the folds 22m and 22n is a mountain fold and the other is a valley fold. In the present embodiment, the fold 22m is a mountain fold and the fold 22n is a valley fold in the state shown in FIG. 13(b).

In the present embodiment, the direction of each of the folds 22j and 22m and the Y direction (the vertical direction in FIG. 13(b)) form an angle of 45°, while the direction of each of the folds 22k and 22n and the Y direction form an angle of 0° (parallel), in the state shown in FIG. 13(b).

As shown in FIG. 13(b), the main part of the COF 16d is disposed on the back surface side of the liquid crystal display panel 2a.

The signal line drive circuit 12 is disposed on the COF 16d so as to face the liquid crystal display panel 2a in the state shown in FIG. 13(b).

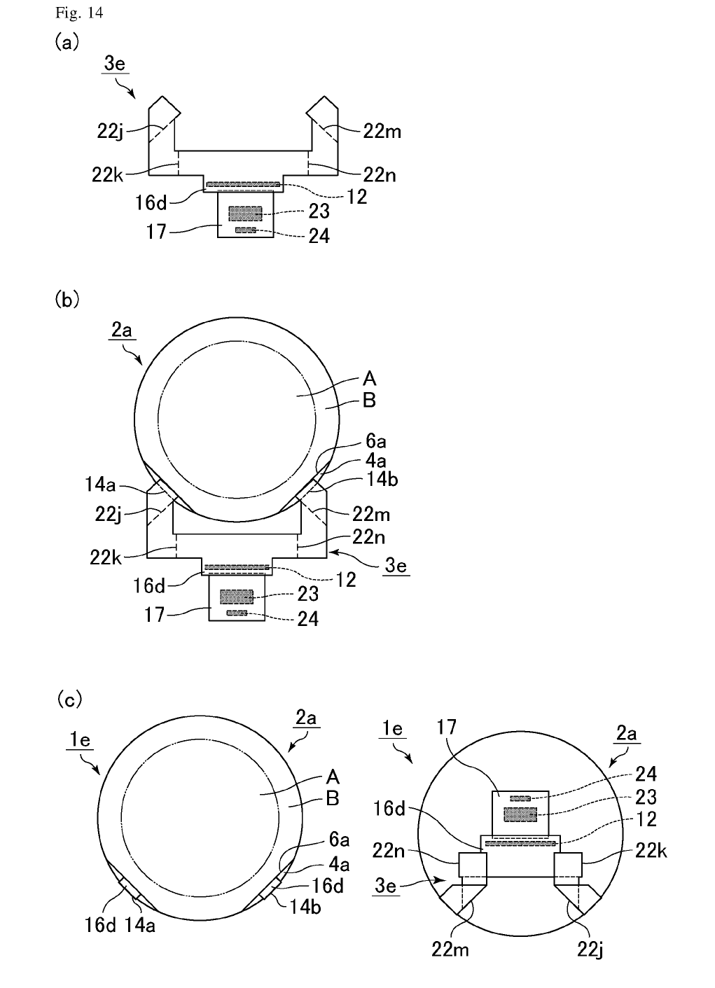

Next, a process of coupling the circuit member 3e with the liquid crystal display panel 2a and bending the circuit member 3e toward the back surface of the liquid crystal display panel 2a is described with reference to FIG. 14. FIG. 14 are schematic plan views illustrating a process of coupling a circuit member of Embodiment 3 with a liquid crystal display panel and bending the circuit member toward the back surface of the liquid crystal display panel (steps (a) to (c)). In FIG. 14, conductive lines and other members of the liquid crystal display panel and circuit member are omitted as appropriate.

### (a) Preparation of COF

As shown in FIG. 14(a), the COF 16d is prepared as the circuit member 3e.

The first branch of the COF 16d has the folds 22j and 22k in addition to the fold along the linear outer edge portion 14a to be formed in the following step (c). The second branch of the COF 16d has the folds 22m and 22n in addition to the fold along the linear outer edge portion 14b to be formed in the following step (c).

### (b) Coupling of Liquid Crystal Display Panel and COF

As shown in FIG. 14(b), the linear outer edge portion 14a and the end of the first branch of the COF 16d are attached to each other. At this time, the first branch of the COF 16d is not bent along the folds 22j and 22k. Also, the linear outer edge portion 14b and the end of the second branch of the COF 16d are attached to each other. At this time, the second branch of the COF 16d is not bent along the folds 22m and 22n. As a result, the circuit member 3e is coupled with the liquid crystal display panel 2a and is placed on the same plane as the liquid crystal display panel 2a.

### (c) Bending of COF

The end of the first branch of the COF 16d is bent from the front surface side toward the back surface of the liquid crystal display panel 2a along the linear outer edge portion 14a. Also, the end of the second branch of the COF 16d is bent from the front surface side toward the back surface of the liquid crystal display panel 2a along the linear outer edge portion 14b. Then, the first branch of the COF 16d is bent along the folds 22j and 22k and the second branch of the COF 16d is bent along the folds 22m and 22n. Thereby, the liquid crystal display device 1e is completed with a deformed shape as shown in FIG. 14(c). In the liquid crystal display device 1e, the circuit member 3e does not protrude from the liquid crystal display panel 2a. The image on the left side of FIG. 14(c) is an image seen from the front surface side. The image on the right side of FIG. 14(c) is an image seen from the back surface side.

### (Variation 1 of Embodiment 3)

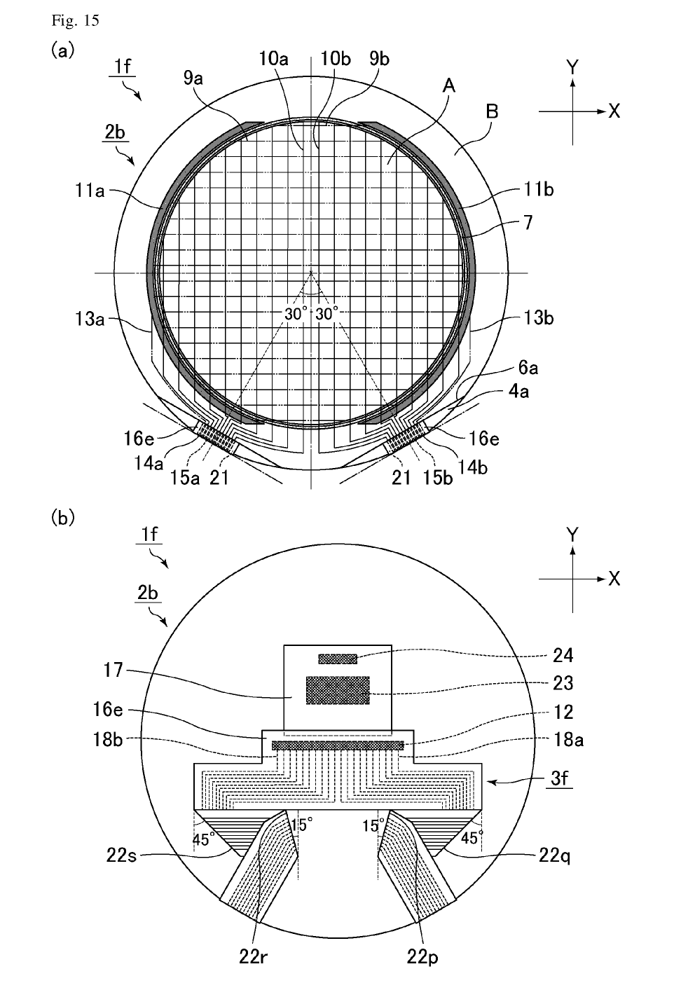

FIG. 15 are schematic plan views of a liquid crystal display device of Variation 1 of Embodiment 3; FIG. 15(a) is a view seen from the front surface side and FIG. 15(b) is a view seen from the back surface side. Variation 1 of Embodiment 3 is the same as Embodiment 3, except that the positions of the two linear outer edge portions of the liquid crystal display panel and the shape of the circuit member are changed. Thus, descriptions of the same features are omitted as appropriate.

A liquid crystal display device 1f includes a liquid crystal display panel 2b and a circuit member 3f disposed on the back surface side of the liquid crystal display panel 2b.

The liquid crystal display panel 2b has the linear outer edge portions 14a and 14b on the outer edge. In the present variation, the direction perpendicular to the linear outer edge portion 14a (14b) and the Y direction (the vertical direction in FIG. 15(a)) form an angle of 30° in the state shown in FIG. 15(a). In this case, the signal lines 10a (10b) can be led substantially equally to the terminals 15a (15b) with the line extending in the direction perpendicular to the linear outer edge portion 14a (14b) (the dotted line in FIG. 15(a)) serving as the boundary. Thus, the frame region B can be the narrowest.

The circuit member 3f is a COF 16e as shown in FIG. 15(b). The COF 16e has a shape such that two branches are coupled with a main part.

The main part of the COF 16e is provided with the signal line drive circuit 12.

A first branch of the COF 16e is provided with the conductive lines 18a. A second branch of the COF 16e is provided with the conductive lines 18b. In FIG. 15(b), only some of the conductive lines 18a and 18b are illustrated.

As shown in FIG. 15(a), the linear outer edge portion 14a and the end of the first branch of the COF 16e are attached to each other via the anisotropic conductive film 21. This allows electrical coupling of the terminals 15a of the liquid crystal display panel 2b and the conductive lines 18a of the COF 16e via the anisotropic conductive film 21. Also, the linear outer edge portion 14b and the end of the second branch of the COF 16e are attached to each other via the anisotropic conductive film 21. This allows electrical coupling of the terminals 15b of the liquid crystal display panel 2b and the conductive lines 18b of the COF 16e via the anisotropic conductive film 21.

As a result, the signal line drive circuit 12 and the terminals 15a are electrically coupled via the conductive lines 18a. Also, the signal line drive circuit 12 and the terminals 15b are electrically coupled via the conductive lines 18b.

As shown in FIGS. 15(a) and 15(b), the end of the first branch of the COF 16e is bent from the front surface side toward the back surface of the liquid crystal display panel 2b along the linear outer edge portion 14a. Also, the end of the second branch of the COF 16e is bent from the front surface side toward the back surface of the liquid crystal display panel 2b along the linear outer edge portion 14b.

The first branch of the COF 16e is bent along folds 22p and 22q in the state shown in FIG. 15(b). Preferably, one of the folds 22p and 22q is a mountain fold and the other is a valley fold. In the present variation, the fold 22p is a mountain fold and the fold 22q is a valley fold in the state shown in FIG. 15(b). Also, the second branch of the COF 16e is bent along folds 22r and 22s in the state shown in FIG. 15(b). Preferably, one of the folds 22r and 22s is a mountain fold and the other is a valley fold. In the present variation, the fold 22r is a mountain fold and the fold 22s is a valley fold in the state shown in FIG. 15(b).

In the present variation, the direction of each of the folds 22p and 22r and the Y direction (the vertical direction in FIG. 15(b)) form an angle of 15°, while the direction of each of the folds 22q and 22s and the Y direction form an angle of 45°, in the state shown in FIG. 15(b).

As shown in FIG. 15(b), the main part of the COF 16e is disposed on the back surface side of the liquid crystal display panel 2b.

The signal line drive circuit 12 is disposed on the COF 16e so as to face the liquid crystal display panel 2b in the state shown in FIG. 15(b).

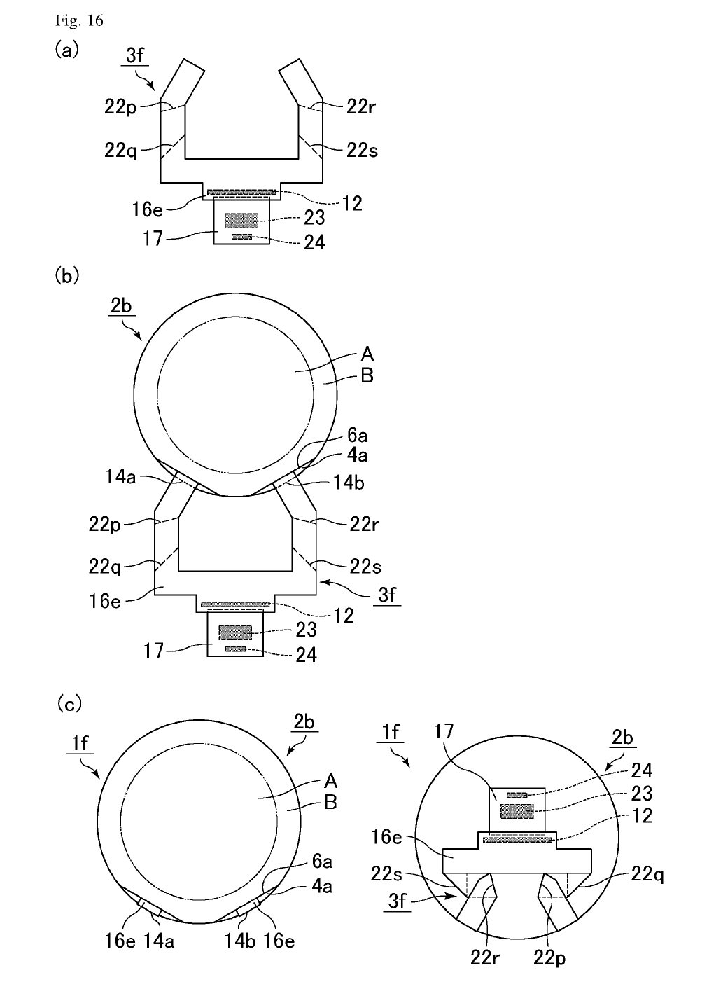

Next, a process of coupling the circuit member 3f with the liquid crystal display panel 2b and bending the circuit member 3f toward the back surface of the liquid crystal display panel 2b is described with reference to FIG. 16. FIG. 16 are schematic plan views illustrating a process of coupling a circuit member of Variation 1 of Embodiment 3 with a liquid crystal display panel and bending the circuit member toward the back surface of the liquid crystal display panel (steps (a) to (c)). In FIG. 16, conductive lines and other members of the liquid crystal display panel and circuit member are omitted as appropriate.

### (a) Preparation of COF

As shown in FIG. 16(a), the COF 16e is prepared as the circuit member 3f.

The first branch of the COF 16e has the folds 22p and 22q in addition to the fold along the linear outer edge portion 14a to be formed in the following step (c). The second branch of the COF 16e has the folds 22r and 22s in addition to the fold along the linear outer edge portion 14b to be formed in the following step (c).

### (b) Coupling of Liquid Crystal Display Panel and COF

As shown in FIG. 16(b), the linear outer edge portion 14a and the end of the first branch of the COF 16e are attached to each other. At this time, the first branch of the COF 16e is not bent along the folds 22p and 22q. Also, the linear outer edge portion 14b and the end of the second branch of the COF 16e are attached to each other. At this time, the second branch of the COF 16e is not bent along the folds 22r and 22s. As a result, the circuit member 3f is coupled with the liquid crystal display panel 2b and is placed on the same plane as the liquid crystal display panel 2b.

### (c) Bending of COF

The end of the first branch of the COF 16e is bent from the front surface side toward the back surface of the liquid crystal display panel 2b along the linear outer edge portion 14a. Also, the end of the second branch of the COF 16e is bent from the front surface side toward the back surface of the liquid crystal display panel 2b along the linear outer edge portion 14b. Then, the first branch of the COF 16e is bent along the folds 22p and 22q and the second branch of the COF 16e is bent along the folds 22r and 22s. Thereby, the liquid crystal display device 1f is completed with a deformed shape as shown in FIG. 16(c). In the liquid crystal display device 1f, the circuit member 3f does not protrude from the liquid crystal display panel 2b. The image on the left side of FIG. 16(c) is an image seen from the front surface side. The image on the right side of FIG. 16(c) is an image seen from the back surface side.

Since the direction perpendicular to the linear outer edge portion 14a (14b) and the Y direction (the vertical direction in FIG. 15(a)) form an angle of 30°, Variation 1 of Embodiment 3 can achieve the narrowest frame region B. This also allows the width of the COF 16e to be short, and thus enables cost reduction relating to the COF 16e.

### (Variation 2 of Embodiment 3)

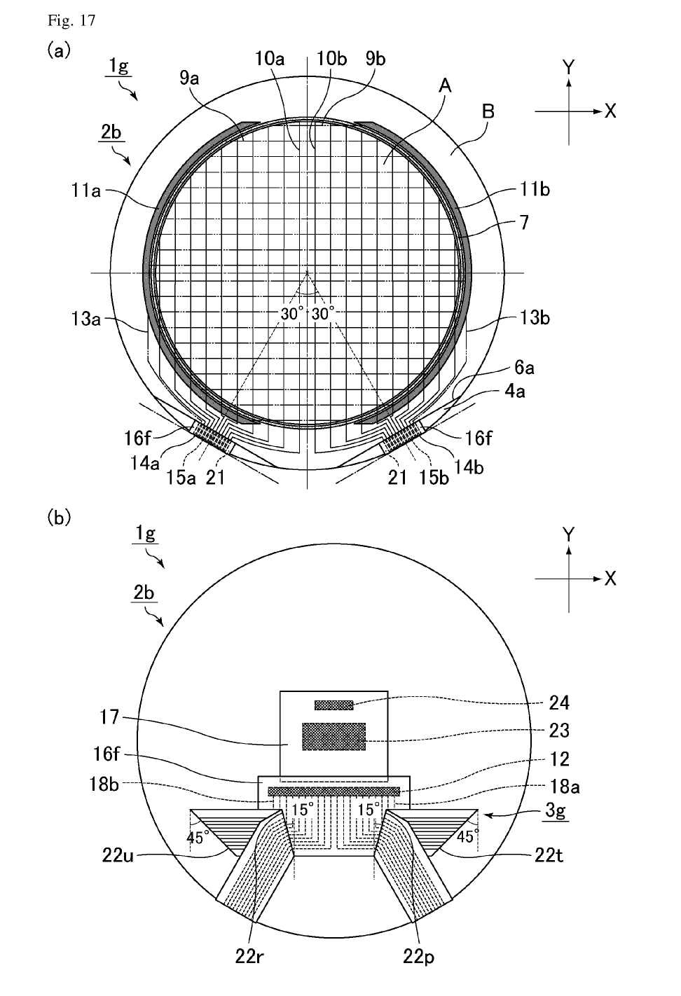

FIG. 17 are schematic plan views of a liquid crystal display device of Variation 2 of Embodiment 3; FIG. 17(a) is a view seen from the front surface side and FIG. 17(b) is a view seen from the back surface side. Variation 2 of Embodiment 3 is the same as Variation 1 of Embodiment 3, except that the positions of the folds on the circuit member are changed. Thus, descriptions of the same features are omitted as appropriate.

A liquid crystal display device 1g includes the liquid crystal display panel 2b and a circuit member 3g disposed on the back surface side of the liquid crystal display panel 2b.

The circuit member 3g is a COF 16f as shown in FIG. 17(b). The COF 16f has a shape such that two branches are coupled with a main part.

The main part of the COF 16f is provided with the signal line drive circuit 12.

A first branch of the COF 16f is provided with the conductive lines 18a. A second branch of the COF 16f is provided with the conductive lines 18b. In FIG. 17(b), only some of the conductive lines 18a and 18b are illustrated.

As shown in FIG. 17(a), the linear outer edge portion 14a and the end of the first branch of the COF 16f are attached to each other via the anisotropic conductive film 21. This allows electrical coupling of the terminals 15a of the liquid crystal display panel 2b and the conductive lines 18a of the COF 16f via the anisotropic conductive film 21. Also, the linear outer edge portion 14b and the end of the second branch of the COF 16f are attached to each other via the anisotropic conductive film 21. This allows electrical coupling of the terminals 15b of the liquid crystal display panel 2b and the conductive lines 18b of the COF 16f via the anisotropic conductive film 21.

As a result, the signal line drive circuit 12 and the terminals 15a are electrically coupled via the conductive lines 18a. Also, the signal line drive circuit 12 and the terminals 15b are electrically coupled via the conductive lines 18b.

As shown in FIGS. 17(a) and 17(b), the end of the first branch of the COF 16f is bent from the front surface side toward the back surface of the liquid crystal display panel 2b along the linear outer edge portion 14a. Also, the end of the second branch of the COF 16f is bent from the front surface side toward the back surface of the liquid crystal display panel 2b along the linear outer edge portion 14b.

The first branch of the COF 16f is bent along the fold 22p and a fold 22t in the state shown in FIG. 17(b). Preferably, one of the folds 22p and 22t is a mountain fold and the other is a valley fold. In the present variation, the fold 22p is a mountain fold and the fold 22t is a valley fold in the state shown in FIG. 17(b). Also, the second branch of the COF 16f is bent along the fold 22r and a fold 22u in the state shown in FIG. 17(b). Preferably, one of the folds 22r and 22u is a mountain fold and the other is a valley fold. In the present variation, the fold 22r is a mountain fold and the fold 22u is a valley fold in the state shown in FIG. 17(b).

In the present variation, the direction of each of the folds 22p and 22r and the Y direction (the vertical direction in FIG. 17(b)) form an angle of 15°, while the direction of each of the folds 22t and 22u and the Y direction form an angle of 45°, in the state shown in FIG. 17(b).

As shown in FIG. 17(b), the main part of the COF 16f is disposed on the back surface side of the liquid crystal display panel 2b.

The signal line drive circuit 12 is disposed on the COF 16f so as to face the liquid crystal display panel 2b in the state shown in FIG. 17(b).

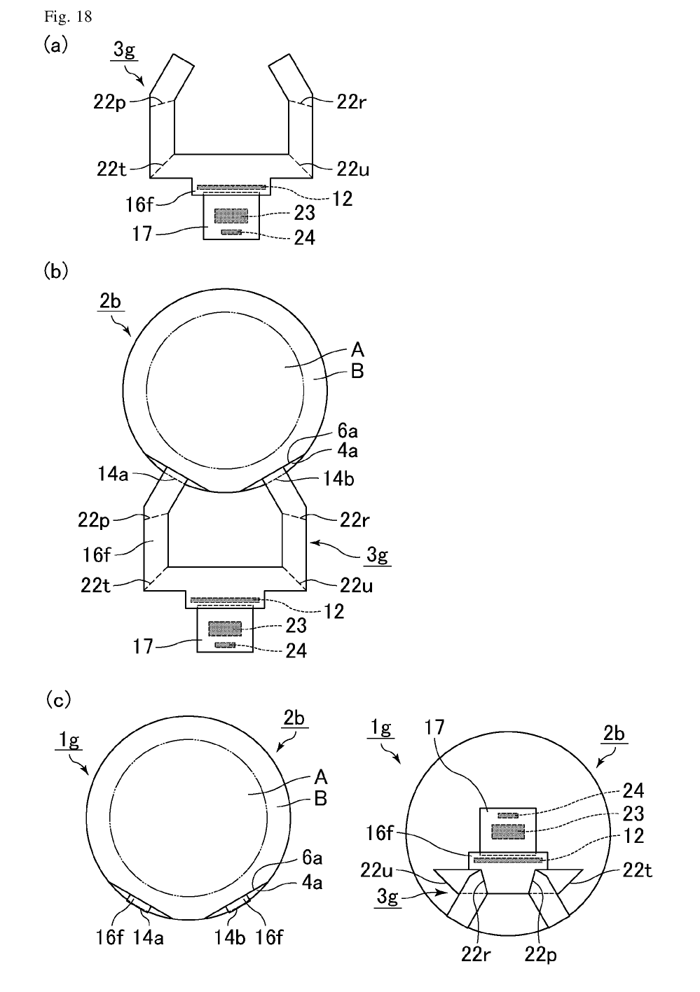

Next, a process of coupling the circuit member 3g with the liquid crystal display panel 2b and bending the circuit member 3g toward the back surface of the liquid crystal display panel 2b is described with reference to FIG. 18. FIG. 18 are schematic plan views illustrating a process of coupling a circuit member of Variation 2 of Embodiment 3 with a liquid crystal display panel and bending the circuit member toward the back surface of the liquid crystal display panel (steps (a) to (c)). In FIG. 18, conductive lines and other members of the liquid crystal display panel and circuit member are omitted as appropriate.

### (a) Preparation of COF

As shown in FIG. 18(a), the COF 16f is prepared as the circuit member 3g.

The first branch of the COF 16f has the folds 22p and 22t in addition to the fold along the linear outer edge portion 14a to be formed in the following step (c). The second branch of the COF 16f has the folds 22r and 22u in addition to the fold along the linear outer edge portion 14b to be formed in the following step (c).

### (b) Coupling of Liquid Crystal Display Panel and COF

As shown in FIG. 18(b), the linear outer edge portion 14a and the end of the first branch of the COF 16f are attached to each other. At this time, the first branch of the COF 16f is not bent along the folds 22p and 22t. Also, the linear outer edge portion 14b and the end of the second branch of the COF 16f are attached to each other. At this time, the second branch of the COF 16f is not bent along the folds 22r and 22u. As a result, the circuit member 3g is coupled with the liquid crystal display panel 2b and is placed on the same plane as the liquid crystal display panel 2b.

### (c) Bending of COF

The end of the first branch of the COF 16f is bent from the front surface side toward the back surface of the liquid crystal display panel 2b along the linear outer edge portion 14a. Also, the end of the second branch of the COF 16f is bent from the front surface side toward the back surface of the liquid crystal display panel 2b along the linear outer edge portion 14b. Then, the first branch of the COF 16f is bent along the folds 22p and 22t and the second branch of the COF 16f is bent along the folds 22r and 22u. Thereby, the liquid crystal display device 1g is completed with a deformed shape as shown in FIG. 18(c). In the liquid crystal display device 1g, the circuit member 3g does not protrude from the liquid crystal display panel 2b. The image on the left side of FIG. 18(c) is an image seen from the front surface side. The image on the right side of FIG. 18(c) is an image seen from the back surface side.

Since the circuit member 3g is folded up smaller on the back surface side of the liquid crystal display panel 2b as shown in FIG. 17(b) in comparison with other embodiments, Variation 2 of Embodiment 3 can ensure a wide space for other members such as a battery.

### Embodiment 4

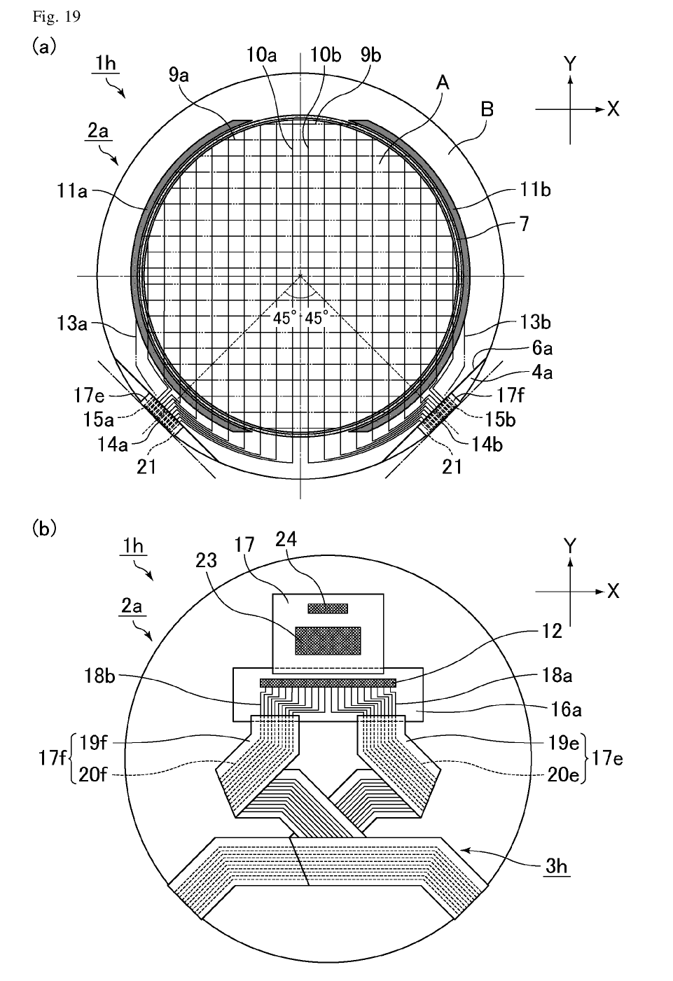

FIG. 19 are schematic plan views of a liquid crystal display device of Embodiment 4; FIG. 19(a) is a view seen from the front surface side and FIG. 19(b) is a view seen from the back surface side. Embodiment 4 is the same as Embodiment 1, except that the shape of the circuit member is changed. Thus, descriptions of the same features are omitted as appropriate.

A liquid crystal display device 1h includes the liquid crystal display panel 2a and a circuit member 3h disposed on the back surface side of the liquid crystal display panel 2a.

As shown in FIG. 19(b), the circuit member 3h includes the COF 16a (main part) and FPCs 17e and 17f (branches) coupled with the COF 16a.

The FPC 17e includes a flexible substrate 19e and multiple conductive lines 20e. A first end of the FPC 17e is provided with multiple FPC terminals (not shown) electrically coupled with the respective conductive lines 20e in an independent manner. A second end of the FPC 17e is provided with ends of the conductive lines 20e or a conductive portion electrically coupled with the conductive lines 20e. The FPC 17f includes a flexible substrate 19f and multiple conductive lines 20f. A first end of the FPC 17f is provided with multiple FPC terminals (not shown) electrically coupled with the respective conductive lines 20f in an independent manner. A second end of the FPC 17f is provided with ends of the conductive lines 20f or a conductive portion electrically coupled with the conductive lines 20f. In FIG. 19(b), only some of the conductive lines 20e and 20f are illustrated.

As shown in FIG. 19(b), the COF 16a and the first end of the FPC 17e are coupled with each other. This allows electrical coupling of the conductive lines 18a of the COF 16a and the conductive lines 20e of the FPC 17e. Also, the COF 16a and the first end of the FPC 17f are coupled with each other. This allows electrical coupling of the conductive lines 18b of the COF 16a and the conductive lines 20f of the FPC 17f.

As shown in FIG. 19(a), the linear outer edge portion 14a and the second end of the FPC 17e are attached to each other via the anisotropic conductive film 21. This allows electrical coupling of the terminals 15a of the liquid crystal display panel 2a and the conductive lines 20e of the FPC 17e via the anisotropic conductive film 21. Also, the linear outer edge portion 14b and the second end of the FPC 17f are attached to each other via the anisotropic conductive film 21. This allows electrical coupling of the terminals 15b of the liquid crystal display panel 2a and the conductive lines 20f of the FPC 17f via the anisotropic conductive film 21.

As a result, the signal line drive circuit 12 and the terminals 15a are electrically coupled via the conductive lines 18a and 20e. Also, the signal line drive circuit 12 and the terminals 15b are electrically coupled via the conductive lines 18b and 20f.

As shown in FIGS. 19(a) and 19(b), the second end of the FPC 17e is bent from the front surface side toward the back surface of the liquid crystal display panel 2a along the linear outer edge portion 14a. Also, the second end of the FPC 17f is bent from the front surface side toward the back surface of the liquid crystal display panel 2a along the linear outer edge portion 14b.

As shown in FIG. 19(b), the FPCs 17e and 17f are twisted and crossed on the back surface side of the liquid crystal display panel 2a. Thereby, the circuit member 3h can be favorably folded up on the back surface side of the liquid crystal display panel 2a.

As shown in FIG. 19(b), the COF 16a is disposed on the back surface side of the liquid crystal display panel 2a.

The signal line drive circuit 12 is disposed on the COF 16a so as to be opposite to the liquid crystal display panel 2a in the state shown in FIG. 19(b).

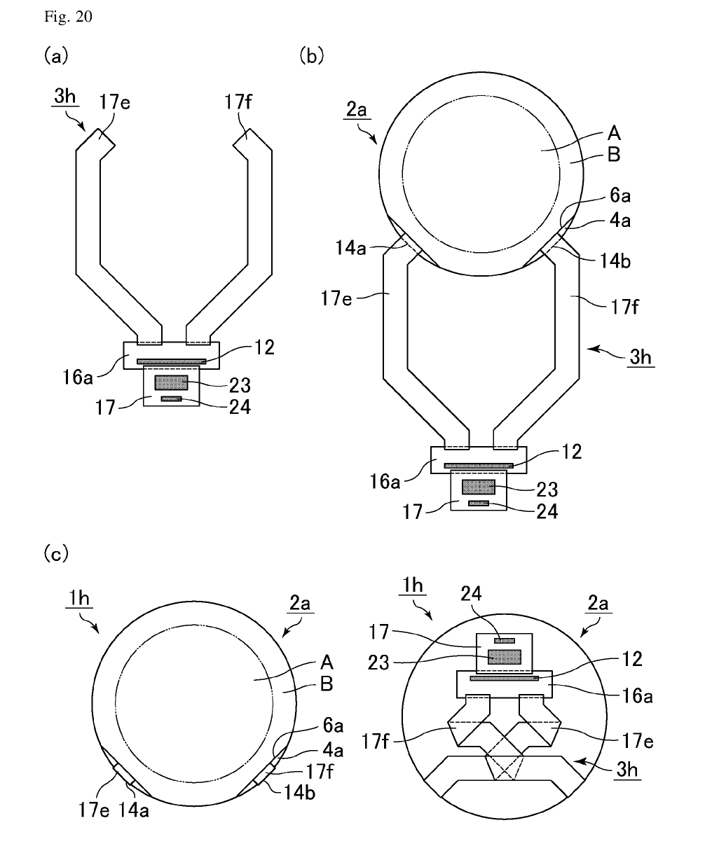

Next, a process of coupling the circuit member 3h with the liquid crystal display panel 2a and bending the circuit member 3h toward the back surface of the liquid crystal display panel 2a is described with reference to FIG. 20. FIG. 20 are schematic plan views illustrating a process of coupling a circuit member of Embodiment 4 with a liquid crystal display panel and bending the circuit member toward the back surface of the liquid crystal display panel (steps (a) to (c)). In FIG. 20, conductive lines and other members of the liquid crystal display panel and circuit member are omitted as appropriate.

### (a) Coupling of COF and FPC

As shown in FIG. 20(a), the COF 16a and the first end of the FPC 17e are coupled with each other. Also, the COF 16a and the first end of the FPC 17f are coupled with each other. As a result, the circuit member 3h is obtained.

### (b) Coupling of Liquid Crystal Display Panel and FPC

As shown in FIG. 20(b), the linear outer edge portion 14a and the second end of the FPC 17e are attached to each other. Also, the linear outer edge portion 14b and the second end of the FPC 17f are attached to each other. As a result, the circuit member 3h is coupled with the liquid crystal display panel 2a and is placed on the same plane as the liquid crystal display panel 2a.

### (c) Bending of FPC

The second end of the FPC 17e is bent from the front surface side toward the back surface of the liquid crystal display panel 2a along the linear outer edge portion 14a. Also, the second end of the FPC 17f is bent from the front surface side toward the back surface of the liquid crystal display panel 2a along the linear outer edge portion 14b. Then, the FPCs 17e and 17f are twisted 360° on the back surface side of the liquid crystal display panel 2a. Thereby, the FPCs 17e and 17f are crossed, and the liquid crystal display device 1h is completed with a deformed shape as shown in FIG. 20(c). In the liquid crystal display device 1h, the circuit member 3h does not protrude from the liquid crystal display panel 2a. The image on the left side of FIG. 20(c) is an image seen from the front surface side. The image on the right side of FIG. 20(c) is an image seen from the back surface side.

In the present embodiment, the step (a) is performed before the step (b), but it may be performed after the step (b). It should be noted that coupling the COF 16a with the FPCs 17e and 17f is technically difficult with the FPCs 17e and 17f being bent toward the back surface of the liquid crystal display panel 2a in the step (c). Thus, the step (a) is preferably performed with the COF 16a and the FPCs 17e and 17f being placed on the same plane as shown in FIG. 20(a).

### (Variation 1 of Embodiment 4)

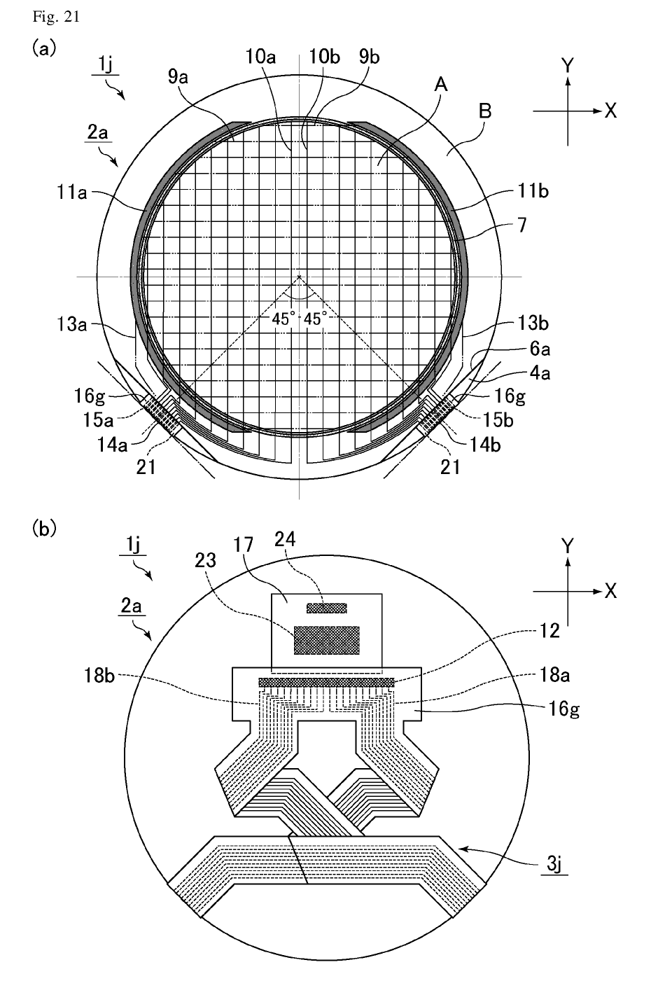

FIG. 21 are schematic plan views of a liquid crystal display device of Variation 1 of Embodiment 4; FIG. 21(a) is a view seen from the front surface side and FIG. 21(b) is a view seen from the back surface side. Variation 1 of Embodiment 4 is the same as Embodiment 4, except that the circuit member is changed to a COF. Thus, descriptions of the same features are omitted as appropriate.

A liquid crystal display device 1j includes the liquid crystal display panel 2a and a circuit member 3j disposed on the back surface side of the liquid crystal display panel 2a.

The circuit member 3j is a COF 16g as shown in FIG. 21(b). The COF 16g has a shape such that two branches are coupled with a main part, which corresponds to integration of the COF 16a (main part) and the FPCs 17e and 17f (branches) as shown in FIG. 19(b).

The main part of the COF 16g is provided with the signal line drive circuit 12.

A first branch of the COF 16g is provided with the conductive lines 18a. A second branch of the COF 16g is provided with the conductive lines 18b. In FIG. 21(b), only some of the conductive lines 18a and 18b are illustrated.

As shown in FIG. 21(a), the linear outer edge portion 14a and the end of the first branch of the COF 16g are attached to each other via the anisotropic conductive film 21. This allows electrical coupling of the terminals 15a of the liquid crystal display panel 2a and the conductive lines 18a of the COF 16g via the anisotropic conductive film 21. Also, the linear outer edge portion 14b and the end of the second branch of the COF 16g are attached to each other via the anisotropic conductive film 21. This allows electrical coupling of the terminals 15b of the liquid crystal display panel 2a and the conductive lines 18b of the COF 16g via the anisotropic conductive film 21.

As a result, the signal line drive circuit 12 and the terminals 15a are electrically coupled via the conductive lines 18a. Also, the signal line drive circuit 12 and the terminals 15b are electrically coupled via the conductive lines 18b.

As shown in FIGS. 21(a) and 21(b), the end of the first branch of the COF 16g is bent from the front surface side toward the back surface of the liquid crystal display panel 2a along the linear outer edge portion 14a. Also, the end of the second branch of the COF 16g is bent from the front surface side toward the back surface of the liquid crystal display panel 2a along the linear outer edge portion 14b.

As shown in FIG. 21(b), the first branch of the COF 16g and the second branch of the COF 16g are twisted and crossed on the back surface side of the liquid crystal display panel 2a.

As shown in FIG. 21(b), the main part of the COF 16g is disposed on the back surface side of the liquid crystal display panel 2a.

The signal line drive circuit 12 is disposed on the COF 16g so as to face the liquid crystal display panel 2a in the state shown in FIG. 21(b).

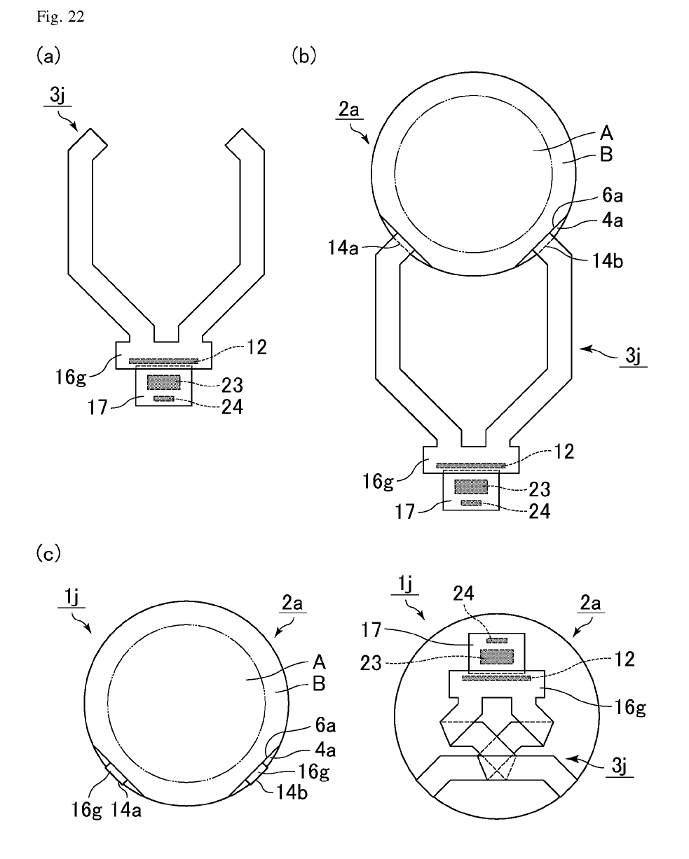

Next, a process of coupling the circuit member 3j with the liquid crystal display panel 2a and bending the circuit member 3j toward the back surface of the liquid crystal display panel 2a is described with reference to FIG. 22. FIG. 22 are schematic plan views illustrating a process of coupling a circuit member of Variation 1 of Embodiment 4 with a liquid crystal display panel and bending the circuit member toward the back surface of the liquid crystal display panel (steps (a) to (c)). In FIG. 22, conductive lines and other members of the liquid crystal display panel and circuit member are omitted as appropriate.

### (a) Preparation of COF

As shown in FIG. 22(a), the COF 16g is prepared as the circuit member 3j.

### (b) Coupling of Liquid Crystal Display Panel and FPC

As shown in FIG. 22(b), the linear outer edge portion 14a and the end of the first branch of the COF 16g are attached to each other. Also, the linear outer edge portion 14b and the end of the second branch of the COF 16g are attached to each other. As a result, the circuit member 3j is coupled with the liquid crystal display panel 2a and is placed on the same plane as the liquid crystal display panel 2a.

### (c) Bending of COF

The end of the first branch of the COF 16g is bent from the front surface side toward the back surface of the liquid crystal display panel 2a along the linear outer edge portion 14a. Also, the end of the second branch of the COF 16g is bent from the front surface side toward the back surface of the liquid crystal display panel 2a along the linear outer edge portion 14b. Then, the first branch of the COF 16g and the second branch of the COF 16g are twisted 360° on the back surface side of the liquid crystal display panel 2a. Thereby, the first branch of the COF 16g and the second branch of the COF 16g are crossed, and the liquid crystal display device 1j is completed with a deformed shape as shown in FIG. 22(c). In the liquid crystal display device 1j, the circuit member 3j does not protrude from the liquid crystal display panel 2a. The image on the left side of FIG. 22(c) is an image seen from the front surface side. The image on the right side of FIG. 22(c) is an image seen from the back surface side.

Since the COF 16g is used as the circuit member 3j, Variation 1 of Embodiment 4 can eliminate the step of coupling the COF 16a with the FPCs 17e and 17f, such as the step (a) in Embodiment 4. As a result, Variation 1 of Embodiment 4 can achieve reduction in the process cost and improvement in the yield in comparison with Embodiment 4.

### (Variation 2 of Embodiment 4)

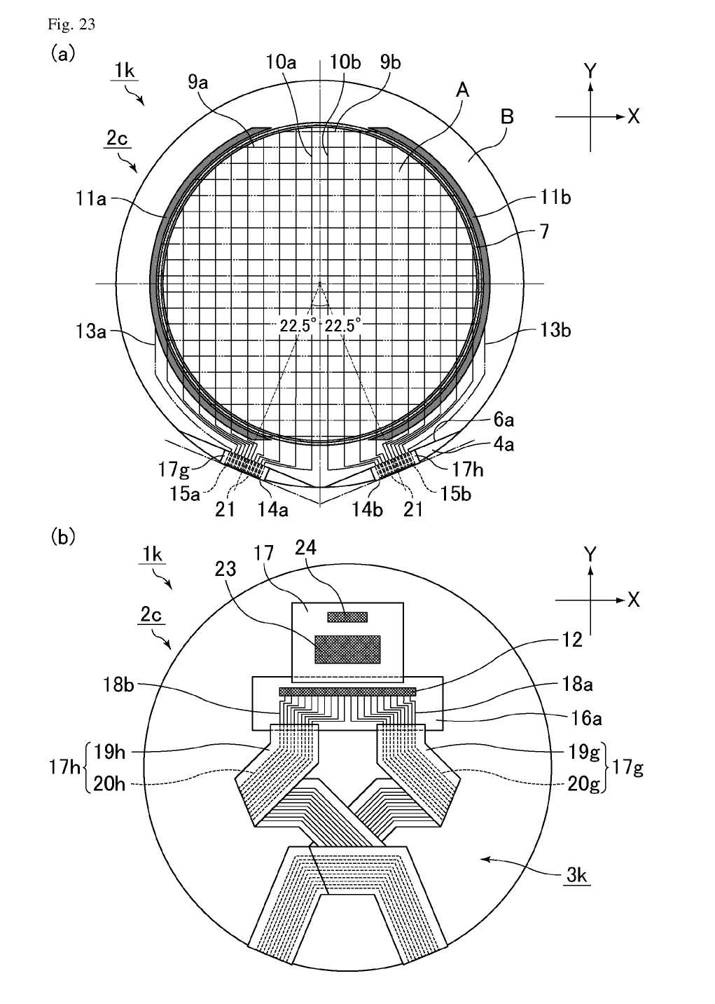

FIG. 23 are schematic plan views of a liquid crystal display device of Variation 2 of Embodiment 4; FIG. 23(a) is a view seen from the front surface side and FIG. 23(b) is a view seen from the back surface side. Variation 2 of Embodiment 4 is the same as Embodiment 4, except that the positions of the two linear outer edge portions of the liquid crystal display panel and the shape of the circuit member are changed. Thus, descriptions of the same features are omitted as appropriate.

A liquid crystal display device 1k includes a liquid crystal display panel 2c and a circuit member 3k disposed on the back surface side of the liquid crystal display panel 2c.

The liquid crystal display panel 2c has the linear outer edge portions 14a and 14b on the outer edge. In the present variation, the direction perpendicular to the linear outer edge portion 14a (14b) and the Y direction (the vertical direction in FIG. 23(a)) form an angle of 22.5° in the state shown in FIG. 23(a).

As shown in FIG. 23(b), the circuit member 3k includes the COF 16a (main part) and FPCs 17g and 17h (branches) coupled with the COF 16a.

The FPC 17g includes a flexible substrate 19g and multiple conductive lines 20g. A first end of the FPC 17g is provided with multiple FPC terminals (not shown) electrically coupled with the respective conductive lines 20g in an independent manner. A second end of the FPC 17g is provided with ends of the conductive lines 20g or a conductive portion electrically coupled with the conductive lines 20g. The FPC 17h includes a flexible substrate 19h and multiple conductive lines 20h. A first end of the FPC 17h is provided with multiple FPC terminals (not shown) electrically coupled with the respective conductive lines 20h in an independent manner. A second end of the FPC 17h is provided with ends of the conductive lines 20h or a conductive portion electrically coupled with the conductive lines 20h. In FIG. 23(b), only some of the conductive lines 20g and 20h are illustrated.

As shown in FIG. 23(b), the COF 16a and the first end of the FPC 17g are coupled with each other. This allows electrical coupling of the conductive lines 18a of the COF 16a and the conductive lines 20g of the FPC 17g. Also, the COF 16a and the first end of the FPC 17h are coupled with each other. This allows electrical coupling of the conductive lines 18b of the COF 16a and the conductive lines 20h of the FPC 17h.

As shown in FIG. 23(a), the linear outer edge portion 14a and the second end of the FPC 17g are attached to each other via the anisotropic conductive film 21. This allows electrical coupling of the terminals 15a of the liquid crystal display panel 2c and the conductive lines 20g of the FPC 17g via the anisotropic conductive film 21. Also, the linear outer edge portion 14b and the second end of the FPC 17h are attached to each other via the anisotropic conductive film 21. This allows electrical coupling of the terminals 15b of the liquid crystal display panel 2c and the conductive lines 20h of the FPC 17h via the anisotropic conductive film 21.

As a result, the signal line drive circuit 12 and the terminals 15a are electrically coupled via the conductive lines 18a and 20g. Also, the signal line drive circuit 12 and the terminals 15b are electrically coupled via the conductive lines 18b and 20h.

As shown in FIGS. 23(a) and 23(b), the second end of the FPC 17g is bent from the front surface side toward the back surface of the liquid crystal display panel 2c along the linear outer edge portion 14a. Also, the second end of the FPC 17h is bent from the front surface side toward the back surface of the liquid crystal display panel 2c along the linear outer edge portion 14b.

As shown in FIG. 23(b), the FPCs 17g and 17h are twisted and crossed on the back surface side of the liquid crystal display panel 2c.

As shown in FIG. 23(b), the COF 16a is disposed on the back surface side of the liquid crystal display panel 2c.

The signal line drive circuit 12 is disposed on the COF 16a so as to be opposite to the liquid crystal display panel 2c in the state shown in FIG. 23(b).

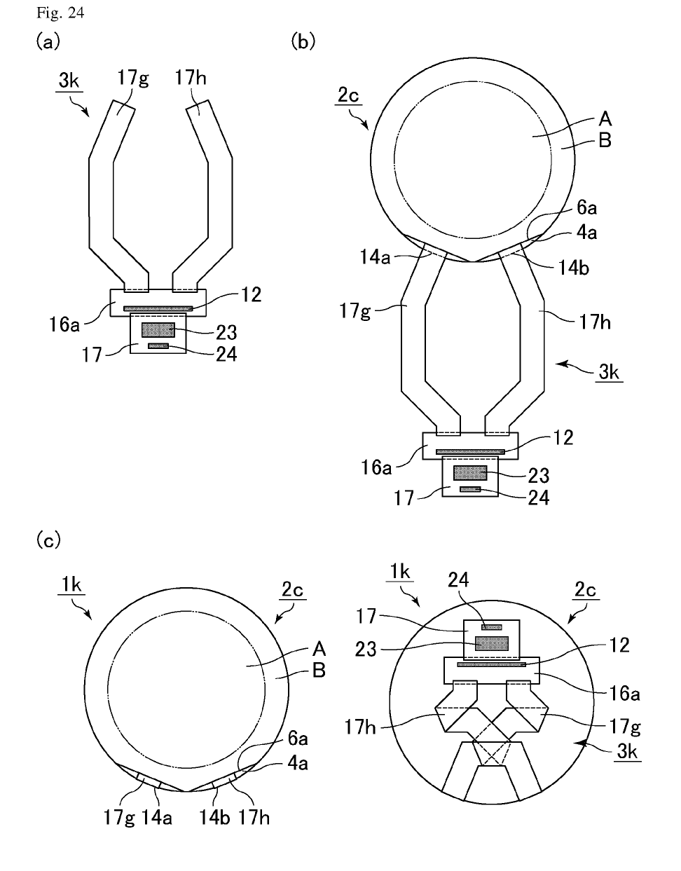

Next, a process of coupling the circuit member 3k with the liquid crystal display panel 2c and bending the circuit member 3k toward the back surface of the liquid crystal display panel 2c is described with reference to FIG. 24. FIG. 24 are schematic plan views illustrating a process of coupling a circuit member of Variation 2 of Embodiment 4 with a liquid crystal display panel and bending the circuit member toward the back surface of the liquid crystal display panel (steps (a) to (c)). In FIG. 24, conductive lines and other members of the liquid crystal display panel and circuit member are omitted as appropriate.

### (a) Coupling of COF and FPC

As shown in FIG. 24(a), the COF 16a and the first end of the FPC 17g are coupled with each other. Also, the COF 16a and the first end of the FPC 17h are coupled with each other. As a result, the circuit member 3k is obtained.

### (b) Coupling of Liquid Crystal Display Panel and FPC

As shown in FIG. 24(b), the linear outer edge portion 14a and the second end of the FPC 17g are attached to each other. Also, the linear outer edge portion 14b and the second end of the FPC 17h are attached to each other. As a result, the circuit member 3k is coupled with the liquid crystal display panel 2c and is placed on the same plane as the liquid crystal display panel 2c.

### (c) Bending of FPC

The second end of the FPC 17g is bent from the front surface side toward the back surface of the liquid crystal display panel 2c along the linear outer edge portion 14a. Also, the second end of the FPC 17h is bent from the front surface side toward the back surface of the liquid crystal display panel 2c along the linear outer edge portion 14b. Then, the FPCs 17g and 17h are twisted 360° on the back surface side of the liquid crystal display panel 2c. Thereby, the FPCs 17g and 17h are crossed, and the liquid crystal display device 1k is completed with a deformed shape as shown in FIG. 24(c). In the liquid crystal display device 1k, the circuit member 3k does not protrude from the liquid crystal display panel 2c. The image on the left side of FIG. 24(c) is an image seen from the front surface side. The image on the right side of FIG. 24(c) is an image seen from the back surface side.

### Embodiment 5

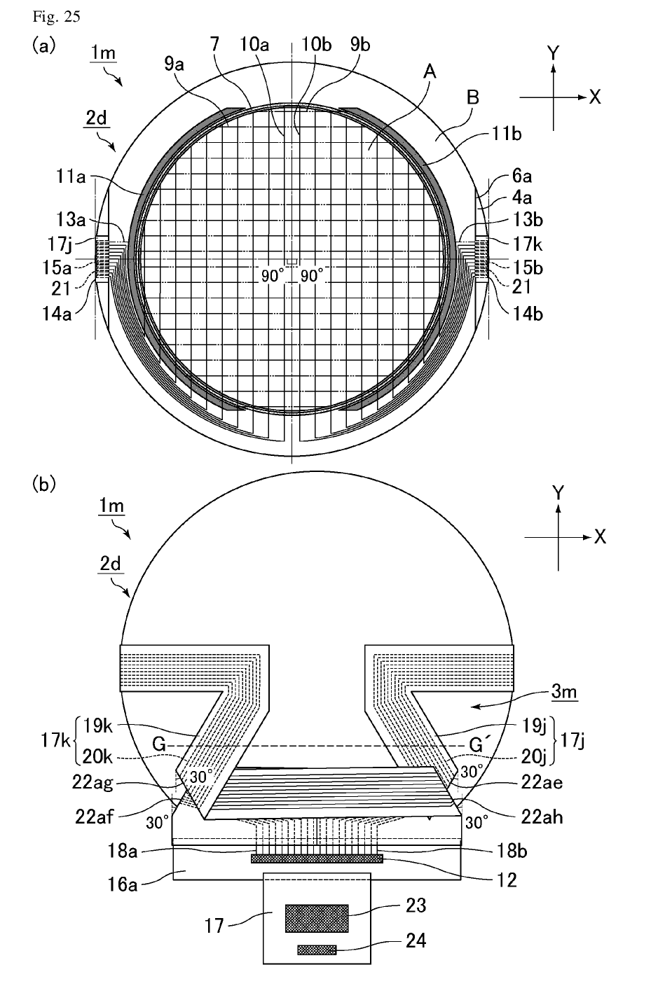

FIG. 25 are schematic plan views of a liquid crystal display device of Embodiment 5; FIG. 25(a) is a view seen from the front surface side and FIG. 25(b) is a view seen from the back surface side (before the circuit member is bent). FIGS. 25(a) and 25(b) do not completely correspond to each other in that part of the circuit member protrudes from the liquid crystal display panel in FIG. 25(b). Still, for convenience of description, FIG. 25(b) illustrates the state before the circuit member is folded up. Embodiment 5 is the same as Embodiment 4, except that the positions of the two linear outer edge portions of the liquid crystal display panel and the shape of the circuit member are changed. Thus, descriptions of the same features are omitted as appropriate.

A liquid crystal display device 1m includes a liquid crystal display panel 2d and a circuit member 3m disposed on the back surface side of the liquid crystal display panel 2d.

The liquid crystal display panel 2d has the linear outer edge portions 14a and 14b on the outer edge. In the present embodiment, the direction perpendicular to the linear outer edge portion 14a (14b) and the Y direction (the vertical direction in FIG. 25(a)) form an angle of 90° in the state shown in FIG. 25(a).

As shown in FIG. 25(b), the circuit member 3m includes the COF 16a (main part) and FPCs 17j and 17k (branches) coupled with the COF 16a.

The FPC 17j includes a flexible substrate 19j and multiple conductive lines 20j. A first end of the FPC 17j is provided with multiple FPC terminals (not shown) electrically coupled with the respective conductive lines 20j in an independent manner. A second end of the FPC 17j is provided with ends of the conductive lines 20j or a conductive portion electrically coupled with the conductive lines 20j. The FPC 17k includes a flexible substrate 19k and multiple conductive lines 20k. A first end of the FPC 17k is provided with multiple FPC terminals (not shown) electrically coupled with the respective conductive lines 20k in an independent manner. A second end of the FPC 17k is provided with ends of the conductive lines 20k or a conductive portion electrically coupled with the conductive lines 20k. In FIG. 25(b), only some of the conductive lines 20j and 20k are illustrated.

As shown in FIG. 25(b), the COF 16a and the first end of the FPC 17j are coupled with each other. This allows electrical coupling of the conductive lines 18a of the COF 16a and the conductive lines 20j of the FPC 17j. Also, the COF 16a and the first end of the FPC 17k are coupled with each other. This allows electrical coupling of the conductive lines 18b of the COF 16a and the conductive lines 20k of the FPC 17k.

As shown in FIG. 25(a), the linear outer edge portion 14a and the second end of the FPC 17j are attached to each other via the anisotropic conductive film 21. This allows electrical coupling of the terminals 15a of the liquid crystal display panel 2d and the conductive lines 20j of the FPC 17j via the anisotropic conductive film 21. Also, the linear outer edge portion 14b and the second end of the FPC 17k are attached to each other via the anisotropic conductive film 21. This allows electrical coupling of the terminals 15b of the liquid crystal display panel 2d and the conductive lines 20k of the FPC 17k via the anisotropic conductive film 21.

As a result, the signal line drive circuit 12 and the terminals 15a are electrically coupled via the conductive lines 18a and 20j. Also, the signal line drive circuit 12 and the terminals 15b are electrically coupled via the conductive lines 18b and 20k.

As shown in FIGS. 25(a) and 25(b), the second end of the FPC 17j is bent from the front surface side toward the back surface of the liquid crystal display panel 2d along the linear outer edge portion 14a. Also, the second end of the FPC 17k is bent from the front surface side toward the back surface of the liquid crystal display panel 2d along the linear outer edge portion 14b.

As shown in FIG. 25(b), the FPCs 17j and 17k are twisted and crossed on the back surface side of the liquid crystal display panel 2d. The FPC 17j is bent along folds 22ae and 22af. The FPC 17k is bent along folds 22ag and 22ah. In the present embodiment, the folds 22ae, 22af, and 22ag are valley folds and the fold 22ah is a mountain fold in the state shown in FIG. 25(b).

In the present embodiment, the direction of each of the folds 22ae, 22af, 22ag, and 22ah and the Y direction (the vertical direction in FIG. 25(b)) form an angle of 30° in the state shown in FIG. 25(b).

As shown in FIG. 25(b), the COF 16a is disposed on the back surface side of the liquid crystal display panel 2d.

The signal line drive circuit 12 is disposed on the COF 16a so as to be opposite to the liquid crystal display panel 2d in the state shown in FIG. 25(b).

As shown in FIG. 25(b), the circuit member 3m protrudes from the liquid crystal display panel 2d in a state of being bent toward the back surface of the liquid crystal display panel 2d. In this case, the circuit member 3m may be bent at any position (for example, at the G-G′ line in FIG. 25(b)). Thereby, the circuit member 3m can be folded up on the back surface side of the liquid crystal display panel 2d. As a result, the liquid crystal display device 1m can be obtained with a deformed shape and with the circuit member 3m not protruding from the liquid crystal display panel 2d, as shown in FIG. 25(a).

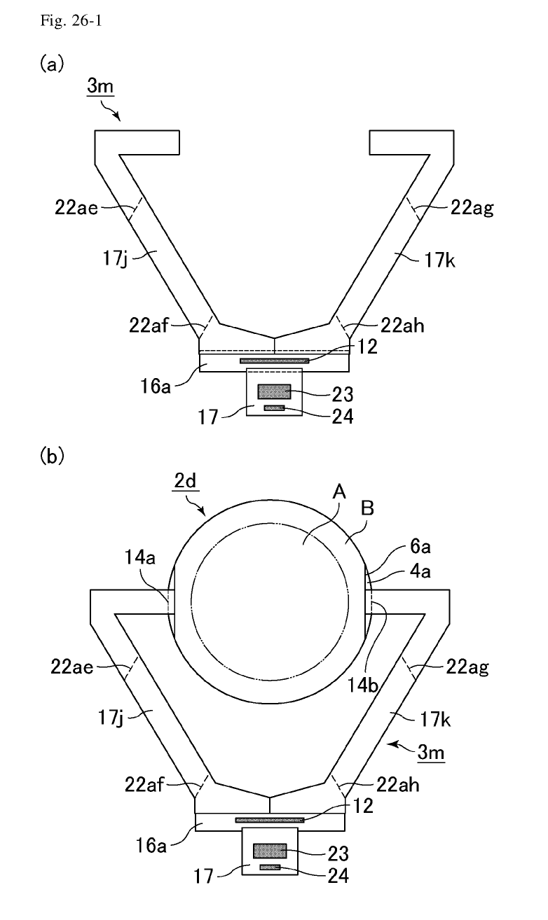

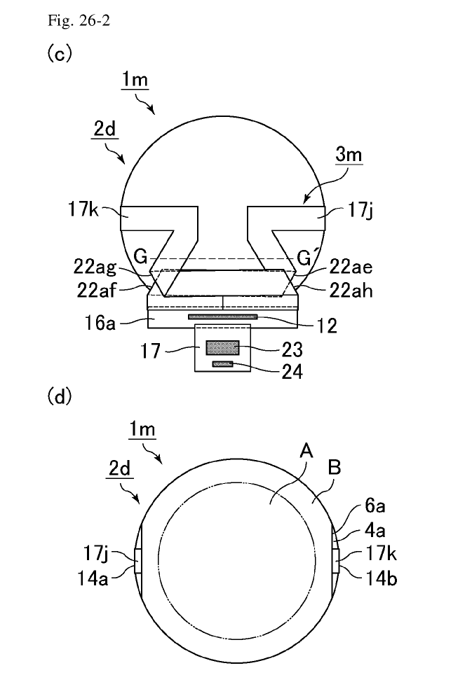

Next, a process of coupling the circuit member 3m with the liquid crystal display panel 2d and bending the circuit member 3m toward the back surface of the liquid crystal display panel 2d is described with reference to FIGS. 26-1 and FIGS. 26-2. FIGS. 26-1 are schematic plan views illustrating a process of coupling a circuit member of Embodiment 5 with a liquid crystal display panel and bending the circuit member toward the back surface of the liquid crystal display panel (steps (a) and (b)). FIGS. 26-2 are schematic plan views illustrating a process of coupling a circuit member of Embodiment 5 with a liquid crystal display panel and bending the circuit member toward the back surface of the liquid crystal display panel (steps (c) and (d)). In FIGS. 26-1 and FIGS. 26-2, conductive lines and other members of the liquid crystal display panel and circuit member are omitted as appropriate.

### (a) Coupling of COF and FPC

As shown in FIG. 26-1(a), the COF 16a and the first end of the FPC 17j are coupled with each other. Also, the COF 16a and the first end of the FPC 17k are coupled with each other. As a result, the circuit member 3m is obtained.

The FPC 17j has the folds 22ae and 22af in addition to the fold along the linear outer edge portion 14a to be formed in the following step (c). The FPC 17k has the folds 22ag and 22ah in addition to the fold along the linear outer edge portion 14b to be formed in the following step (c).

### (b) Coupling of Liquid Crystal Display Panel and FPC

As shown in FIG. 26-1(b), the linear outer edge portion 14a and the second end of the FPC 17j are attached to each other. Also, the linear outer edge portion 14b and the second end of the FPC 17k are attached to each other. As a result, the circuit member 3m is coupled with the liquid crystal display panel 2d and is placed on the same plane as the liquid crystal display panel 2d.

### (c) Bending of FPC

The second end of the FPC 17j is bent from the front surface side toward the back surface of the liquid crystal display panel 2d along the linear outer edge portion 14a. Also, the second end of the FPC 17k is bent from the front surface side toward the back surface of the liquid crystal display panel 2d along the linear outer edge portion 14b. Then, the FPCs 17j and 17k are twisted 180° on the back surface side of the liquid crystal display panel 2d while the FPC 17j is bent along the folds 22ae and 22af and the FPC 17k is bent along the folds 22ag and 22ah. Thereby, the FPCs 17j and 17k are crossed, and the circuit member 3m is bent toward the back surface of the liquid crystal display panel 2d as shown in FIG. 26-2(c). FIG. 26-2(c) is a view seen from the back surface side.

### (d) Folding Up of Circuit Member

As shown in FIG. 26-2(c), the circuit member 3m protrudes from the liquid crystal display panel 2d. In this case, the circuit member 3m may be bent at any position of the FPCs 17j and 17k (for example, at the G-G′ line in FIG. 26-2(c)). Thereby, the circuit member 3m can be folded up on the back surface side of the liquid crystal display panel 2d. As a result, the liquid crystal display device 1m can be obtained with a deformed shape and with the circuit member 3m not protruding from the liquid crystal display panel 2d, as shown in FIG. 26-2(d). FIG. 26-2(d) is a view seen from the front surface side.

### (Variation of Embodiment 5)

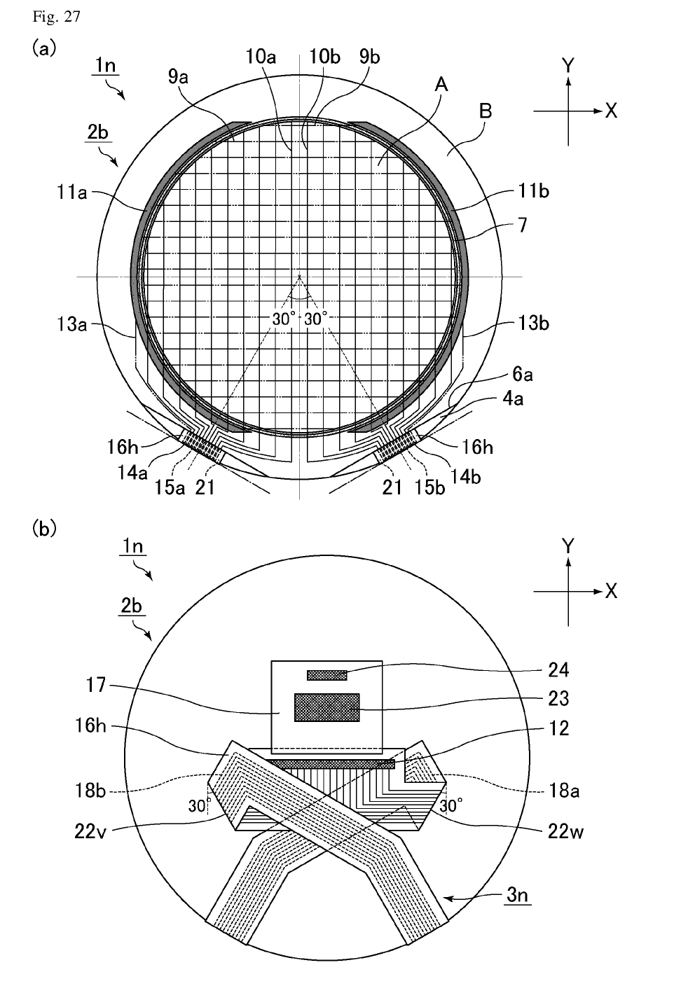

FIG. 27 are schematic plan views of a liquid crystal display device of Variation of Embodiment 5; FIG. 27(a) is a view seen from the front surface side and FIG. 27(b) is a view seen from the back surface side. Variation of Embodiment 5 is the same as Embodiment 5, except that the positions of the two linear outer edge portions of the liquid crystal display panel and the shape of the circuit member are changed and that the circuit member is changed to a COF. Thus, descriptions of the same features are omitted as appropriate.

A liquid crystal display device 1n includes the liquid crystal display panel 2b and a circuit member 3n disposed on the back surface side of the liquid crystal display panel 2b.

The circuit member 3n is a COF 16h as shown in FIG. 27(b). The COF 16h has a shape such that two branches are coupled with a main part.

The main part of the COF 16h is provided with the signal line drive circuit 12.

A first branch of the COF 16h is provided with the conductive lines 18b. A second branch of the COF 16h is provided with the conductive lines 18a. In FIG. 27(b), only some of the conductive lines 18a and 18b are illustrated.

As shown in FIG. 27(a), the linear outer edge portion 14a and the end of the first branch of the COF 16h are attached to each other via the anisotropic conductive film 21. This allows electrical coupling of the terminals 15a of the liquid crystal display panel 2b and the conductive lines 18b of the COF 16h via the anisotropic conductive film 21. Also, the linear outer edge portion 14b and the end of the second branch of the COF 16h are attached to each other via the anisotropic conductive film 21. This allows electrical coupling of the terminals 15b of the liquid crystal display panel 2b and the conductive lines 18a of the COF 16h via the anisotropic conductive film 21.

As a result, the signal line drive circuit 12 and the terminals 15a are electrically coupled via the conductive lines 18b. Also, the signal line drive circuit 12 and the terminals 15b are electrically coupled via the conductive lines 18a.

As shown in FIGS. 27(a) and 27(b), the end of the first branch of the COF 16h is bent from the front surface side toward the back surface of the liquid crystal display panel 2b along the linear outer edge portion 14a. Also, the end of the second branch of the COF 16h is bent from the front surface side toward the back surface of the liquid crystal display panel 2b along the linear outer edge portion 14b.

As shown in FIG. 27(b), the first branch of the COF 16h and the second branch of the COF 16h are twisted and crossed on the back surface side of the liquid crystal display panel 2b. Further, the first branch of the COF 16h is bent along a fold 22v. The second branch of the COF 16h is bent along a fold 22w. In the present variation, the fold 22v is a mountain fold and the fold 22w is a valley fold in the state shown in FIG. 27(b).

In the present variation, the direction of each of the folds 22v and 22w and the Y direction (the vertical direction in FIG. 27(b)) form an angle of 30° in the state shown in FIG. 27(b).

As shown in FIG. 27(b), the main part of the COF 16h is disposed on the back surface side of the liquid crystal display panel 2b.

The signal line drive circuit 12 is disposed on the COF 16h so as to be opposite to the liquid crystal display panel 2b in the state shown in FIG. 27(b).

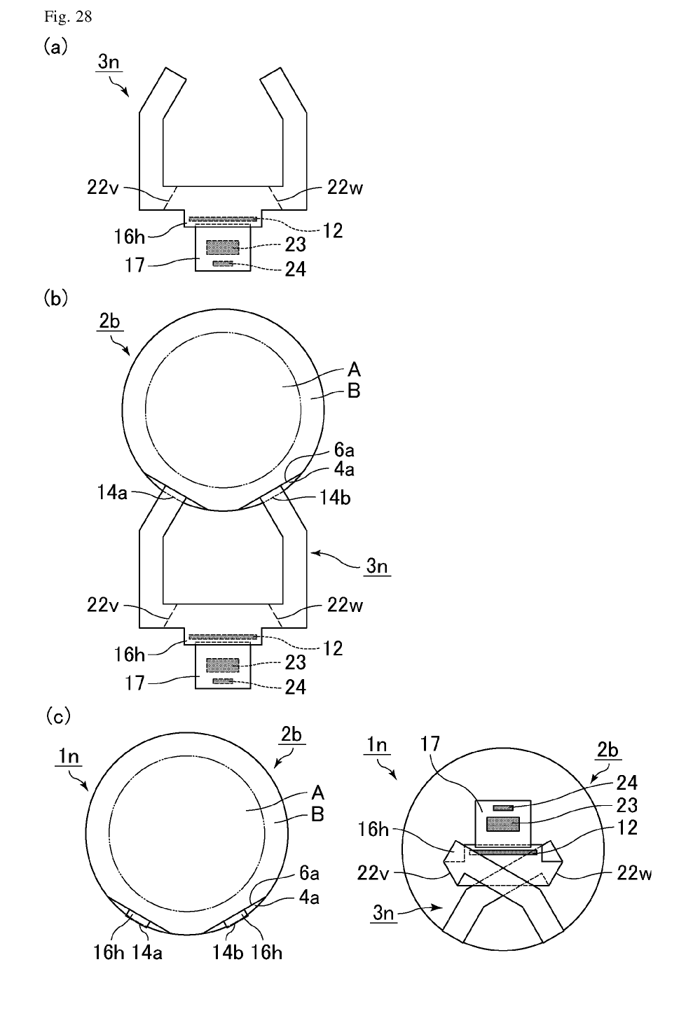

Next, a process of coupling the circuit member 3n with the liquid crystal display panel 2b and bending the circuit member 3n toward the back surface of the liquid crystal display panel 2b is described with reference to FIG. 28. FIG. 28 are schematic plan views illustrating a process of coupling a circuit member of Variation of Embodiment 5 with a liquid crystal display panel and bending the circuit member toward the back surface of the liquid crystal display panel (steps (a) to (c)). In FIG. 28, conductive lines and other members of the liquid crystal display panel and circuit member are omitted as appropriate.

### (a) Preparation of COF

As shown in FIG. 28(a), the COF 16h is prepared as the circuit member 3n.

The first branch of the COF 16h has the fold 22v in addition to the fold along the linear outer edge portion 14a to be formed in the following step (c). The second branch of the COF 16h has the fold 22w in addition to the fold along the linear outer edge portion 14b to be formed in the following step (c).

### (b) Coupling of Liquid Crystal Display Panel and COF

As shown in FIG. 28(b), the linear outer edge portion 14a and the end of the first branch of the COF 16h are attached to each other. At this time, the first branch of the COF 16h is not bent along the fold 22v. Also, the linear outer edge portion 14b and the end of the second branch of the COF 16h are attached to each other. At this time, the second branch of the COF 16h is not bent along the fold 22w. As a result, the circuit member 3n is coupled with the liquid crystal display panel 2b and is placed on the same plane as the liquid crystal display panel 2b.

### (c) Bending of COF

The end of the first branch of the COF 16h is bent from the front surface side toward the back surface of the liquid crystal display panel 2b along the linear outer edge portion 14a. Also, the end of the second branch of the COF 16h is bent from the front surface side toward the back surface of the liquid crystal display panel 2b along the linear outer edge portion 14b. Then, these two branches are twisted 180° on the back surface side of the liquid crystal display panel 2b while the first branch of the COF 16h is bent along the fold 22v and the second branch of the COF 16h is bent along the fold 22w. Thereby, the first branch of the COF 16h and the second branch of the COF 16h are crossed, and the liquid crystal display device 1n is completed as shown in FIG. 28(c). In the liquid crystal display device 1n, the circuit member 3n does not protrude from the liquid crystal display panel 2b. The image on the left side of FIG. 28(c) is an image seen from the front surface side. The image on the right side of FIG. 28(c) is an image seen from the back surface side.

Since the number of folds of the circuit member 3n is smaller than that of the circuit member 3m in Embodiment 5, Variation of Embodiment 5 can reduce the number of spacers used in bending of the circuit member 3n, such as the spacer 25 that has already been described with reference to FIG. 5, and thus can achieve cost reduction.

### Embodiment 6

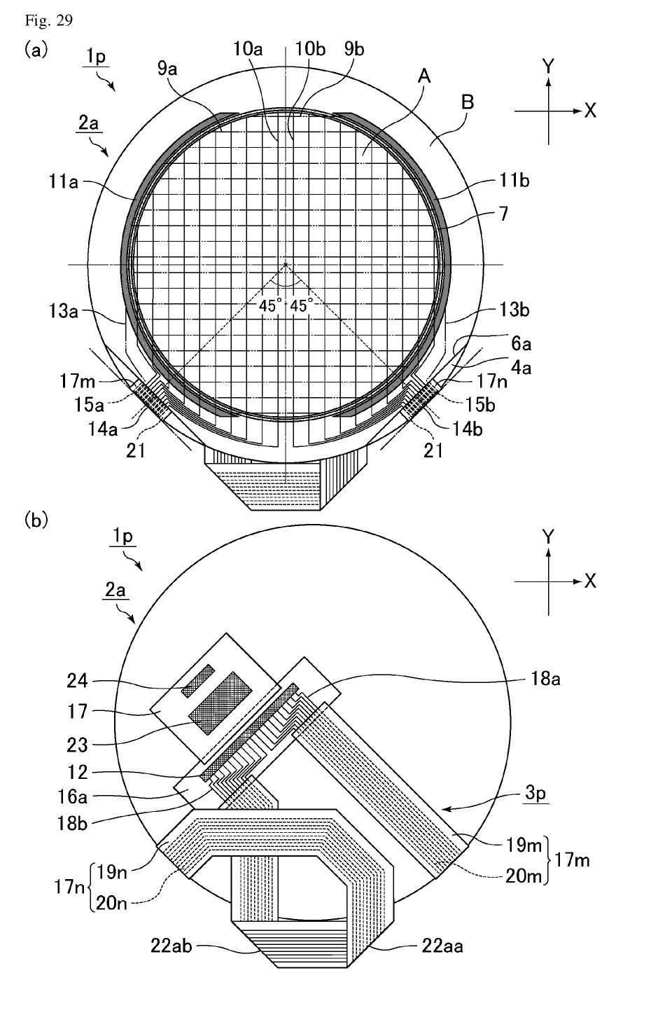

FIG. 29 are schematic plan views of a liquid crystal display device of Embodiment 6; FIG. 29(a) is a view seen from the front surface side and FIG. 29(b) is a view seen from the back surface side. Embodiment 6 is the same as Embodiment 1, except that the shape of the circuit member is changed. Thus, descriptions of the same features are omitted as appropriate.

A liquid crystal display device 1p includes the liquid crystal display panel 2a and a circuit member 3p disposed on the back surface side of the liquid crystal display panel 2a.

As shown in FIG. 29(b), the circuit member 3p includes the COF 16a (main part) and FPCs 17m and 17n (branches) coupled with the COF 16a.

The FPC 17m includes a flexible substrate 19m and multiple conductive lines 20m. A first end of the FPC 17m is provided with multiple FPC terminals (not shown) electrically coupled with the respective conductive lines 20m in an independent manner. A second end of the FPC 17m is provided with ends of the conductive lines 20m or a conductive portion electrically coupled with the conductive lines 20m. The FPC 17n includes a flexible substrate 19n and multiple conductive lines 20n. A first end of the FPC 17n is provided with multiple FPC terminals (not shown) electrically coupled with the respective conductive lines 20n in an independent manner. A second end of the FPC 17n is provided with ends of the conductive lines 20n or a conductive portion electrically coupled with the conductive lines 20n. In FIG. 29(b), only some of the conductive lines 20m and 20n are illustrated.

As shown in FIG. 29(b), the COF 16a and the first end of the FPC 17m are coupled with each other. This allows electrical coupling of the conductive lines 18a of the COF 16a and the conductive lines 20m of the FPC 17m. Also, the COF 16a and the first end of the FPC 17n are coupled with each other. This allows electrical coupling of the conductive lines 18b of the COF 16a and the conductive lines 20n of the FPC 17n.

As shown in FIG. 29(a), the linear outer edge portion 14a and the second end of the FPC 17m are attached to each other via the anisotropic conductive film 21. This allows electrical coupling of the terminals 15a of the liquid crystal display panel 2a and the conductive lines 20m of the FPC 17m via the anisotropic conductive film 21. Also, the linear outer edge portion 14b and the second end of the FPC 17n are attached to each other via the anisotropic conductive film 21. This allows electrical coupling of the terminals 15b of the liquid crystal display panel 2a and the conductive lines 20n of the FPC 17n via the anisotropic conductive film 21.

As a result, the signal line drive circuit 12 and the terminals 15a are electrically coupled via the conductive lines 18a and 20m. Also, the signal line drive circuit 12 and the terminals 15b are electrically coupled via the conductive lines 18b and 20n.

As shown in FIGS. 29(a) and 29(b), the second end of the FPC 17m is bent from the front surface side toward the back surface of the liquid crystal display panel 2a along the linear outer edge portion 14a. Also, the second end of the FPC 17n is bent from the front surface side toward the back surface of the liquid crystal display panel 2a along the linear outer edge portion 14b.

As shown in FIG. 29(b), the FPC 17n is bent along folds 22aa and 22ab. In the present embodiment, both the folds 22aa and 22ab are valley folds in the state shown in FIG. 29(b).

The fold 22aa is placed on the same straight line as the fold along the linear outer edge portion 14a of the FPC 17m. The fold 22ab is placed on the same straight line as the fold along the linear outer edge portion 14b of the FPC 17n.

As shown in FIG. 29(b), the COF 16a is disposed on the back surface side of the liquid crystal display panel 2a.

The signal line drive circuit 12 is disposed on the COF 16a so as to be opposite to the liquid crystal display panel 2a in the state shown in FIG. 29(b).

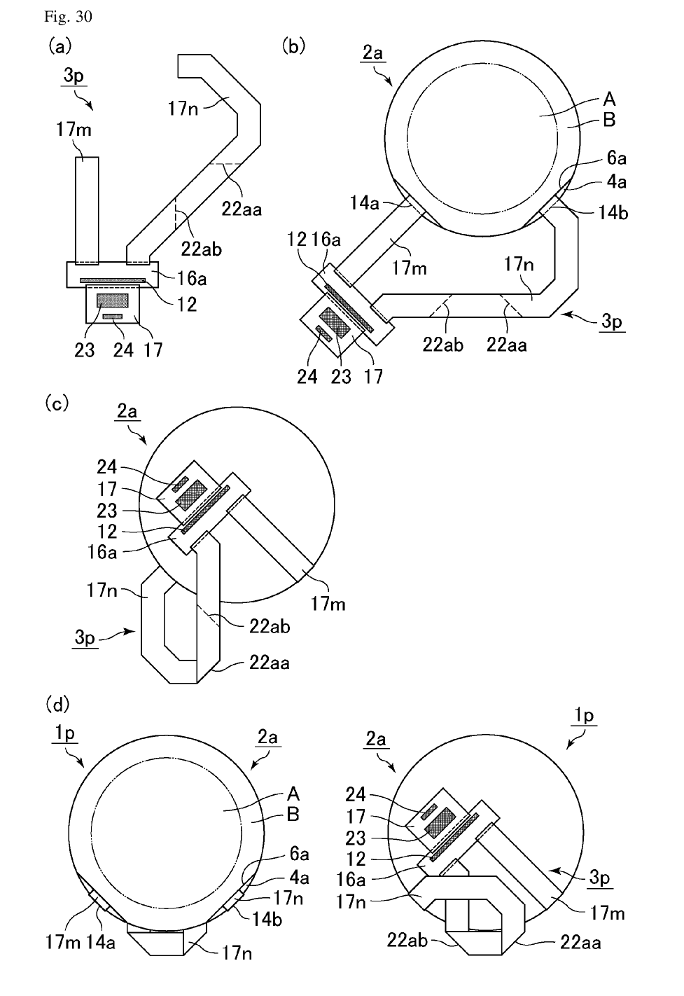

Next, a process of coupling the circuit member 3p with the liquid crystal display panel 2a and bending the circuit member 3p toward the back surface of the liquid crystal display panel 2a is described with reference to FIG. 30. FIG. 30 are schematic plan views illustrating a process of coupling a circuit member of Embodiment 6 with a liquid crystal display panel and bending the circuit member toward the back surface of the liquid crystal display panel (steps (a) to (d)). In FIG. 30, conductive lines and other members of the liquid crystal display panel and circuit member are omitted as appropriate.

### (a) Coupling of COF and FPC

As shown in FIG. 30(a), the COF 16a and the first end of the FPC 17m are coupled with each other. Also, the COF 16a and the first end of the FPC 17n are coupled with each other. As a result, the circuit member 3p is obtained.

The FPC 17n has the folds 22aa and 22ab in addition to the fold along the linear outer edge portion 14b to be formed in the following step (d).

### (b) Coupling of Liquid Crystal Display Panel and FPC

As shown in FIG. 30(b), the linear outer edge portion 14a and the second end of the FPC 17m are attached to each other. Also, the linear outer edge portion 14b and the second end of the FPC 17n are attached to each other. As a result, the circuit member 3p is coupled with the liquid crystal display panel 2a and is placed on the same plane as the liquid crystal display panel 2a.

The circuit member 3p has a line-asymmetric shape in the state shown in FIG. 30(b).

The FPC 17m extends in the direction perpendicular to the linear outer edge portion 14a. This allows the FPC 17m and the COF 16a to be easily placed on the back surface side of the liquid crystal display panel 2a only by bending the FPC 17m along the linear outer edge portion 14a.

### (c) Bending of FPC (1)

As shown in FIG. 30(c), the second end of the FPC 17m is bent from the front surface side toward the back surface of the liquid crystal display panel 2a along the linear outer edge portion 14a. Also, the FPC 17n is bent along the fold 22aa. FIG. 30(c) is a view seen from the back surface side.

### (d) Bending of FPC (2)

The second end of the FPC 17n is bent from the front surface side toward the back surface of the liquid crystal display panel 2a along the linear outer edge portion 14b. Also, the FPC 17n is bent along the fold 22ab. Thereby, the liquid crystal display device 1p is completed with a deformed shape as shown in FIG. 30(d). The image on the left side of FIG. 30(d) is an image seen from the front surface side. The image on the right side of FIG. 30(d) is an image seen from the back surface side.

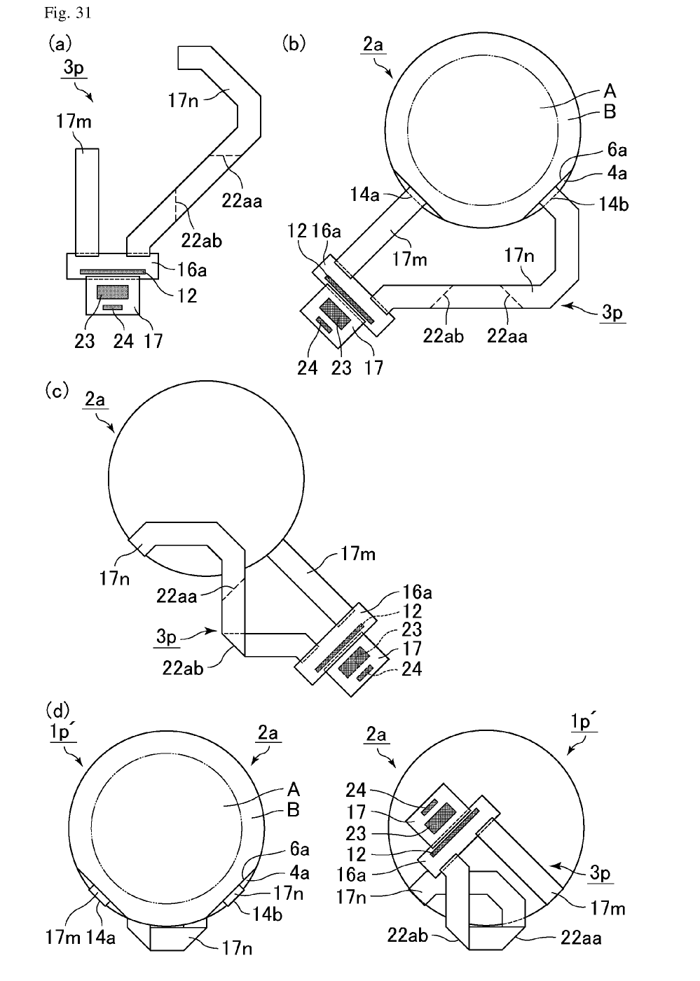

Alternatively, even in a process as shown in FIG. 31, the circuit member 3p can be bent toward the back surface of the liquid crystal display panel 2a. FIG. 31 are schematic plan views illustrating another process of coupling the circuit member of Embodiment 6 with a liquid crystal display panel and bending the circuit member toward the back surface of the liquid crystal display panel (steps (a) to (d)). In FIG. 31, conductive lines and other members of the liquid crystal display panel and circuit member are omitted as appropriate.

### (a) Coupling of COF and FPC

As shown in FIG. 31(a), the COF 16a and the first end of the FPC 17m are coupled with each other. Also, the COF 16a and the first end of the FPC 17n are coupled with each other. As a result, the circuit member 3p is obtained.

The FPC 17n has the folds 22aa and 22ab in addition to the fold along the linear outer edge portion 14b to be formed in the following step (c).

### (b) Coupling of Liquid Crystal Display Panel and FPC

As shown in FIG. 31(b), the linear outer edge portion 14a and the second end of the FPC 17m are attached to each other. Also, the linear outer edge portion 14b and the second end of the FPC 17n are attached to each other. As a result, the circuit member 3p is coupled with the liquid crystal display panel 2a and is placed on the same plane as the liquid crystal display panel 2a.

### (c) Bending of FPC (1)

As shown in FIG. 31(c), the second end of the FPC 17n is bent from the front surface side toward the back surface of the liquid crystal display panel 2a along the linear outer edge portion 14b. Also, the FPC 17n is bent along the fold 22ab. FIG. 31(c) is a view seen from the back surface side.

### (d) Bending of FPC (2)

The second end of the FPC 17m is bent from the front surface side toward the back surface of the liquid crystal display panel 2a along the linear outer edge portion 14a. Also, the FPC 17n is bent along the fold 22aa. Thereby, the liquid crystal display device 1p′ is completed with a deformed shape as shown in FIG. 31(d). The image on the left side of FIG. 31(d) is an image seen from the front surface side. The image on the right side of FIG. 31(d) is an image seen from the back surface side.

### (Variation 1 of Embodiment 6)

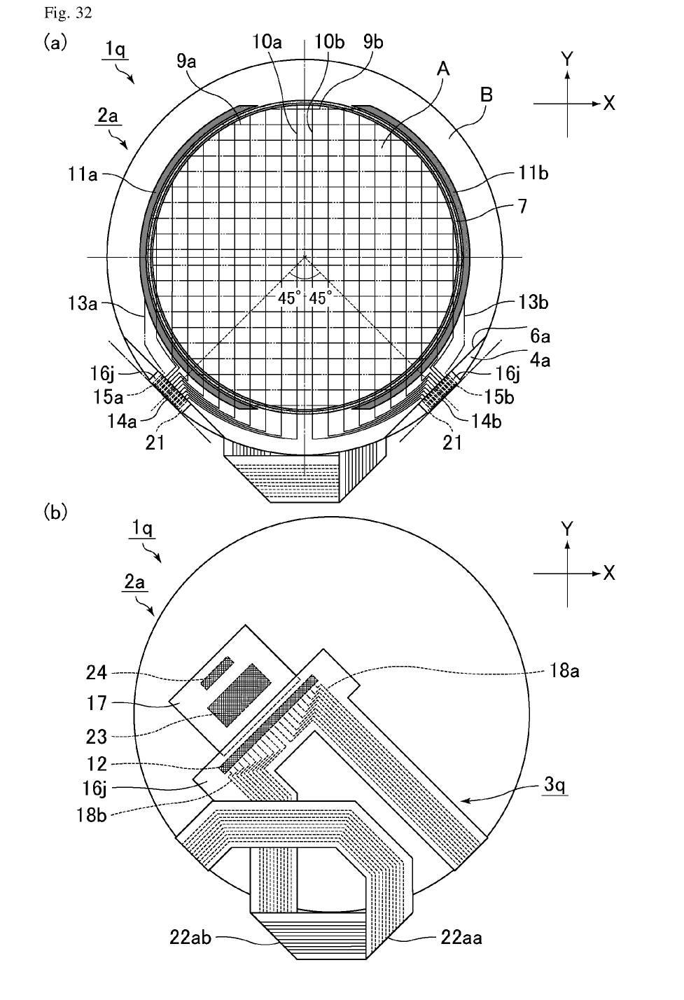

FIG. 32 are schematic plan views of a liquid crystal display device of Variation 1 of Embodiment 6; FIG. 32(a) is a view seen from the front surface side and FIG. 32(b) is a view seen from the back surface side. Variation 1 of Embodiment 6 is the same as Embodiment 6, except that the circuit member is changed to a COF. Thus, descriptions of the same features are omitted as appropriate.

A liquid crystal display device 1q includes the liquid crystal display panel 2a and a circuit member 3q disposed on the back surface side of the liquid crystal display panel 2a.

The circuit member 3q is a COF 16j as shown in FIG. 32(b). The COF 16j has a shape such that two branches are coupled with a main part, which corresponds to integration of the COF 16a (main part) and the FPCs 17m and 17n (branches) as shown in FIG. 29(b).

The main part of the COF 16j is provided with the signal line drive circuit 12.

A first branch of the COF 16j is provided with the conductive lines 18a. A second branch of the COF 16j is provided with the conductive lines 18b. In FIG. 32(b), only some of the conductive lines 18a and 18b are illustrated.

As shown in FIG. 32(a), the linear outer edge portion 14a and the end of the first branch of the COF 16j are attached to each other via the anisotropic conductive film 21. This allows electrical coupling of the terminals 15a of the liquid crystal display panel 2a and the conductive lines 18a of the COF 16j via the anisotropic conductive film 21. Also, the linear outer edge portion 14b and the end of the second branch of the COF 16j are attached to each other via the anisotropic conductive film 21. This allows electrical coupling of the terminals 15b of the liquid crystal display panel 2a and the conductive lines 18b of the COF 16j via the anisotropic conductive film 21.

As a result, the signal line drive circuit 12 and the terminals 15a are electrically coupled via the conductive lines 18a. Also, the signal line drive circuit 12 and the terminals 15b are electrically coupled via the conductive lines 18b.

As shown in FIGS. 32(a) and 32(b), the end of the first branch of the COF 16j is bent from the front surface side toward the back surface of the liquid crystal display panel 2a along the linear outer edge portion 14a. Also, the end of the second branch of the COF 16j is bent from the front surface side toward the back surface of the liquid crystal display panel 2a along the linear outer edge portion 14b.

As shown in FIG. 32(b), the second branch of the COF 16j is bent along the folds 22aa and 22ab. In the present variation, both the folds 22aa and 22ab are valley folds in the state shown in FIG. 32(b).

The fold 22aa is placed on the same straight line as the fold along the linear outer edge portion 14a of the first branch of the COF 16j. The fold 22ab is placed on the same straight line as the fold along the linear outer edge portion 14b of the second branch of the COF 16j.

As shown in FIG. 32(b), the main part of the COF 16j is disposed on the back surface side of the liquid crystal display panel 2a.

The signal line drive circuit 12 is disposed on the COF 16j so as to face the liquid crystal display panel 2a in the state shown in FIG. 32(b).

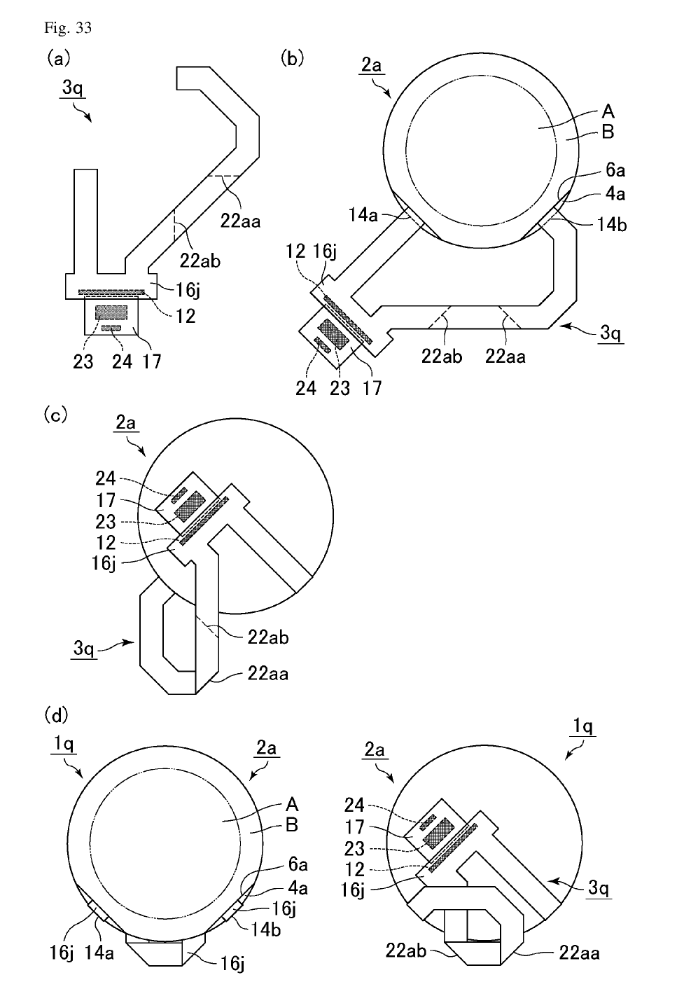

Next, a process of coupling the circuit member 3q with the liquid crystal display panel 2a and bending the circuit member 3q toward the back surface of the liquid crystal display panel 2a is described with reference to FIG. 33. FIG. 33 are schematic plan views illustrating a process of coupling a circuit member of Variation 1 of Embodiment 6 with a liquid crystal display panel and bending the circuit member toward the back surface of the liquid crystal display panel (steps (a) to (d)). In FIG. 33, conductive lines and other members of the liquid crystal display panel and circuit member are omitted as appropriate.

### (a) Preparation of COF

As shown in FIG. 33(a), the COF 16j is prepared as the circuit member 3q.

The second branch of the COF 16j has the folds 22aa and 22ab in addition to the fold along the linear outer edge portion 14b to be formed in the following step (d).

### (b) Coupling of Liquid Crystal Display Panel and COF

As shown in FIG. 33(b), the linear outer edge portion 14a and the end of the first branch of the COF 16j are attached to each other. Also, the linear outer edge portion 14b and the end of the second branch of the COF 16j are attached to each other. As a result, the circuit member 3q is coupled with the liquid crystal display panel 2a and is placed on the same plane as the liquid crystal display panel 2a.

### (c) Bending of COF (1)

As shown in FIG. 33(c), the end of the first branch of the COF 16j is bent from the front surface side toward the back surface of the liquid crystal display panel 2a along the linear outer edge portion 14a. Also, the second branch of the COF 16j is bent along the fold 22aa. FIG. 33(c) is a view seen from the back surface side.

### (d) Bending of COF (2)

The end of the second branch of the COF 16j is bent from the front surface side toward the back surface of the liquid crystal display panel 2a along the linear outer edge portion 14b. Also, the second branch of the COF 16j is bent along the fold 22ab. Thereby, the liquid crystal display device 1q is completed with a deformed shape as shown in FIG. 33(d). The image on the left side of FIG. 33(d) is an image seen from the front surface side. The image on the right side of FIG. 33(d) is an image seen from the back surface side.

Since the COF 16j is used as the circuit member 3q, Variation 1 of Embodiment 6 can eliminate the step of coupling the COF 16a with the FPCs 17m and 17n such as the step (a) in Embodiment 6. As a result, Variation 1 of Embodiment 6 can achieve reduction in the process cost and improvement in the yield in comparison with Embodiment 6.

### (Variation 2 of Embodiment 6)

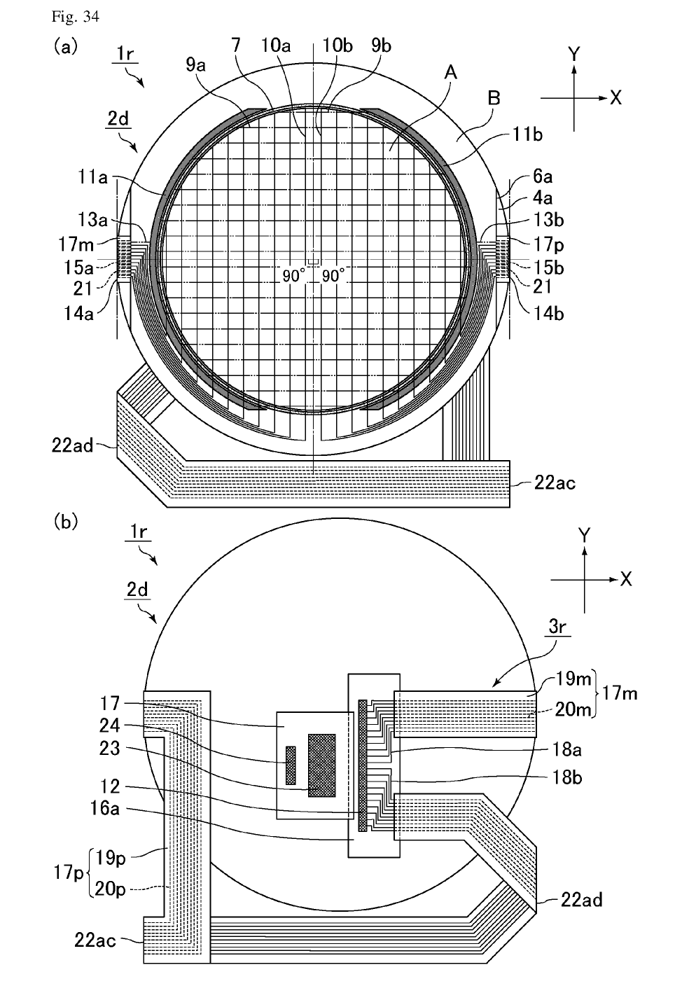

FIG. 34 are schematic plan views of a liquid crystal display device of Variation 2 of Embodiment 6; FIG. 34(a) is a view seen from the front surface side and FIG. 34(b) is a view seen from the back surface side. Variation 2 of Embodiment 6 is the same as Embodiment 6, except that the positions of the two linear outer edge portions of the liquid crystal display panel and the shape of the circuit member are changed. Thus, descriptions of the same features are omitted as appropriate.

A liquid crystal display device 1r includes the liquid crystal display panel 2d and a circuit member 3r disposed on the back surface side of the liquid crystal display panel 2d.

The liquid crystal display panel 2d in FIG. 34(a) is the same as one that has already been described with reference to FIG. 25(a).

As shown in FIG. 34(b), the circuit member 3r includes the COF 16a (main part) and FPCs 17m and 17p (branches) coupled with the COF 16a.

The FPC 17m includes the flexible substrate 19m and the conductive lines 20m. The first end of the FPC 17m is provided with multiple FPC terminals (not shown) electrically coupled with the respective conductive lines 20m in an independent manner. The second end of the FPC 17m is provided with ends of the conductive lines 20m or a conductive portion electrically coupled with the conductive lines 20m. The FPC 17p includes a flexible substrate 19p and multiple conductive lines 20p. The first end of the FPC 17p is provided with multiple FPC terminals (not shown) electrically coupled with the respective conductive lines 20p in an independent manner. The second end of the FPC 17p is provided with ends of the conductive lines 20p or a conductive portion electrically coupled with the conductive lines 20p. In FIG. 34(b), only some of the conductive lines 20m and 20p are illustrated.

As shown in FIG. 34(b), the COF 16a and the first end of the FPC 17m are coupled with each other. This allows electrical coupling of the conductive lines 18a of the COF 16a and the conductive lines 20m of the FPC 17m. Also, the COF 16a and the first end of the FPC 17p are coupled with each other. This allows electrical coupling of the conductive lines 18b of the COF 16a and the conductive lines 20p of the FPC 17p.

As shown in FIG. 34(a), the linear outer edge portion 14a and the second end of the FPC 17m are attached to each other via the anisotropic conductive film 21. This allows electrical coupling of the terminals 15a of the liquid crystal display panel 2a and the conductive lines 20m of the FPC 17m via the anisotropic conductive film 21. Also, the linear outer edge portion 14b and the second end of the FPC 17p are attached to each other via the anisotropic conductive film 21. This allows electrical coupling of the terminals 15b of the liquid crystal display panel 2a and the conductive lines 20p of the FPC 17p via the anisotropic conductive film 21.

As a result, the signal line drive circuit 12 and the terminals 15a are electrically coupled via the conductive lines 18a and 20m. Also, the signal line drive circuit 12 and the terminals 15b are electrically coupled via the conductive lines 18b and 20p.

As shown in FIGS. 34(a) and 34(b), the second end of the FPC 17m is bent from the front surface side toward the back surface of the liquid crystal display panel 2d along the linear outer edge portion 14a. Also, the second end of the FPC 17p is bent from the front surface side toward the back surface of the liquid crystal display panel 2d along the linear outer edge portion 14b.

As shown in FIG. 34(b), the FPC 17p is bent along folds 22ac and 22ad. In the present variation, both the folds 22ac and 22ad are valley folds in the state shown in FIG. 34(b).

The fold 22ac is placed on the same straight line as the fold along the linear outer edge portion 14b of the FPC 17p. The fold 22ad is placed on the same straight line as the fold along the linear outer edge portion 14a of the FPC 17m.

As shown in FIG. 34(b), the COF 16a is disposed on the back surface side of the liquid crystal display panel 2d.

The signal line drive circuit 12 is disposed on the COF 16a so as to be opposite to the liquid crystal display panel 2d in the state shown in FIG. 34(b).

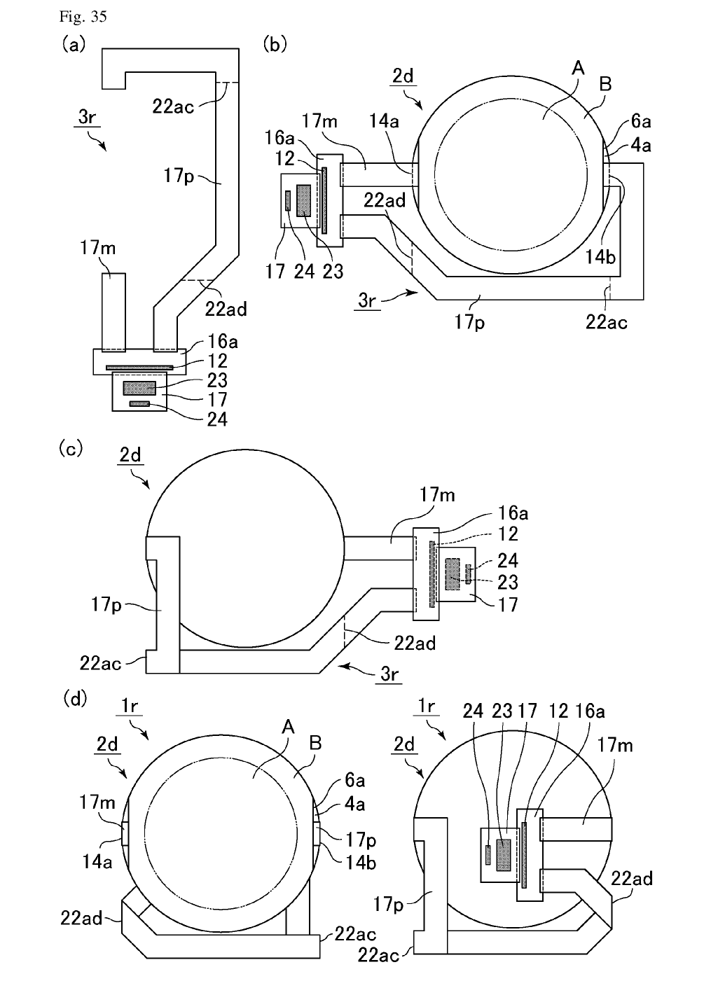

Next, a process of coupling the circuit member 3r with the liquid crystal display panel 2d and bending the circuit member 3r toward the back surface of the liquid crystal display panel 2d is described with reference to FIG. 35. FIG. 35 are schematic plan views illustrating a process of coupling a circuit member of Variation 2 of Embodiment 6 with a liquid crystal display panel and bending the circuit member toward the back surface of the liquid crystal display panel (steps (a) to (d)). In FIG. 35, conductive lines and other members of the liquid crystal display panel and circuit member are omitted as appropriate.

### (a) Coupling of COF and FPC

As shown in FIG. 35(a), the COF 16a and the first end of the FPC 17m are coupled with each other. Also, the COF 16a and the first end of the FPC 17p are coupled with each other. As a result, the circuit member 3r is obtained.

The FPC 17p has the folds 22ac and 22ad in addition to the fold along the linear outer edge portion 14b to be formed in the following step (c).

### (b) Coupling of Liquid Crystal Display Panel and FPC

As shown in FIG. 35(b), the linear outer edge portion 14a and the second end of the FPC 17m are attached to each other. Also, the linear outer edge portion 14b and the second end of the FPC 17p are attached to each other. As a result, the circuit member 3r is coupled with the liquid crystal display panel 2d and is placed on the same plane as the liquid crystal display panel 2d.

### (c) Bending of FPC (1)

As shown in FIG. 35(c), the second end of the FPC 17p is bent from the front surface side toward the back surface of the liquid crystal display panel 2d along the linear outer edge portion 14b. Also, the FPC 17p is bent along the fold 22ac.

### (d) Bending of FPC (2)

The second end of the FPC 17m is bent from the front surface side toward the back surface of the liquid crystal display panel 2d along the linear outer edge portion 14a. Also, the FPC 17p is bent along the fold 22ad. Thereby, the liquid crystal display device 1r is completed with a deformed shape as shown in FIG. 35(d). The image on the left side of FIG. 35(d) is an image seen from the front surface side. The image on the right side of FIG. 35(d) is an image seen from the back surface side.

### Embodiment 7

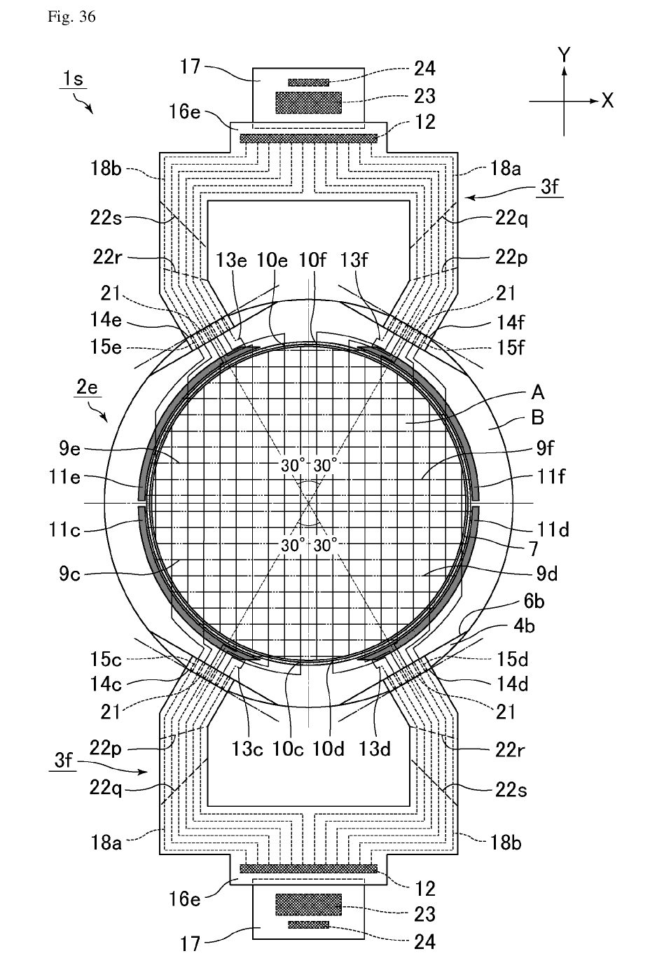

FIG. 36 is a schematic plan view of a liquid crystal display device of Embodiment 7. Embodiment 7 is the same as Variation 1 of Embodiment 3, except that the number of the linear outer edge portions of the liquid crystal display panel is changed. Thus, descriptions of the same features are omitted as appropriate. FIG. 36 shows a state before the circuit member is bent toward the back surface of the liquid crystal display panel.

In a liquid crystal display device 1s, two circuit members 3f are coupled with a liquid crystal display panel 2e. The two circuit members 3f in FIG. 36 are both the same as one that has already been described with reference to FIG. 16(a).

The liquid crystal display panel 2e has linear outer edge portions 14c, 14d, 14e, and 14f on the outer edge.

The outer edge of a thin film transistor array substrate 4b (frame region B) is provided with a scanning line drive circuit 11c configured to apply voltage to multiple scanning lines 9c, a scanning line drive circuit 11d configured to apply voltage to multiple scanning lines 9d, a scanning line drive circuit 11e configured to apply voltage to multiple scanning lines 9e, and a scanning line drive circuit 11f configured to apply voltage to multiple scanning lines 9f.

Multiple signal lines 10c and a conductive line 13c led from the scanning line drive circuit 11c are electrically coupled with multiple terminals 15c disposed on the front surface side of the linear outer edge portion 14c in an independent manner. Multiple signal lines 10d and a conductive line 13d led from the scanning line drive circuit 11d are electrically coupled with multiple terminals 15d disposed on the front surface side of the linear outer edge portion 14d in an independent manner. Multiple signal lines 10e and a conductive line 13e led from the scanning line drive circuit 11e are electrically coupled with multiple terminals 15e disposed on the front surface side of the linear outer edge portion 14e in an independent manner. Multiple signal lines 10f and a conductive line 13f led from the scanning line drive circuit 11f are electrically coupled with multiple terminals 15f disposed on the front surface side of the linear outer edge portion 14f in an independent manner.

The signal lines 10c and the signal lines 10e are arranged alternately on the left half of the thin film transistor array substrate 4b. The signal lines 10d and the signal lines 10f are arranged alternately on the right half of the thin film transistor array substrate 4b.

In the liquid crystal display panel 2e, the direction perpendicular to each of the linear outer edge portions and the Y direction (the vertical direction in FIG. 36) preferably form an angle of 30° as shown in FIG. 36. This enables the narrowest frame region B.

The two branches of one of the two circuit members 3f are respectively attached to the linear outer edge portions 14c and 14d. The two branches of the other circuit member 3f are respectively attached to the linear outer edge portions 14e and 14f.

Each of the two circuit members 3f can be bent toward the back surface of the liquid crystal display panel 2e by a process that has already been described with reference to FIG. 16.

Embodiment 7 can provide the following effects by disposing the four linear outer edge portions 14c, 14d, 14e, and 14f.

(1) When the number of terminals of the liquid crystal display panel is the same, the number of terminals disposed on one linear outer edge portion of the liquid crystal display panel 2e (the present embodiment) can be half in comparison with the liquid crystal display panel 2b (Variation 1 of Embodiment 3). In other words, the frame can be more easily narrowed down.

(2) When the number of terminals disposed on one linear outer edge portion is the same, the number of signal lines to be disposed on the liquid crystal display panel 2e (the present embodiment) can be doubled in comparison with the liquid crystal display panel 2b (Variation 1 of Embodiment 3). In other words, higher definition can be more easily achieved.

Although the present embodiment shows a structure in which two circuit members 3f are coupled with the liquid crystal display panel 2e, a circuit member having a different shape (for example, the circuit member 3g as shown in FIG. 18(a)) may be coupled therewith.

### (Variation of Embodiment 7)

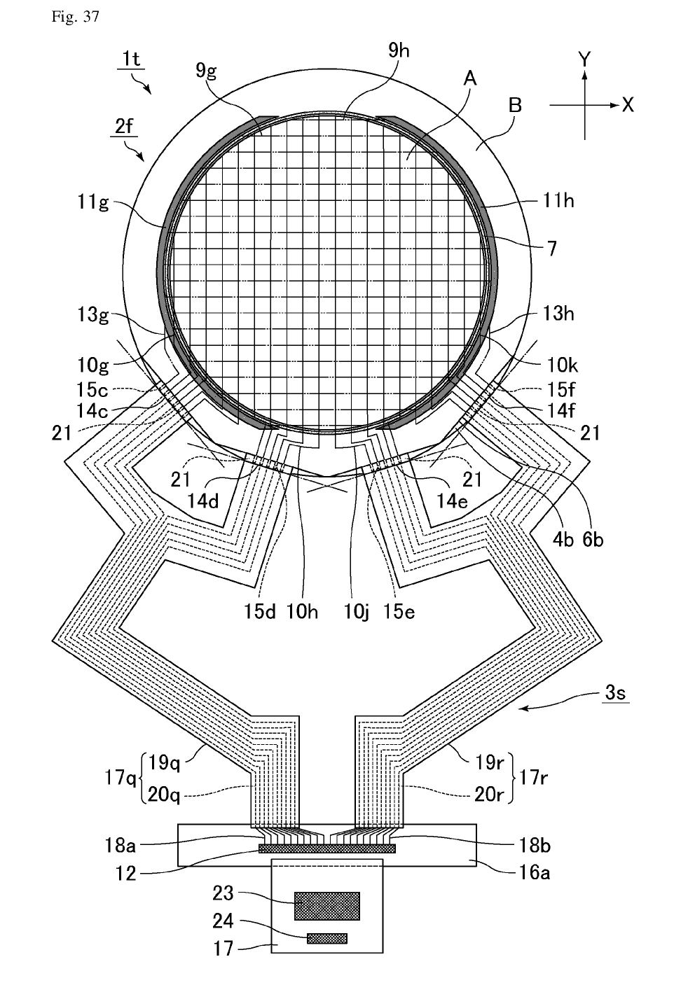

FIG. 37 is a schematic plan view of a liquid crystal display device of Variation of Embodiment 7. Variation of Embodiment 7 is the same as Embodiment 7, except that the positions of the four linear outer edge portions of the liquid crystal display panel and the shape of the circuit member are changed. Thus, descriptions of the same features are omitted as appropriate. FIG. 37 shows a state before the circuit member is bent toward the back surface of the liquid crystal display panel.

In a liquid crystal display device 1t, a circuit member 3s is coupled with a liquid crystal display panel 2f.

The liquid crystal display panel 2f has the linear outer edge portions 14c, 14d, 14e, and 14f on the outer edge. In the present variation, the linear outer edge portions 14c, 14d, 14e, and 14f are disposed on the lower half of the liquid crystal display panel 2f.

The outer edge of the thin film transistor array substrate 4b (frame region B) is provided with a scanning line drive circuit 11g configured to apply voltage to multiple scanning lines 9g and a scanning line drive circuit 11h configured to apply voltage to multiple scanning lines 9h.

Multiple signal lines 10g and a conductive line 13g led from the scanning line drive circuit 11g are electrically coupled with the terminals 15c disposed on the linear outer edge portion 14c in an independent manner. Multiple signal lines 10h are electrically coupled with the terminals 15d disposed on the linear outer edge portion 14d in an independent manner. Multiple signal lines 10j are electrically coupled with the terminals 15e disposed on the linear outer edge portion 14e in an independent manner. Multiple signal lines 10k and a conductive line 13h led from the scanning line drive circuit 11h are electrically coupled with the terminals 15f disposed on the linear outer edge portion 14f in an independent manner.

The signal lines 10g, 10h, 10j, and 10k are arranged in order from the left side to the right side in FIG. 37.

The circuit member 3s includes the COF 16a (main part) and FPCs 17q and 17r coupled with the COF 16a. A first end of each of the FPCs 17q and 17r has a shape such that the end is divided into two branches.

The FPC 17q includes a flexible substrate 19q and multiple conductive lines 20q. The FPC 17r includes a flexible substrate 19r and multiple conductive lines 20r. In FIG. 37, only some of the conductive lines 20q and 20r are illustrated.

The ends of the two branches of the FPC 17q are respectively attached to the linear outer edge portions 14c and 14d. This allows electrical coupling of the terminals 15c and 15d of the liquid crystal display panels 2f with the conductive lines 20q of the FPC 17q. The ends of the two branches of the FPC 17r are respectively attached to the linear outer edge portions 14e and 14f. This allows electrical coupling of the terminals 15e and 15f of the liquid crystal display panel 2f with the conductive lines 20r of the FPC 17r.

The COF 16a and a second end of the FPC 17q are coupled with each other. This allows electrical coupling of the conductive lines 18a of the COF 16a and the conductive lines 20q of the FPC 17q. The COF 16a and a second end of the FPC 17r are coupled with each other. This allows electrical coupling of the conductive lines 18b of the COF 16a and the conductive lines 20r of the FPC 17r.

As a result, the signal line drive circuit 12 and the terminals 15c and 15d are electrically coupled via the conductive lines 18a and 20q. Also, the signal line drive circuit 12 and the terminals 15e and 15f are electrically coupled via the conductive lines 18b and 20r.

The circuit member 3s can be bent toward the back surface of the liquid crystal display panel 2f by bending the ends of the two branches of the FPC 17q along the linear outer edge portions 14c and 14d and by bending the ends of the two branches of the FPC 17r along the linear outer edge portions 14e and 14f, each from the front surface side toward the back surface of the liquid crystal display panel 2f.

Variation of Embodiment 7 can simplify the processes in an external circuit configured to supply data signals to the signal line drive circuit 12 in comparison with Embodiment 7. In contrast, Embodiment 7 requires a process of distributing data signals to the two signal line drive circuits 12, which complicates the processes in an external circuit.

Although the present variation shows a structure in which the circuit member 3s is coupled with the liquid crystal display panel 2f, a circuit member having a different shape may be coupled therewith.

### Embodiment 8

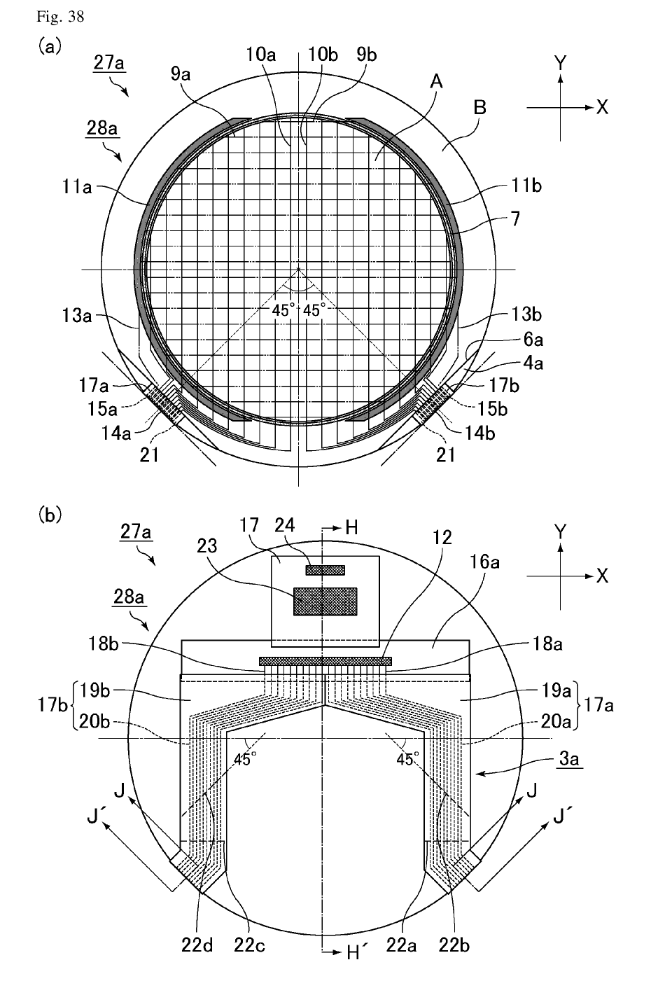

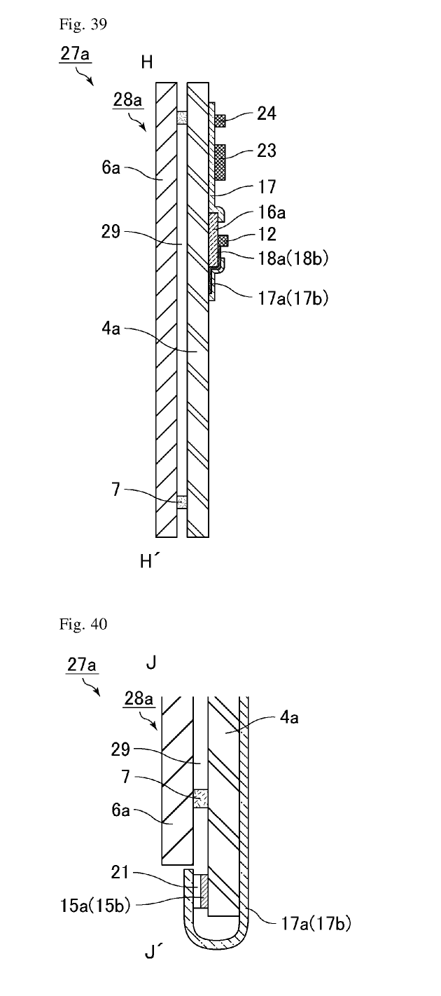

An organic electroluminescent display device and a circuit member of Embodiment 8 are described with reference to FIG. 38, FIG. 39, and FIG. 40. FIG. 38 are schematic plan views of an organic electroluminescent display device of Embodiment 8; FIG. 38(a) is a view seen from the front surface side and FIG. 38(b) is a view seen from the back surface side. FIG. 39 is a schematic cross-sectional view of a cross section taken along the H-H′ line in FIG. 38(b). FIG. 40 is a schematic cross-sectional view of a cross section taken along the J-J′ line in FIG. 38(b). Embodiment 8 is the same as Embodiment 1, except that the liquid crystal display panel is changed to an organic electroluminescent display panel. Thus, descriptions of the same features are omitted as appropriate. The term organic electroluminescent as used herein is also referred to as “organic EL”. The organic EL is also referred to as an organic light emitting diode (OLED).

An organic EL display device 27a includes an organic EL display panel 28a and the circuit member 3a disposed on the back surface side of the organic EL display panel 28a.

As shown in FIG. 39, the organic EL display panel 28a includes the thin film transistor array substrate 4a, an organic EL layer 29, and the color filter substrate 6a in the given order from the back surface side to the front surface side.

The organic EL layer 29 may have a structure in which an anode, a hole-transport layer, a light emitting layer, an electron-transport layer, and a cathode are arranged in the given order from the back surface side to the front surface side, for example. Coupling the thin film transistor element of the thin film transistor array substrate 4a and the anode enables driving of the organic EL layer 29.

Instead of the thin film transistor array substrate 4a, a plastic substrate may be used. In this case, the organic EL display panel 28a can be flexible.

The organic EL layer 29 may further include other components such as a hole-injection layer, an electron-injection layer, a hole-blocking layer, and an electron-blocking layer, as appropriate. The organic EL layer 29 may also include a layer having multiple functions, such as a layer serving as both a hole-injection layer and a hole-transport layer formed by combining a hole-injection layer and a hole-transport layer and a layer serving as both an electron-injection layer and an electron-transport layer formed by combining an electron-injection layer and an electron-transport layer.

In the present embodiment, a colorization technique of the organic EL display panel 28a is a color filter technique. In the color filter technique, a white light emitting layer is disposed as the light emitting layer of the organic EL layer 29 and combined with the color filter substrate 6a, thereby achieving colorization. The colorization technique of the organic EL display panel 28a may be a three-color technique using red, green, and blue light emitting layers.

Since the organic EL display device 27a is a self-luminous display device, it does not need a backlight unlike the liquid crystal display device 1a of Embodiment 1.

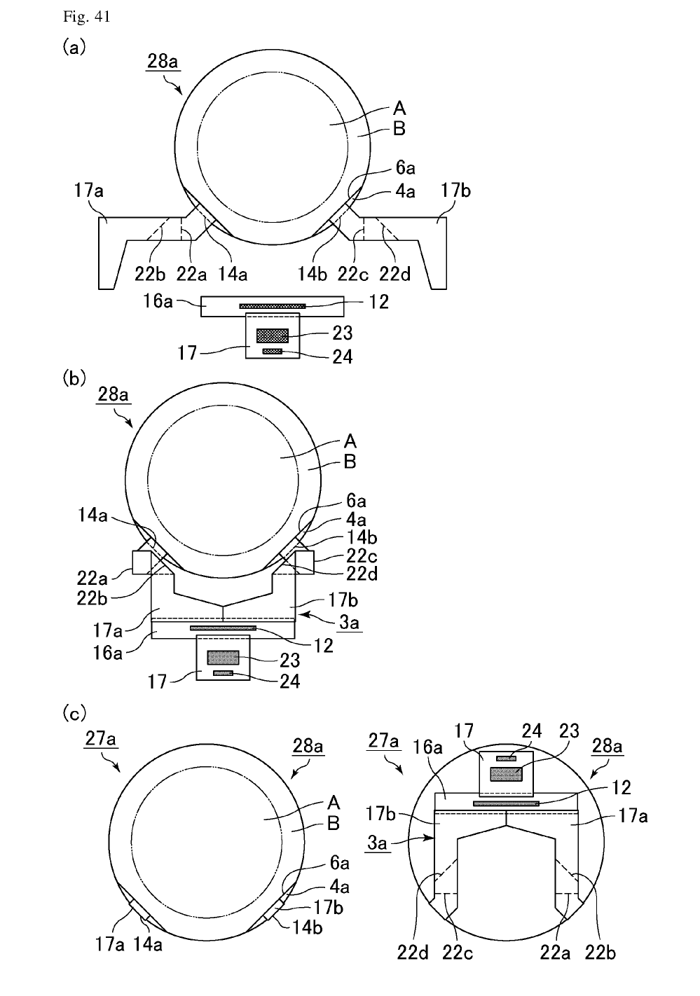

Next, a process of coupling the circuit member 3a with the organic EL display panel 28a and bending the circuit member 3a toward the back surface of the organic EL display panel 28a is described with reference to FIG. 41. FIG. 41 are schematic plan views illustrating a process of coupling a circuit member of Embodiment 8 with an organic EL display panel and bending the circuit member toward the back surface of the organic EL display panel (steps (a) to (c)). In FIG. 41, conductive lines and other members of the organic EL display panel and circuit member are omitted as appropriate.

### (a) Coupling of Organic EL Display Panel and FPC

As shown in FIG. 41(a), the linear outer edge portion 14a and the first end of the FPC 17a are attached to each other. Also, the linear outer edge portion 14b and the first end of the FPC 17b are attached to each other. The COF 16a is prepared.

### (b) Coupling of COF and FPC

As shown in FIG. 41(b), the COF 16a and the second end of the FPC 17a are coupled with each other. At this time, the FPC 17a is bent along the folds 22a and 22b. Also, the COF 16a and the second end of the FPC 17b are coupled with each other. At this time, the FPC 17b is bent along the folds 22c and 22d. As a result, the circuit member 3a is coupled with the organic EL display panel 28a and is placed on the same plane as the organic EL display panel 28a. In this state, the organic EL display panel 28a can be easily subjected to a lighting inspection using the circuit member 3a. This enables early detection of open circuits of any of the conductive lines (e.g., the signal lines 10a and 10b) of the organic EL display panel 28a and the conductive lines 20a and 20b of the circuit member 3a.

### (c) Bending of FPC

The first end of the FPC 17a is bent from the front surface side toward the back surface of the organic EL display panel 28a along the linear outer edge portion 14a. Also, the first end of the FPC 17b is bent from the front surface side toward the back surface of the organic EL display panel 28a along the linear outer edge portion 14b. Thereby, the organic EL display device 27a is completed with a deformed shape as shown in FIG. 41(c). In the organic EL display device 27a, the circuit member 3a does not protrude from the organic EL display panel 28a. The image on the left side of FIG. 41(c) is an image seen from the front surface side. The image on the right side of FIG. 41(c) is an image seen from the back surface side.

Although the present embodiment shows a structure in which the liquid crystal display panel 2a in Embodiment 1 is changed to the organic EL display panel 28a, the liquid crystal display panel of any embodiment (variation) other than Embodiment 1 may be changed to an organic EL display panel.

### (Examples of Shape of Display Panel)

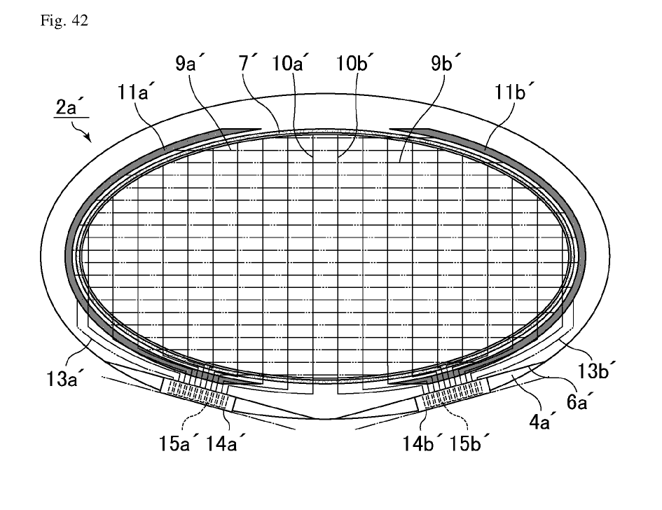

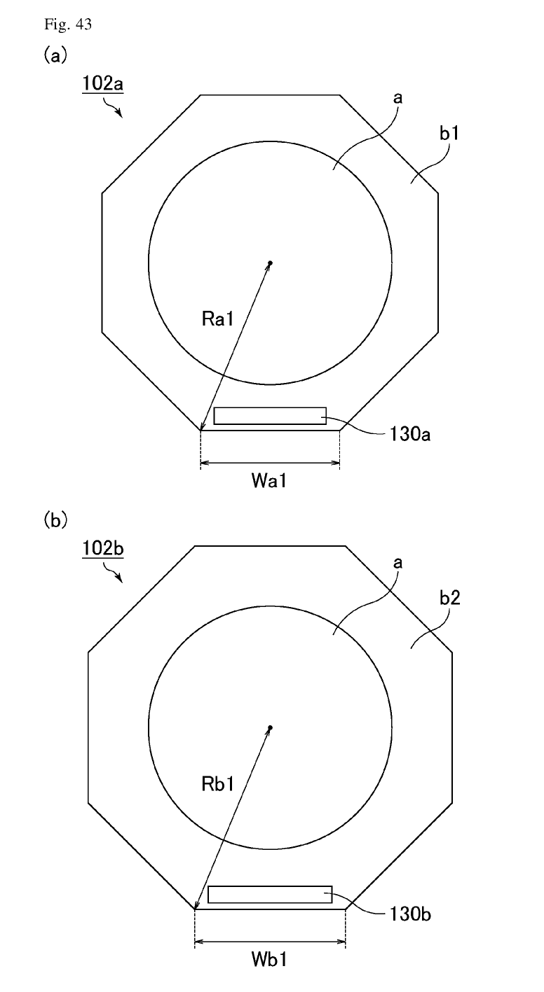

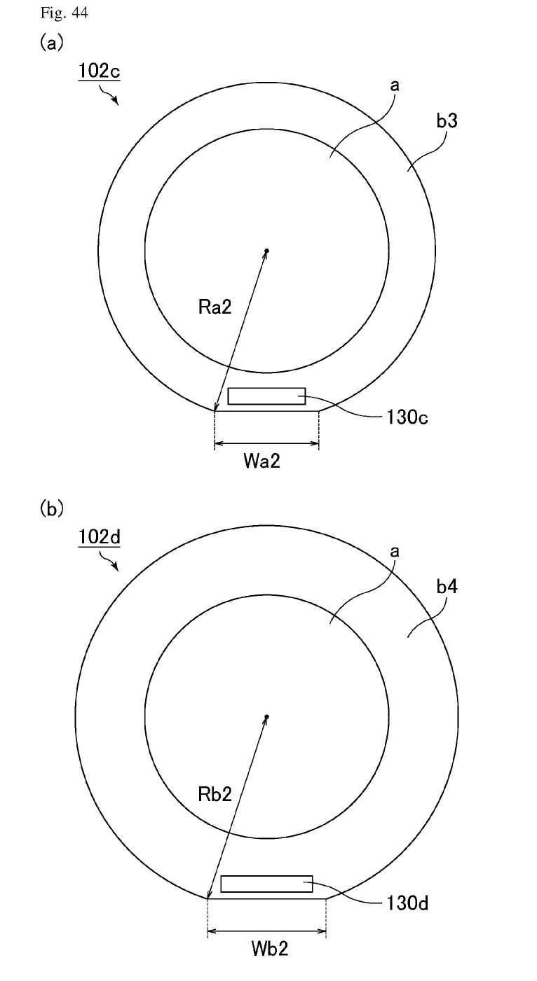

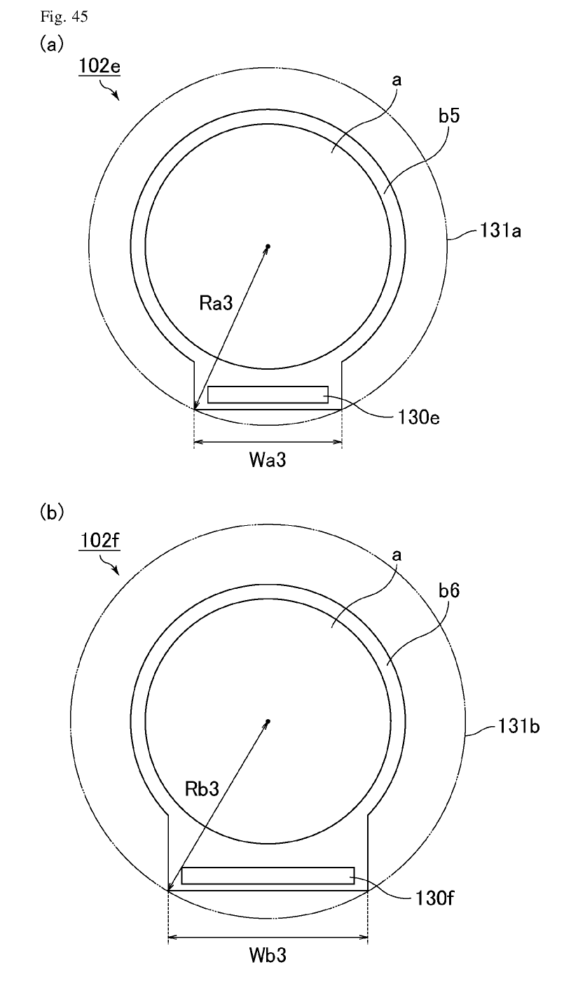

Each of the above embodiments (variations) shows a structure in which the outer edge of the display panel has a circular shape except for the multiple linear outer edge portions. Alternatively, the outer edge may have a shape constituted by curves other than the circular shape. FIG. 42 shows an example of such a structure in which the liquid crystal display panel 2a as in Embodiment 1 has an elliptic circular shape. FIG. 42 is a schematic plan view of an example of the shape of a liquid crystal display panel different from that in Embodiment 1. As shown in FIG. 42, the outer edge of a liquid crystal display panel 2a′ has an elliptic circular shape except for linear outer edge portions 14a′ and 14b′.

### (Additional Remarks)

Hereinafter, examples of preferred features of the display device of the present invention are described. These examples may be appropriately combined within the spirit of the present invention.

The circuit member may be placed on the same plane as the display panel with the ends of the branches being not bent toward the back surface of the display panel. Thereby, the display panel can be easily subjected to a lighting inspection using the circuit member. This enables early detection of open circuits of any of the conductive lines of the display panel and the conductive lines of the circuit member.

The circuit member may have a line-symmetric shape with the ends of the branches being not bent toward the back surface of the display panel. Thereby, the shape of the circuit member can be more simplified.

Each of the branches may have a fold along the corresponding linear outer edge portion and additional multiple folds. The folds may include a mountain fold and a valley fold. Thereby, the circuit member can favorably be coupled with the display panel and bent toward the back surface of the display panel.

The branches may be twisted and crossed on the back surface side of the display panel. Each of the branches may have a fold along the corresponding linear outer edge portion and an additional single fold. Thereby, the circuit member can be favorably folded up on the back surface side of the display panel.

The circuit member may have a line-asymmetric shape with the ends of the branches being not bent toward the back surface of the display panel. The linear outer edge portions may include a first linear outer edge portion. The branches may include a first branch attached to the first linear outer edge portion. The first branch may extend in the direction perpendicular to the first linear outer edge portion. Thereby, the first branch excluding the portion attached to the first linear outer edge portion can be placed on the back surface side of the display panel only by bending the first branch along the first linear outer edge portion. As a result, the circuit member can be favorably bent toward the back surface of the display panel.

The main part may be a chip on film, and each of the branches may be a flexible printed circuit. Thereby, the present invention can be used even for a structure in which the circuit member is a combination of a chip on film and a flexible printed circuit.

The circuit member may be a chip on film. Thereby, the present invention can also be applied to the cases where the circuit member is a chip on film. Further, this structure can achieve reduction in the process cost and improvement in the yield in comparison with the structure in which the circuit member is a combination of a chip on film and a flexible printed circuit.

The driver may be disposed on the main part so as to be opposite to the display panel. Thereby, the driver and an external circuit configured to supply signals to the driver can be easily coupled with each other, and the thickness of the display device can be reduced.

The circuit member may be attached to the back surface side of the display panel with an adhesive component. Thereby, the circuit member can be easily fixed on the back surface side of the display panel.

The display panel may be a liquid crystal display panel. Thereby, the present invention can also be applied to the cases where a liquid crystal display panel is used as the display panel (in other words, the display device is a liquid crystal display device).

The display panel may be an organic electroluminescent display panel. Thereby, the present invention can also be applied to the cases where an organic EL display panel is used as the display panel (in other words, the display device is an organic EL display device).

The display panel may be of any type. Alternative to the liquid crystal display panel and the organic EL display panel, the display panel may be an electrophoresis display panel or a microelectromechanical system (MEMS) display panel, for example.

These are examples of preferred features of the display device of the present invention, and those relating to the circuit member among these examples are also examples of preferred features of the circuit member of the present invention.

### REFERENCE SIGNS LIST

1a, 1b, 1c, 1d, 1e, 1f, 1g, 1h, 1j, 1k, 1m, 1n, 1p, 1p′, 1q, 1r, 1s, 1t: liquid crystal display device
2a, 2a′, 2b, 2c, 2d, 2e, 2f, 102a, 102b, 102c, 102d, 102e, 102f: liquid crystal display panel
3a, 3b, 3c, 3d, 3e, 3f, 3g, 3h, 3j, 3k, 3m, 3n, 3p, 3q, 3r, 3s: circuit member
4a, 4a′, 4b: thin film transistor array substrate
5: liquid crystal layer
6a, 6a′, 6b: color filter substrate
7, 7′: sealing material
8: backlight
9a, 9a′, 9b, 9b′, 9c, 9d, 9e, 9f, 9g, 9h: scanning line
10a, 10a′, 10b, 10b′, 10c, 10d, 10e, 10f, 10g, 10h, 10j, 10k: signal line
11a, 11a′, 11b, 11b′, 11c, 11d, 11e, 11f, 11g, 11h: scanning line drive circuit
12: signal line drive circuit
13a, 13a′, 13b, 13b′, 13c, 13d, 13e, 13f, 13g, 13h: conductive line led from scanning line drive circuit
14a, 14a′, 14b, 14b′, 14c, 14d, 14e, 14f: linear outer edge portion
15a, 15a′, 15b, 15b′, 15c, 15d, 15e, 15f: terminal
16a, 16b, 16c, 16d, 16e, 16f, 16g, 16h, 16j: chip on film (COF)
17, 17a, 17b, 17c, 17d, 17e, 17f, 17g, 17h, 17j, 17k, 17m, 17n, 17p, 17q, 17r: flexible printed circuit (FPC)
18a, 18b: conductive line led from signal line drive circuit
19a, 19b, 19c, 19d, 19e, 19f, 19g, 19h, 19j, 19k, 19m, 19n, 19p, 19q, 19r: flexible substrate
20a, 20b, 20c, 20d, 20e, 20f, 20g, 20h, 20j, 20k, 20m, 20n, 20p, 20q, 20r: conductive line
21: anisotropic conductive film
22a, 22b, 22c, 22d, 22e, 22f, 22g, 22h, 22j, 22k, 22m, 22n, 22p, 22q, 22r, 22s, 22t, 22u, 22v, 22w, 22aa, 22ab, 22ac, 22ad, 22ae, 22af, 22ag, 22ab: fold
23: component
24: B to B connector
25: spacer
26: insulating resin
27a: organic EL display device
28a: organic EL display panel
29: organic EL layer
130a, 130b, 130c, 130d, 130e, 130f: terminal portion
131a, 131b: housing
A, a: display region
B, b1, b2, b3, b4, b5, b6: frame region
w: width of insulating resin applied
t: thickness of spacer
Wa1, Wa1, Wa3, Wb1, Wb2, Wb3: width of region where liquid crystal display panel (terminal portion) and circuit member are attached
Ra1, Ra2, Ra3, Rb1, Rb2, Rb3: distance from center of display region to outermost portion of liquid crystal display panel

1. A display device comprising:
a display panel having an outer shape that is curved as a whole and is partially provided with multiple linear outer edge portions; and
a circuit member including a main part and multiple branches coupled with the main part,
each of the linear outer edge portions being provided with a terminal on the front surface side of the display panel,
the main part being provided with a driver,
each of the branches being provided with a conductive line that electrically couples the driver and the terminal,
each of ends of the branches being attached to the corresponding linear outer edge portion and being bent along the corresponding linear outer edge portion from the front surface side toward the back surface of the display panel,
the main part being disposed on the back surface side of the display panel.

2. The display device according to claim 1,
wherein the circuit member is placed on the same plane as the display panel with the ends of the branches being not bent toward the back surface of the display panel.

3. The display device according to claim 1 or 2,
wherein the circuit member has a line-symmetric shape with the ends of the branches being not bent toward the back surface of the display panel.

4. The display device according to claim 3,
wherein each of the branches has a fold along the corresponding linear outer edge portion and additional multiple folds.

5. The display device according to claim 4,
wherein the folds include a mountain fold and a valley fold.

6. The display device according to claim 3,
wherein the branches are twisted and crossed on the back surface side of the display panel.

7. The display device according to claim 6,
wherein each of the branches has a fold along the corresponding linear outer edge portion and an additional single fold.

8. The display device according to claim 1 or 2,
wherein the circuit member has a line-asymmetric shape with the ends of the branches being not bent toward the back surface of the display panel,
the linear outer edge portions include a first linear outer edge portion,
the branches include a first branch attached to the first linear outer edge portion,
the first branch extends in the direction perpendicular to the first linear outer edge portion.

9. The display device according to claim 1,
wherein the main part is a chip on film, and
each of the branches is a flexible printed circuit.

10. The display device according to claim 1,
wherein the circuit member is a chip on film.

11. The display device according to claim 1,
wherein the driver is disposed on the main part so as to be opposite to the display panel.

12. The display device according to claim 1,
wherein the circuit member is attached to the back surface side of the display panel with an adhesive component.

13. The display device according to claim 1,
wherein the display panel is a liquid crystal display panel.

14. The display device according to claim 1,
wherein the display panel is an organic electroluminescent display panel.

15. A circuit member comprising:
a main part; and
multiple branches coupled with the main part,
the main part being provided with a driver,
each of the branches being provided with a conductive line electrically coupled with the driver,
at least an end of each of the branches being bendable.
